(19) United States
(12) Patent Application Publication
(10) Pub. No.: US 2023/0138085 A1
(43) Pub. Date: May 4, 2023

(54) LIGHT-EMITTING DEVICE, LIGHT-EMITTING APPARATUS, ELECTRONIC DEVICE AND LIGHTING DEVICE

(71) Applicant: SEMICONDUCTOR ENERGY LABORATORY CO., LTD., Atsugi-shi, Kanagawa-ken (JP)

(72) Inventors: Sachiko KAWAKAMI, Atsugi, Kanagawa (JP); Naoaki HASHIMOTO, Sagamihara, Kanagawa (JP); Satoshi SEO, Sagamihara, Kanagawa (JP)

(21) Appl. No.: 17/907,878

(22) PCT Filed: Mar. 12, 2021
(86) PCT No.: PCT/IB2021/052064

§ 371 Date: Aug. 29, 2022

(30) Foreign Application Priority Data
Mar. 18, 2020 (JP) 2020-047969

(51) Int. Cl. H10K 85/30

(52) U.S. Cl. CPC H10K 85/30; H10K 50/11

(57) ABSTRACT

A light-emitting device with a long lifetime is provided. A light-emitting device with a low driving voltage is provided. In the light-emitting device, an electron-transport layer includes an organometallic complex of an alkali metal and an organic compound having an electron-transport property; the organometallic complex and the organic compound form an exciplex in combination; a value (eV) obtained by converting into energy a peak wavelength of an emission spectrum of the exciplex formed with the organometallic complex and the organic compound having a mass ratio of 1:1 is smaller than a difference (eV) between a HOMO level of the organometallic complex and a LUMO level of the organic compound by greater than or equal to 0.1 eV.

### TECHNICAL FIELD

One embodiment of the present invention relates to a light-emitting device, a light-emitting element, a display module, a lighting module, a display device, a light-emitting apparatus, an electronic device, and a lighting device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting apparatus, a lighting device, a power storage device, a memory device, an imaging device, a driving method thereof, and a manufacturing method thereof.

### BACKGROUND ART

Light-emitting devices (organic EL elements) including organic compounds and utilizing electroluminescence (EL) have been put into practical use. In the basic structure of such light-emitting devices, an organic compound layer containing a light-emitting material (an EL layer) is interposed between a pair of electrodes. Carriers are injected by application of voltage to the element, and recombination energy of the carriers is used, whereby light emission can be obtained from the light-emitting material.

Such light-emitting devices are of self-light-emitting type and thus have advantages over liquid crystal, such as high visibility and no need for backlight when used for pixels of a display, and are suitable as flat panel display devices. Displays using such light-emitting devices are also highly advantageous in that they can be fabricated to be thin and lightweight. Moreover, an extremely fast response speed is also a feature.

Since light-emitting layers of such light-emitting devices can be successively formed two-dimensionally, planar light emission can be achieved. This feature is difficult to realize with point light sources typified by incandescent lamps and LEDs or linear light sources typified by fluorescent lamps; thus, the light-emitting devices also have great potential as planar light sources, which can be applied to lighting and the like.

Displays or lighting devices using light-emitting devices can be suitably used for a variety of electronic devices as described above, and research and development of light-emitting devices have progressed for higher efficiency and a longer lifetime.

In a structure disclosed in Patent Document 1, a hole-transport material whose HOMO level is between the HOMO level of a hole-injection layer and the HOMO level of a host material is provided between a light-emitting layer and a hole-transport layer in contact with a hole-injection layer.

The characteristics of light-emitting devices have been improved considerably, but are still insufficient to satisfy advanced requirements for various characteristics such as efficiency and durability.

### REFERENCE

### Patent Document

[Patent Document 1] Japanese Published Patent Application No. 2016-174161

### SUMMARY OF THE INVENTION

### Problems to be Solved by the Invention

In view of the above, an object of one embodiment of the present invention is to provide a novel light-emitting device. Another object is to provide a light-emitting device with a long lifetime. Another object is to provide a light-emitting device with a low driving voltage.

An object of another embodiment of the present invention is to provide a light-emitting apparatus, an electronic device, and a display device each having high reliability.

It is only necessary that at least one of the above-described objects be achieved in one embodiment of the present invention.

### Means for Solving the Problems

One embodiment of the present invention is a light-emitting device including a first electrode, a second electrode, and an EL layer. The EL layer is positioned between the first electrode and the second electrode. The EL layer includes a light-emitting layer and an electron-transport layer. The electron-transport layer is positioned between the light-emitting layer and the second electrode. The electron-transport layer includes an organometallic complex of an alkali metal and an organic compound having an electron-transport property. The organometallic complex and the organic compound form an exciplex in combination. A value (eV) obtained by converting into energy a peak wavelength of an emission spectrum of the exciplex formed with the organometallic complex and the organic compound having a mass ratio of 1:1 is smaller than a difference (eV) between a HOMO level of the organometallic complex and a LUMO level of the organic compound by greater than or equal to 0.1 eV.

Another embodiment of the present invention is a light-emitting device including a first electrode, a second electrode, and an EL layer. The EL layer is positioned between the first electrode and the second electrode. The EL layer includes a light-emitting layer and an electron-transport layer. The electron-transport layer is positioned between the light-emitting layer and the second electrode. The electron-transport layer includes an organometallic complex of an alkali metal and an organic compound having an electron-transport property. The organometallic complex and the organic compound form an exciplex in combination. A peak wavelength of an emission spectrum of the exciplex formed with the organometallic complex and the organic compound having a mass ratio of 1:1 is greater than or equal to 570 nm.

Another embodiment of the present invention is a light-emitting device including a first electrode, a second electrode, and an EL layer. The EL layer is positioned between the first electrode and the second electrode. The EL layer includes a light-emitting layer and an electron-transport layer. The electron-transport layer is positioned between the light-emitting layer and the second electrode. The electron-transport layer includes an organometallic complex of an alkali metal and an organic compound having an electron-transport property. The organometallic complex and the organic compound form an exciplex in combination. A peak wavelength of an emission spectrum of the exciplex formed with the organometallic complex and the organic compound having a mass ratio of 1:1 is greater than or equal to 570 nm and less than 610 nm.

Another embodiment of the present invention is a light-emitting device including a first electrode, a second electrode, and an EL layer. The EL layer is positioned between the first electrode and the second electrode. The EL layer includes a light-emitting layer and an electron-transport layer. The electron-transport layer is positioned between the light-emitting layer and the second electrode. The electron-transport layer includes an organometallic complex of an alkali metal and an organic compound having an electron-transport property. The organometallic complex and the organic compound form an exciplex in combination. A peak wavelength of an emission spectrum of the exciplex formed with the organometallic complex and the organic compound having a mass ratio of 1:1 is greater than or equal to 610 nm.

Another embodiment of the present invention is a light-emitting device with any of the above structures, in which the organometallic complex of an alkali metal is an organometallic complex of lithium.

Another embodiment of the present invention is a light-emitting device with any of the above structures, in which the organometallic complex of an alkali metal includes a ligand having a quinolinol skeleton.

Another embodiment of the present invention is a light-emitting device with any of the above structures, in which the organometallic complex of an alkali metal is 8-hydroxyquinolinato-lithium or a derivative thereof.

Another embodiment of the present invention is a light-emitting device including a first electrode, a second electrode, and an EL layer. The EL layer is positioned between the first electrode and the second electrode. The EL layer includes a light-emitting layer and an electron-transport layer. The electron-transport layer is positioned between the light-emitting layer and the second electrode. The electron-transport layer includes an organometallic complex of an alkali metal and an organic compound having an electron-transport property. A difference between a HOMO level of the organometallic complex and a LUMO level of the organic compound is less than or equal to 2.9 eV. When a mixed film of the organometallic complex and the organic compound is analyzed by mass spectrometry, a value obtained by subtracting 2 from the sum of a molecular weight of the organometallic complex, a molecular weight of the organic compound, and an atomic weight of an alkaline earth metal contained in the organometallic complex is observed as m/z.

Another embodiment of the present invention is a light-emitting device with the above structure, in which the organometallic complex of an alkali metal is an organometallic complex of lithium.

Another embodiment of the present invention is a light-emitting device with the above structure, in which the organometallic complex of an alkali metal is 8-hydroxyquinolinato-lithium.

Another embodiment of the present invention is a light-emitting device with the above structure, in which the organometallic complex and the organic compound form an exciplex.

Another embodiment of the present invention is a light-emitting device with the above structure, in which a value (eV) obtained by converting into energy a peak wavelength of an emission spectrum of the exciplex formed with the organometallic complex and the organic compound having a mass ratio of 1:1 is smaller than the difference (eV) between the HOMO level of the organometallic complex and the LUMO level of the organic compound by greater than or equal to 0.1 eV.

Another embodiment of the present invention is a light-emitting device with the above structure, in which the peak wavelength of the emission spectrum of the exciplex formed with the organometallic complex and the organic compound having a mass ratio of 1:1 is greater than or equal to 570 nm.

Another embodiment of the present invention is a light-emitting device with the above structure, in which the peak wavelength of the emission spectrum of the exciplex formed with the organometallic complex and the organic compound having a mass ratio of 1:1 is greater than or equal to 570 nm and less than 610 nm.

Another embodiment of the present invention is a light-emitting device with the above structure, in which the peak wavelength of the emission spectrum of the exciplex formed with the organometallic complex and the organic compound having a mass ratio of 1:1 is greater than or equal to 610 nm.

Another embodiment of the present invention is a light-emitting device with any of the above structures, in which the organic compound has a heteroaromatic ring.

Another embodiment of the present invention is a light-emitting device with any of the above structures, in which the electron-transport layer is in contact with the light-emitting layer.

Another embodiment of the present invention is the light-emitting device in which the light-emitting layer contains a host material and a light-emitting material, and the light-emitting material emits blue fluorescent light.

Another embodiment of the present invention is an electronic device including any of the above light-emitting devices, and a sensor, an operation button, a speaker, or a microphone.

Another embodiment of the present invention is a light-emitting apparatus including any of the above light-emitting devices, and a transistor or a substrate.

Another embodiment of the present invention is a lighting device including any of the above light-emitting devices and a housing.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, in some cases, lighting equipment or the like includes the light-emitting apparatus.

### Effect of the Invention

According to one embodiment of the present invention, a novel light-emitting device can be provided. A light-emitting device with a long lifetime can be provided. A light-emitting device with high emission efficiency can be provided.

According to another embodiment of the present invention, a light-emitting apparatus, an electronic device, and a display device each having high reliability can be provided. According to another embodiment of the present invention, a light-emitting apparatus, an electronic device, and a display device each having low power consumption can be provided.

Note that the description of these effects does not preclude the existence of other effects. One embodiment of the present invention does not have to have all of these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A, FIG. 1B, and FIG. 1C are diagrams of light-emitting devices.

FIG. 2A and FIG. 2B are diagrams of an active matrix light-emitting apparatus.

FIG. 3A and FIG. 3B are diagrams of active matrix light-emitting apparatuses.

FIG. 4 is a diagram of an active matrix light-emitting apparatus.

FIG. 5A and FIG. 5B are diagrams showing a lighting device.

FIG. 6A, FIG. 6B1, FIG. 6B2, and FIG. 6C are diagrams showing electronic devices.

FIG. 7A, FIG. 7B, and FIG. 7C are diagrams showing electronic devices.

FIG. 8 is a diagram showing a lighting device.

FIG. 9 is a diagram showing a lighting device.

FIG. 10 is a diagram showing in-vehicle display devices and lighting devices.

FIG. 11A, FIG. 11B, and FIG. 11C are diagrams showing an electronic device.

FIG. 12A and FIG. 12B are diagrams showing an electronic device.

FIG. 13 is a graph showing the luminance-current density characteristics of a light-emitting device 1, a light-emitting device 2, and a comparative light-emitting device 1.

FIG. 14 is a graph showing the current efficiency-luminance characteristics of the light-emitting device 1, the light-emitting device 2, and the comparative light-emitting device 1.

FIG. 15 is a graph showing the luminance-voltage characteristics of the light-emitting device 1, the light-emitting device 2, and the comparative light-emitting device 1.

FIG. 16 is a graph showing the current-voltage characteristics of the light-emitting device 1, the light-emitting device 2, and the comparative light-emitting device 1.

FIG. 17 is a graph showing the external quantum efficiency-luminance characteristics of the light-emitting device 1, the light-emitting device 2, and the comparative light-emitting device 1.

FIG. 18 is a graph showing the emission spectra of the light-emitting device 1, the light-emitting device 2, and the comparative light-emitting device 1.

FIG. 19 is a graph showing the time dependence of normalized luminance of the light-emitting device 1, the light-emitting device 2, and the comparative light-emitting device 1.

FIG. 20 shows the emission spectra of an OCET010Q film, a Liq film, and a mixed film of OCET010 and Liq mixed at a mass ratio of 1:1.

FIG. 21 shows the emission spectra of an NBPhen film, a Liq film, and a mixed film of NBPhen and Liq mixed at a mass ratio of 1:1.

FIG. 22 shows the emission spectra of an αN-βNPAnth film, a Liq film, and a mixed film of αN-βNPAnth and Liq mixed at a mass ratio of 1:1.

FIG. 23 shows the results of analyzing the mixed film of NBPhen and Liq by ToF-SIMS.

FIG. 24 is a graph showing the luminance-current density characteristics of a light-emitting device 3.

FIG. 25 is a graph showing the current efficiency-luminance characteristics of the light-emitting device 3.

FIG. 26 is a graph showing the luminance-voltage characteristics of the light-emitting device 3.

FIG. 27 is a graph showing the current-voltage characteristics of the light-emitting device 3.

FIG. 28 is a graph showing the external quantum efficiency-luminance characteristics of the light-emitting device 3.

FIG. 29 is a graph showing the emission spectrum of the light-emitting device 3.

FIG. 30 is a graph showing the time dependence of normalized luminance of the light-emitting device 3.

FIG. 31 shows the emission spectra of a PyA1PQ film, a Liq film, and a mixed film of PyA1PQ and Liq mixed at a mass ratio of 1:1.

FIG. 32 shows the results of analyzing the mixed film of PyA1PQ and Liq by ToF-SIMS.

FIG. 33 is a graph showing the oxidation-reduction wave of OCET010.

FIG. 34 is a graph showing the reduction-oxidation wave of OCET010.

FIG. 35 is a graph showing the oxidation-reduction wave of NBPhen.

FIG. 36 is a graph showing the reduction-oxidation wave of NBPhen.

FIG. 37 is a graph showing the oxidation-reduction wave of Liq.

FIG. 38A and FIG. 38B are graphs each showing the reduction-oxidation wave of Liq.

FIG. 39 is a graph showing the oxidation-reduction wave of PyA1PQ.

FIG. 40 is a graph showing the reduction-oxidation wave of PyA1PQ.

FIG. 41 is a graph showing the luminance-current density characteristics of a light-emitting device 4.

FIG. 42 is a graph showing the luminance-voltage characteristics of the light-emitting device 4.

FIG. 43 is a graph showing the current efficiency-luminance characteristics of the light-emitting device 4.

FIG. 44 is a graph showing the current-voltage characteristics of the light-emitting device 4.

FIG. 45 is a graph showing the external quantum efficiency-luminance characteristics of the light-emitting device 4.

FIG. 46 is a graph showing the emission spectrum of the light-emitting device 4.

FIG. 47 is a graph showing the time dependence of normalized luminance of the light-emitting device 4.

FIG. 48 is a graph showing the emission spectra of a mPn-mDMePyPTzn film, a Liq film, and a mixed film of mPn-mDMePyPTzn and Liq mixed at a mass ratio of 1:1.

FIG. 49 is a graph showing the reduction-oxidation wave of mPn-mDMePyPTzn.

FIG. 50 is a graph showing the luminance-current density characteristics of a light-emitting device 5, a light-emitting device 6, and a light-emitting device 7.

FIG. 51 is a graph showing the luminance-voltage characteristics of the light-emitting device 5, the light-emitting device 6, and the light-emitting device 7.

FIG. 52 is a graph showing the current efficiency-luminance characteristics of the light-emitting device 5, the light-emitting device 6, and the light-emitting device 7.

FIG. 53 is a graph showing the current-voltage characteristics of the light-emitting device 5, the light-emitting device 6, and the light-emitting device 7.

FIG. 54 is a graph showing the external quantum efficiency-luminance characteristics of the light-emitting device 5, the light-emitting device 6, and the light-emitting device 7.

FIG. 55 is a graph showing the emission spectra of the light-emitting device 5, the light-emitting device 6, and the light-emitting device 7.

FIG. 56 is a graph showing the time dependence of normalized luminance of the light-emitting device 5, the light-emitting device 6, and the light-emitting device 7.

FIG. 57 shows the emission spectra of an αN-βNPAnth film, a Li-4mq film, and a mixed film of αN-βNPAnth and Liq mixed at a mass ratio of 1:1.

FIG. 58 shows the emission spectra of a mPn-mDMePyPTzn film, a Li-4mq film, and a mixed film of mPn-mDMePyPTzn and Liq mixed at a mass ratio of 1:1.

FIG. 59 shows the emission spectra of a PyA1PQ film, a Li-4mq film, and a mixed film of PyA1PQ and Li-4mq mixed at a mass ratio of 1:1.

FIG. 60 is a graph showing the oxidation-reduction wave of αN-βNPAnth.

FIG. 61 is a graph showing the reduction-oxidation wave of αN-βNPAnth.

FIG. 62 is a graph showing the oxidation-reduction wave of Li-4mq.

FIG. 63 is a graph showing the reduction-oxidation wave of Li-4mq.

### MODE FOR CARRYING OUT THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

### EMBODIMENT 1

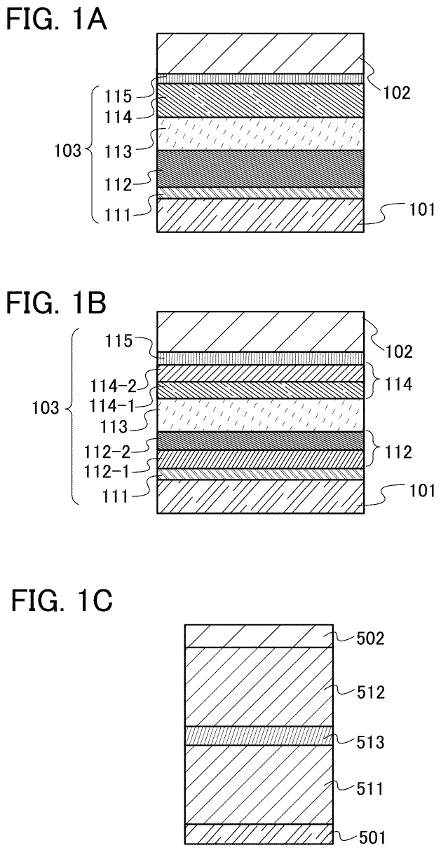

FIG. 1A illustrates a light-emitting device of one embodiment of the present invention. The light-emitting device of one embodiment of the present invention includes an anode 101, a cathode 102, and an EL layer 103, and the EL layer includes at least a light-emitting layer 113 and an electron-transport layer 114.

Although the EL layer 103 in FIG. 1A includes a hole-injection layer 111, a hole-transport layer 112, and an electron-injection layer 115 in addition to the light-emitting layer 113 and the electron-transport layer 114, the structure of the EL layer 103 is not limited thereto. As in FIG. 1B, the hole-transport layer 112 may include a first hole-transport layer 112-1 and a second hole-transport layer 112-2, and the electron-transport layer 114 may include a first electron-transport layer 114-1 and a second electron-transport layer 114-2.

In the light-emitting device of one embodiment of the present invention, the electron-transport layer 114 includes an organic compound having an electron-transport property and an organometallic complex of an alkali metal. Note that the mixture ratio thereof is preferably 3:7 to 7:3 (mass ratio).

The organic compound having an electron-transport property and the organometallic complex of an alkali metal preferably form an exciplex in combination. In that case, a value (E_{Ex}) obtained by converting into energy a peak wavelength (λp_{Ex}) of an emission spectrum of the exciplex formed with the organic compound having an electron-transport property and the organometallic complex of an alkali metal having a mass ratio of 1:1 is preferably smaller than a difference (ΔE_{LUMO-HOMO}) between the LUMO level of the organic compound having an electron-transport property and the HOMO level of Liq, which is the organometallic complex of an alkali metal, by greater than or equal to 0.1 eV, further preferably by greater than or equal to 0.3 eV, and still further preferably by greater than or equal to 0.5 eV.

The peak wavelength can be converted into energy using the formula E [eV]=1240/λ [nm], which is obtained from the energy formula (E=hv=hc/λ, where E is energy [J], h is the Plank constant (6.626×10⁻³⁴ [J·s]), v is the number of vibrations, c is the speed of light (2.998×10⁸ [m/s]), and λ is the wavelength [m]) and the elementary charge (1.602×10⁻¹⁹ [J]).

It is suggested that in the light-emitting device of one embodiment of the present invention having such a structure, the organic compound having an electron-transport property and the organometallic complex of an alkali metal form an exciplex and interaction other than the formation of the exciplex further occurs. The interaction probably has an influence on the element property of the light-emitting device of one embodiment of the present invention, allowing the light-emitting device to have a long lifetime.

When the electron-transport layer or a film formed by mixing the organic compound having an electron-transport property and the organometallic complex of an alkali metal included in the electron-transport layer at a ratio similar to that in the electron-transport layer is measured by time-of-flight secondary ion mass spectrometry (TOF-SIMS), mass spectrometry using laser desorption/ionization-time of flight (LDI-TOF), or the like, the light-emitting device of one embodiment of the present invention is found to show a distinctive result. That is, positive ions are detected at mass-to-charge ratio m/z=M_{E}+M_{ACom}+M_{A}−2 as the result of the mass spectrometry, when M_{E}, M_{ACom}, and MA denote the molecular weight of the organic compound having an electron-transport property, the molecular weight of the organometallic complex of an alkali metal, and the molecular weight of the alkali metal, respectively.

In the case where positive ions (positive) are measured by the aforementioned mass spectrometry, detected ions are generally derived from molecules included in the film, substituents desorbed from the molecules, the molecules from which the substituents have been desorbed, and association thereof. Hence, the sum M (corresponding to M_{E}+M_{ACom}+MA in the light-emitting device of one embodiment of the present invention) of the molecular weight of substituents of the molecules, molecules from which the substituents have been desorbed, and the like or M+1 is detected as m/z and ions corresponding to M−2 are hardly detected in general.

That is, detection of the ions M−2 in the measurement of positive ions (positive) is a distinctive result as the analysis result of the light-emitting device of one embodiment of the present invention. Note that also in such a light-emitting device, the organic compound having an electron-transport property and the organometallic complex of an alkali metal included in the electron-transport layer preferably form an exciplex in combination. When the organometallic complex of an alkali metal is measured by ToF-SIMS, mass-to-charge ratio m/z=M_{ACom}+M_{A} is detected in some cases. In that case, the association described above is probably association of the organic compound and M_{ACom}+M_{A} ions that are generated by ionization of the organometallic complex of an alkali metal.

A light-emitting device whose ΔE_{LUMO-HOMO} (difference between the LUMO level of the organic compound having an electron-transport property and the HOMO level of the organometallic complex of an alkali metal) described above is less than or equal to 2.90 eV is a preferable mode because the organic compound having an electron-transport property and the organometallic complex of an alkali metal included in the electron-transport layer easily form an exciplex.

A light-emitting device whose peak wavelength (λp_{Ex}) in an emission spectrum of an exciplex formed with the organic compound having an electron-transport property and the organometallic complex of an alkali metal included in the electron-transport layer is greater than or equal to 570 nm has a small slope of long-term decay and is less likely to degrade in long-term driving.

A light-emitting device whose peak wavelength (λp_{Ex}) in the emission spectrum of the exciplex is greater than or equal to 570 nm and less than 610 nm has a small slope of long-term decay and undergoes an increase in luminance at the initial driving stage, so that the initial decay can be canceled out to obtain a longer-lifetime light-emitting device.

A light-emitting device whose peak wavelength (λp_{Ex}) in the emission spectrum of the exciplex is greater than or equal to 610 nm can have a small slope of long-term decay and high emission efficiency.

As the organic compound having an electron-transport property, an organic compound whose electron-transport property is more dominant than the hole-transport property can be used. The electron mobility of the organic compound having an electron-transport property when the square root of the electric field strength [V/cm] is 600 is preferably higher than or equal to 1×10⁷ cm²/Vs and lower than or equal to 5×10⁻⁵ cm²/Vs. Lowering the electron-transport property of the electron-transport layer enables control of the amount of electrons injected into the light-emitting layer and can prevent the light-emitting layer from having excess electrons.

The organic compound having an electron-transport property preferably has an electron-transport property and a HOMO level of higher than or equal to −6.0 eV.

As the material having an electron-transport property, specifically, 2,9-di(2-naphthyl)-4,7-diphenyl-1,10-phenanthroline (abbreviation: NBPhen), 2-phenyl-3-[10-(3-pyridyl)-9-anthryl]phenylquinoxaline (abbreviation: PyA1PQ), or the like is preferable and PyA1PQ is particularly preferable. Furthermore, a metal complex such as bis(10-hydroxybenzo[h]quinolinato)beryllium(II) (abbreviation: BeBq2), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring skeleton is preferable. Examples of the organic compound having a π-electron deficient heteroaromatic ring skeleton include a heterocyclic compound having a polyazole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II); a heterocyclic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), or 4,6-bis[3-(4-dibenzothienyl)phenyl]pyrimidine (abbreviation: 4,6mDBTP2Pm-II); a heterocyclic compound having a triazine skeleton, such as 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnfBPTzn-02); and a heterocyclic compound having a pyridine skeleton, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB). In addition, anthracene derivatives such as 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), and 9-phenyl-10-{4-(9-phenyl-9H-fluoren-9-yl)biphenyl-4′-yl}anthracene (abbreviation: FLPPA), and the like can be given. From these materials, a material that will form an exciplex together with an organometallic complex of an alkali metal or a material whose LUMO level differs from the HOMO level of the organometallic complex of an alkali metal by less than or equal to 2.90 eV is selected and used. Among the above, the heterocyclic compound having a diazine skeleton, the heterocyclic compound having a triazine skeleton, and the heterocyclic compound having a pyridine skeleton are preferable in terms of driving lifetime because they are likely to form an exciplex with an organometallic complex of an alkali metal with stable energy (the emission wavelength of the exciplex easily becomes longer). In particular, the heterocyclic compound having a diazine skeleton and the heterocyclic compound having a triazine skeleton have deep LUMO level and thus are preferred for stabilization of energy of an exciplex.

Note that the organometallic complex of an alkali metal is preferably an organometallic complex of lithium. Alternatively, the organometallic complex of an alkali metal preferably has a ligand having a quinolinol skeleton. Further preferably, the organometallic complex of an alkali metal is 8-hydroxyquinolinato-lithium or a derivative thereof.

In the light-emitting device of one embodiment of the present invention, the light-emitting layer 113 contains a light-emitting material. Note that the light-emitting layer 113 may further contain a host material for dispersing a light-emitting material.

The light-emitting material may be a fluorescent substance, a phosphorescent substance, a substance exhibiting thermally activated delayed fluorescence (TADF), or any other light-emitting material. Furthermore, the light-emitting layer 113 may be a single layer or formed of a plurality of layers. Note that one embodiment of the present invention is more suitably used in the case where the light-emitting layer 113 exhibits fluorescence, specifically, blue fluorescence. On the other hand, one embodiment of the present invention can be used for a light-emitting device that emits any color light, and can also be used for light-emitting devices (light-emitting elements) of different colors.

Examples of a material that can be used as a fluorescent substance in the light-emitting layer 113 include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N′-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N,N-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,N,N′,N′,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(1,1′-biphenyl-2-yl)-2-anthryl]-N′,N-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N-(1,6-pyrene-diyl)bis[(6-diphenylbenzo[b]naphtho[1,2-d]furan)-8-amine] (abbreviation:1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). In particular, a condensed aromatic diamine compound typified by a pyrenediamine compound such as 1,6FLPAPrn, 1,6mMemFLPAPrn, and 1,6BnfAPrn-03 is preferable because of its high hole-trapping property, high emission efficiency, and high reliability.

In the case where a phosphorescent substance is used as an emission center material in the light-emitting layer 113, examples of the material that can be used include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), and tris[4-(3-biphenyl)-5-isopropyl-3-phenyl-4H-1,2,4-triazolato]iridium(III) (abbreviation: [Jr(iPrptz-3b)₃]); an organometallic iridium complex having a 1H-triazole skeleton, such as tris[3-methyl-1-(2-methylphenyl)-5-phenyl-1H-1,2,4-triazolato]iridium(III) (abbreviation: [Jr(Mptz1-mp)₃]) and tris(1-methyl-5-phenyl-3-propyl-1H-1,2,4-triazolato)iridium(III) (abbreviation: [Jr(Prptz1-Me)₃]); an organometallic iridium complex having an imidazole skeleton, such as fac-tris[(1-2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Jr(dmpimpt-Me)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C²]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac). These are compounds exhibiting blue phosphorescent light, and are compounds having an emission peak at 440 nm to 520 nm.

Examples of the material that can be used in the light-emitting layer 113 also include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Jr(tBuppm)₃]), (acetylacetonato)bis(6-methyl-4-phenylpyrimidinato)iridium(III) (abbreviation: [Jr(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Jr(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), or bis(2-phenylquinolinato-N,C^{2′})iridium(III) acetylacetonate (abbreviation: [Ir(pq)₂(acac)]); and a rare earth metal complex such as tris(acetylacetonato)(monophenanthroline)terbium(III) (abbreviation: [Tb(acac)₃(Phen)]). These are compounds that mainly exhibit green phosphorescent light, and have an emission peak at 500 nm to 600 nm. Note that an organometallic iridium complex having a pyrimidine skeleton is particularly preferable because of its distinctively high reliability and emission efficiency.

Examples of the material that can be used in the light-emitting layer 113 also include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]) or bis(1-phenylisoquinolinato-N,C^{2′})iridium(III) acetylacetonate (abbreviation: [Ir(piq)₂(acac)]); a platinum complex such as 2,3,7,8,12,13,17,18-octaethyl-21H,23H-porphyrin platinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[l-(2-thenoyl)-3,3,3-trifluoroacetonato](monophenanthroline)europium(III) (abbreviation: [Eu(TTA)₃(Phen)]). These are compounds exhibiting red phosphorescent light, and have an emission peak at 600 nm to 700 nm. Furthermore, from the organometallic iridium complex having a pyrazine skeleton, red light emission with favorable chromaticity can be obtained.

Besides the above-described phosphorescent compounds, other known phosphorescent materials may be selected and used.

As the TADF material, a fullerene, a derivative thereof, an acridine, a derivative thereof, an eosin derivative, or the like can be used. Other examples include a metal-containing porphyrin containing magnesium (Mg), zinc (Zn), cadmium (Cd), tin (Sn), platinum (Pt), indium (In), palladium (Pd), or the like. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂(OEP)), which are represented by the following structural formulae.

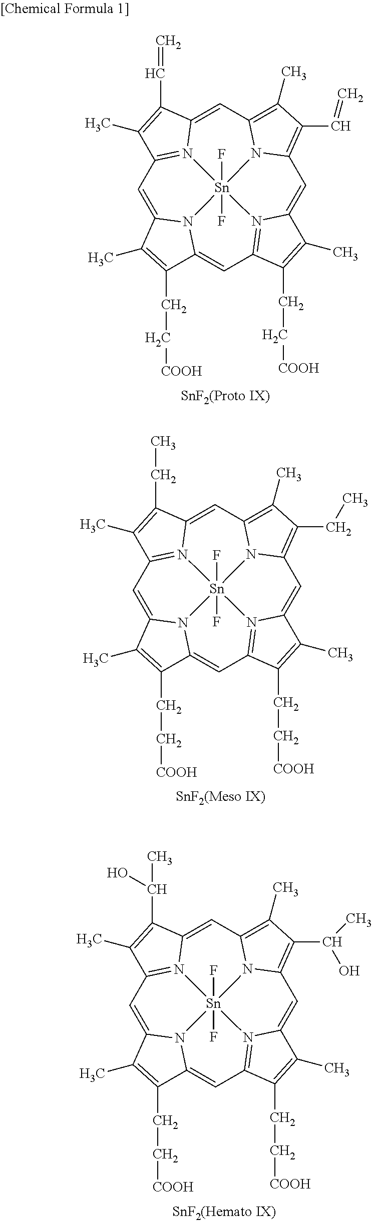

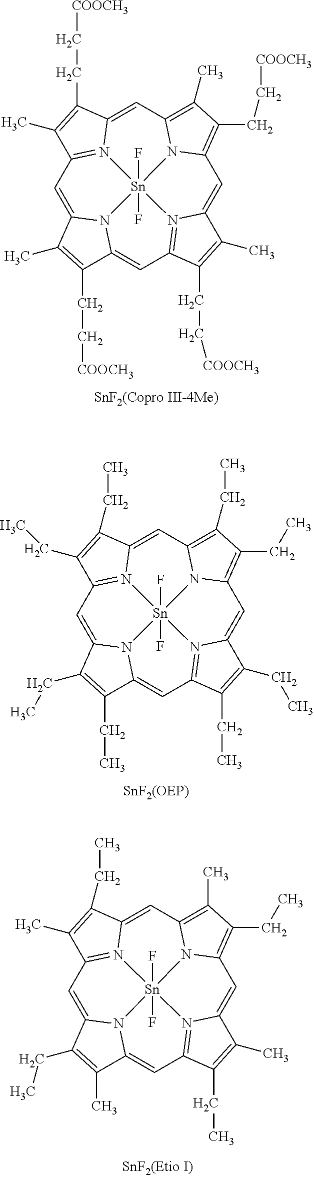

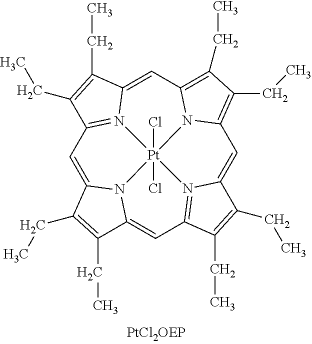

It is also possible to use a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 9-[4-(4,6-diphenyl-1,3,5-triazin-2-yl)phenyl]-9′-phenyl-9H,9′H-3,3′-bicarbazol (abbreviation: PCCzPTzn), 2-[4-(10H-phenoxazine-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). These heterocyclic compounds are preferable because of having both a high electron-transport property and a high hole-transport property owing to the π-electron rich heteroaromatic ring and the π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are particularly preferable because of their stability and favorable reliability. In particular, a benzofuropyrimidine skeleton, a benzothienopyrimidine skeleton, a benzofuropyrazine skeleton, and a benzothienopyrazine skeleton are preferable because of their high acceptor property and favorable reliability. Among skeletons having a π-electron rich heteroaromatic ring, an acridine skeleton, a phenoxazine skeleton, a phenothiazine skeleton, a furan skeleton, a thiophene skeleton, and a pyrrole skeleton have stability and favorable reliability; therefore, at least one of these skeletons is preferably included. Note that a dibenzofuran skeleton and a dibenzothiophene skeleton are preferable as the furan skeleton and the thiophene skeleton, respectively. As the pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which a π-electron rich heteroaromatic ring and a π-electron deficient heteroaromatic ring are directly bonded to each other is particularly preferable because the electron-donating property of the π-electron rich heteroaromatic ring and the electron-accepting property of the π-electron deficient heteroaromatic ring are both increased and the energy difference between the S1 level and the T1 level becomes small, and thus thermally activated delayed fluorescence can be obtained efficiently. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a boron-containing skeleton such as phenylborane or boranthrene, an aromatic ring or a heteroaromatic ring having a nitrile group or a cyano group, such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

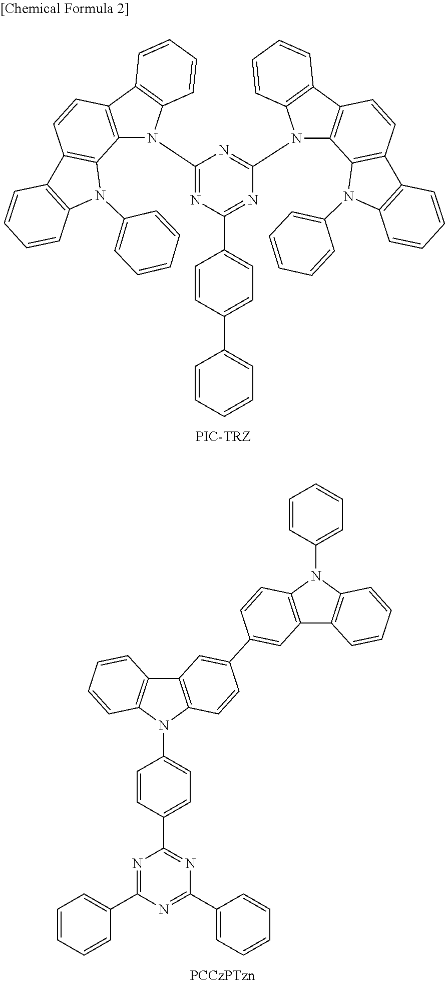 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

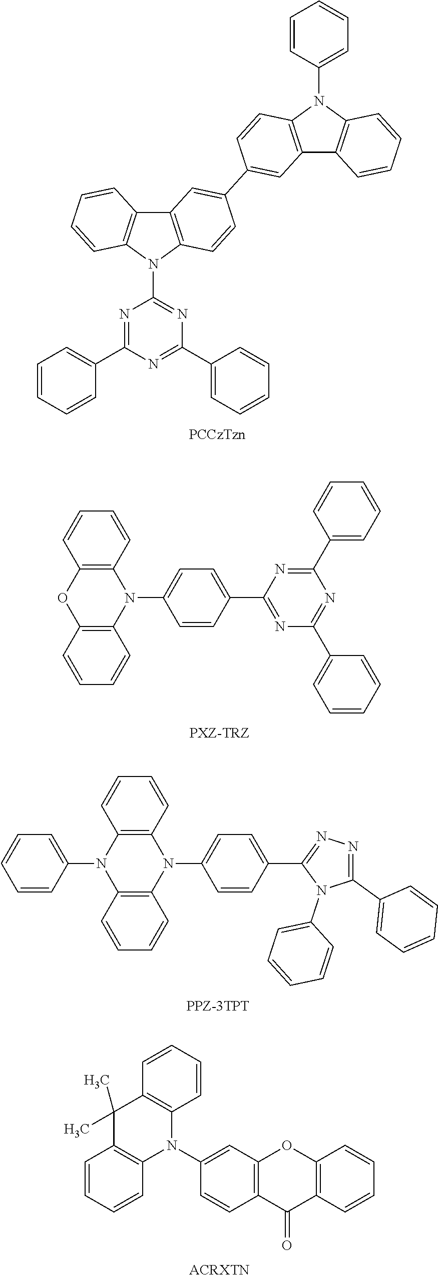 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21]

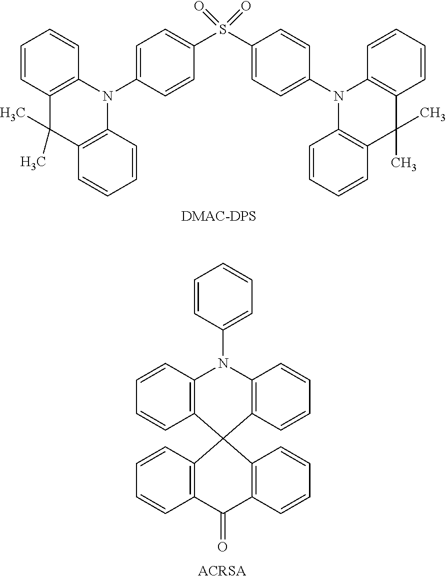 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Note that the TADF material is a material that has a small difference between the S1 level and the T1 level and has a function of converting triplet excitation energy into singlet excitation energy by reverse intersystem crossing. Thus, it is possible to upconvert triplet excitation energy into singlet excitation energy (reverse intersystem crossing) using a little thermal energy and to efficiently generate a singlet excited state. In addition, the triplet excitation energy can be converted into light emission.

An exciplex whose excited state is formed by two kinds of substances has an extremely small difference between the S1 level and the T1 level and has a function of a TADF material that can convert triplet excitation energy into singlet excitation energy.

Note that a phosphorescent spectrum observed at low temperatures (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably less than or equal to 0.3 eV, further preferably less than or equal to 0.2 eV.

When the TADF material is used as an emission center material, the S1 level of the host material is preferably higher than the S1 level of the TADF material. In addition, the T1 level of the host material is preferably higher than the T1 level of the TADF material.

As the host material in the light-emitting layer 113, various carrier-transport materials such as a material having an electron-transport property, a material having a hole-transport property, and the TADF material can be used.

The material having a hole-transport property that can be used as the host material is preferably an organic compound having an amine skeleton or a π-electron rich heteroaromatic ring skeleton. Examples include a compound having an aromatic amine skeleton, such as 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]spiro-9,9′-bifluoren-2-amine (abbreviation: PCBASF), or N-[4-(9-phenyl-9H-carbazol-3-yl)phenyl]-bis(9,9-dimethyl-9H-fluoren-2-yl)amine (abbreviation: PCBFF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above, the compound having an aromatic amine skeleton and the compound having a carbazole skeleton are preferable because these have favorable reliability, have high hole-transport property, and contribute to a reduction in driving voltage. It is also possible to use the hole-transport materials given above as examples of the second substance. Among the compounds having a carbazole skeleton, a compound having a 3,3′-bi(9H-carbazol) skeleton is particularly preferable because it has high reliability and hole-transport property, and contributes to a reduction in driving voltage.

The material having an electron-transport property that can be used as the host material is preferably, for example, a metal complex such as bis(10-hydroxybenzo[h]quinolinato)beryllium(II) (abbreviation: BeBq2), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring skeleton. Examples of the organic compound having a π-electron deficient heteroaromatic ring skeleton include a heterocyclic compound having a polyazole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II); a heterocyclic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 8-(1,1′-biphenyl-4-yl)-4-[3′-(dibenzothiophen-4-yl)biphenyl-3-yl]-[1]benzofuro[3,2-d]pyrimidine (abbreviation: 8BP-4mDBtBPBfpm), 11-[(3′-(dibenzothiophen-4-yl)biphenyl-3-yl]phenanthro[9′,10′:4,5]furo[2,3-b]pyrazine (abbreviation: 11mDBtBPPnfpr), 9-[(3′-dibenzothiophen-4-yl)biphenyl-3-yl]naphtho[1′,2′:4,5]furo[2,3-b]pyrazine (abbreviation: 9mDBtBPNfpr), or 9-phenyl-9′-(4-phenyl-2-quinazolinyl)-3,3′-bi-9H-carbazole (abbreviation: PCCzQz); a heterocyclic compound having a pyridine skeleton, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB); 2-[3′-(triphenylen-2-yl)-1,1′-biphenyl-3-yl]-4,6-diphenyl-1,3,5-triazine (abbreviation: mTpBPTzn); and 11-(4-[1,1′-biphenyl]-4-yl-6-phenyl-1,3,5-triazin-2-yl)-11,12-dihydro-12-phenyl-indolo[2,3-a]carbazole (abbreviation: BP-Icz(II)Tzn). Among the above, the heterocyclic compound having a triazine skeleton, the heterocyclic compound having a diazine skeleton, and the heterocyclic compound having a pyridine skeleton have favorable reliability and thus are preferable. In particular, the heterocyclic compound having a triazine skeleton or a diazine (pyrimidine or pyrazine) skeleton has a high electron-transport property and contributes to a reduction in driving voltage.

As the TADF material that can be used as the host material, the above-mentioned materials given as TADF materials can also be used. When the TADF material is used as the host material, triplet excitation energy generated in the TADF material is converted into singlet excitation energy by reverse intersystem crossing and transferred to the emission center substance, whereby the emission efficiency of the light-emitting device can be increased. At this time, the TADF material functions as an energy donor, and the emission center substance functions as an energy acceptor.

This is very effective in the case where the emission center substance is a fluorescent substance. In that case, the S1 level of the TADF material is preferably higher than the S1 level of the fluorescent substance in order to achieve high emission efficiency. Furthermore, the T1 level of the TADF material is preferably higher than the S1 level of the fluorescent substance. Therefore, the T1 level of the TADF material is preferably higher than the T1 level of the fluorescent substance.

It is also preferable to use a TADF material that exhibits light emission overlapping with the wavelength of a lowest-energy-side absorption band of the fluorescent substance. This enables smooth transfer of excitation energy from the TADF material to the fluorescent substance and accordingly enables efficient light emission.

In order that singlet excitation energy is efficiently generated from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that causes light emission) of the fluorescent substance. As the protective group, a substituent having no π bond and saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituent having no π bond has a poor carrier-transport property; thus, the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring. Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the emission center substance, a material having an anthracene skeleton is preferable as the host material. The use of a substance having an anthracene skeleton as a host material for a fluorescent substance makes it possible to achieve a light-emitting layer with favorable emission efficiency and durability. As the substance having an anthracene skeleton that can be used as the host material, a substance having a diphenylanthracene skeleton, in particular, a substance having a 9,10-diphenylanthracene skeleton, is preferable because of its chemical stability. The host material preferably has a carbazole skeleton because the hole-injection and hole-transport properties are improved; further preferably, the host material has a benzocarbazole skeleton in which a benzene ring is further condensed to carbazole because the HOMO level thereof is shallower than that of carbazole by approximately 0.1 eV and thus holes enter the host material easily. In particular, the host material having a dibenzocarbazole skeleton is preferable because its HOMO level is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, a benzofluorene skeleton or a dibenzofluorene skeleton may be used instead of a carbazole skeleton. Examples of such a substance include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), and 9-(1-naphthyl)-10-[4-(2-naphthyl)phenyl]anthracene (abbreviation: αN-βNPAnth). In particular, CzPA, cgDBCzPA, 2mBnfPPA, and PCzPA are preferably selected because they exhibit highly favorable characteristics.

Note that a host material may be a material of a mixture of a plurality of kinds of substances; in the case of using a mixed host material, it is preferable to mix a material having an electron-transport property with a material having a hole-transport property. When the material having an electron-transport property is mixed with the material having a hole-transport property, the transport property of the light-emitting layer 113 can be easily adjusted and a recombination region can be easily controlled. The mass ratio of the content of the material having a hole-transport property to the content of the material having an electron-transport property may be the material having a hole-transport property: the material having an electron-transport property=1:19 to 19:1.

Note that a phosphorescent substance can be used as part of the mixed material. When a fluorescent substance is used as the emission center material, a phosphorescent substance can be used as an energy donor for supplying excitation energy to the fluorescent substance.

An exciplex may be formed by these mixed materials. A combination is preferably selected so as to form an exciplex that exhibits light emission overlapping with the wavelength of a lowest-energy-side absorption band of a light-emitting substance, because energy can be transferred smoothly and light emission can be efficiently obtained. The use of the structure is preferable because the driving voltage is also be reduced.

Note that at least one of the materials forming an exciplex in the light-emitting layer may be a phosphorescent substance. In this case, triplet excitation energy can be efficiently converted into singlet excitation energy by reverse intersystem crossing.

In order to form an exciplex efficiently, a material having an electron-transport property and a material having a hole-transport property and a HOMO level higher than or equal to that of the material having an electron-transport property are preferably used in combination. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV). The HOMO level can also be obtained by ionization potential measurement (IP measurement) of a thin film. The HOMO level obtained by IP measurement and the optical band gap (energy (eV) calculated from the absorption edge on a long wavelength side of an absorption spectrum of the thin film) can be used to calculate the LUMO level. Specifically, the LUMO level is calculated by adding the energy (eV) calculated from the band gap to the HOMO level.

Note that the formation of an exciplex can be confirmed by comparing the spectrum of each of mixed materials (e.g., the emission spectrum of a material having a hole-transport property, the emission spectrum of a material having an electron-transport property, and the spectrum of an organometallic complex) with the emission spectrum of a mixed film in which these materials are mixed, and then observing a phenomenon in which the emission spectrum of the mixed film is shifted to a longer wavelength side than the emission spectrum of each of the materials (or has another peak on a longer wavelength side). Alternatively, the formation of an exciplex can be confirmed by comparing the transient photoluminescence (PL) of each of the mixed materials and the transient PL of the mixed film in which these materials are mixed, and then observing a difference in transient response in which the transient PL lifetime of the mixed film has longer lifetime components or has a larger proportion of delayed components than the transient PL lifetime of each of the materials. The transient PL can be rephrased as transient electroluminescence (EL). That is, the formation of an exciplex can also be confirmed by comparing the transient EL of each of the mixed materials and the transient EL of the mixed film of the materials, and then observing a difference in transient response.

Next, the other layers that can be used in the EL layer 103 will be described.

The hole-injection layer 111 facilitates injection of holes into the EL layer 103 and is formed using a material having a high hole-injection property. The hole-injection layer 111 may be formed using only an acceptor substance but is preferably formed using a composite material containing an acceptor substance and an organic compound having a hole-transport property.

The acceptor substance exhibits an electron-accepting property with respect to the organic compound having a hole-transport property contained in the hole-transport layer or the hole-injection layer.

Either an inorganic compound or an organic compound can be used as the acceptor substance, and an organic compound having an electron-withdrawing group (in particular, a cyano group or a halogen group such as a fluoro group) is preferably used, for example. Among the above substances, a substance exhibiting an electron-accepting property with respect to the organic compound having a hole-transport property contained in the hole-transport layer or the hole-injection layer is selected as the acceptor substance as appropriate.

Examples of such an acceptor substance include 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. In particular, a compound in which electron-withdrawing groups are bonded to a condensed aromatic ring having a plurality of heteroatoms, such as HAT-CN, is preferable because it is thermally stable. A [3]radialene derivative having an electron-withdrawing group (in particular, a cyano group or a halogen group such as a fluoro group) has a very high electron-accepting property and thus is preferable. Specific examples include organic compounds such as α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. When the acceptor substance is an inorganic compound, a transition metal oxide can also be used. An oxide of a metal belonging to Group 4 to Group 8 in the periodic table is particularly preferable; as the oxide of a metal belonging to Group 4 to Group 8 in the periodic table, vanadium oxide, niobium oxide, tantalum oxide, chromium oxide, molybdenum oxide, tungsten oxide, manganese oxide, rhenium oxide, or the like is preferably used because of their high electron-accepting properties. In particular, molybdenum oxide is preferable because it is stable in the air, has a low hygroscopic property, and is easily handled.

It is preferable that the organic compound having a hole-transport property used for the composite material have a relatively deep HOMO level greater than or equal to −5.7 eV and less than or equal to −5.4 eV. When the organic compound having a hole-transport property used for the composite material has a relatively deep HOMO level, induction of holes can be inhibited properly while the induced holes can be easily injected into the hole-transport layer 112.

The organic compound having a hole-transport property used for the composite material further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to nitrogen of the amine through an arylene group may be used. Note that these substances preferably have an N,N-bis(4-biphenyl)amino group because a light-emitting device with a long lifetime can be manufactured. Specific examples of the substances include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAβONB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenylyl)carbazole)}triphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(4-biphenylyl)-9,9′-spirobi[9H-fluoren]-2-amine (abbreviation: BBASF), N,N-bis(1,1′-biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), and N-(1,1′-biphenyl-4-yl)-9,9-dimethyl-N-[4-(9-phenyl-9H-carbazol-3-yl)phenyl]-9H-fluoren-2-amine (abbreviation: PCBBiF).

The hole mobility of the organic compound having a hole-transport property when the square root of the electric field strength [V/cm] is 600 is preferably lower than or equal to 1×10⁻³ cm²/Vs.

The composition ratio of the acceptor material to the organic compound having a hole-transport property in the composite material is preferably 1:0.01 to 1:0.15 (mass ratio), further preferably 1:0.01 to 1:0.1 (mass ratio).

The electron mobility of the electron-transport layer 114 when the square root of the electric field strength [V/cm] is 600 is preferably higher than or equal to 1×10⁻⁷ cm²/Vs and lower than or equal to 5×10⁻⁵ cm²/Vs.

Furthermore, the electron-transport layer 114 preferably includes an organometallic complex of an alkali metal, and further preferably has an 8-hydroxyquinolinato structure. In particular, a complex of a monovalent metal ion is preferable; specifically, 8-hydroxyquinolinato-lithium (abbreviation: Liq), 8-hydroxyquinolinato-sodium (abbreviation: Naq), or the like is preferably included. A lithium complex is particularly preferable, and Liq is further preferable. Note that in the case where the 8-hydroxyquinolinato structure is included, a methyl-substituted product (e.g., a 2-methyl-substituted product or a 5-methyl-substituted product) thereof or the like can also be used.

The concentration of the organometallic complex of an alkali metal preferably differs in the thickness direction of the electron-transport layer 114 (including the case where the concentration is 0). Accordingly, the light-emitting device can have longer lifetime and higher reliability.

Note that the HOMO level of the organic compound having an electron-transport property used for the electron-transport layer 114 is preferably higher than or equal to −6.0 eV.

The luminance decay curve of the light-emitting device having such a structure, which is obtained by a driving test at a constant current density, sometimes has a shape with a local maximum value, i.e., a shape where the luminance partly increases with time. The light-emitting device showing such a decay behavior enables a rapid decay at the initial driving stage, which is called initial decay, to be canceled out by the luminance increase, so that the light-emitting device can have an extremely long driving lifetime with a smaller initial decay. Such a light-emitting device is referred to as a recombination-site tailoring injection element (ReSTI element).

The hole-injection layer having the above-described structure contains an organic compound having a hole-transport property and a deep HOMO level; thus, the induced holes are easily injected into the hole-transport layer and the light-emitting layer. Accordingly, only some holes easily pass through the light-emitting layer to reach the electron-transport layer at the initial driving stage.

When the light-emitting device including the electron-transport layer that contains an organic compound having an electron-transport property and an organometallic complex of an alkali metal continuously emits light, a phenomenon in which electron-injection and electron-transport properties of the electron-transport layer are improved is observed. By contrast, since the induction of holes in the hole-injection layer is properly inhibited as described above, a large number of holes cannot be supplied to the electron-transport layer. As a result, the number of holes that can reach the electron-transport layer decreases over time, thereby increasing the probability of recombination of holes and electrons in the light-emitting layer. That is, the carrier balance shifts such that recombination occurs in the light-emitting layer more easily, while the light-emitting device continuously emits light. Such a shift offers the light-emitting device whose decay curve has a portion where the luminance increases with time and whose initial decay is inhibited.

The light-emitting device of one embodiment of the present invention having the above-described structure can have a significantly long lifetime. In particular, a lifetime in a region with an extremely small decay up to approximately LT95 can be significantly extended. Moreover, when a compound including a first skeleton having a function of transporting electrons, a second skeleton having a function of accepting holes, and a third skeleton that is a monocyclic π-electron deficient heteroaromatic ring is used as the organic compound having an electron-transport property, the light-emitting device can have an extremely small long-term decay and a long lifetime.

When the initial decay can be reduced, the problem of burn-in, which has still been mentioned as a great drawback of organic EL devices, and the time and effort for aging for reducing the problem before shipment can be significantly reduced.

The hole-transport layer 112 may be a single layer (FIG. 1A) but preferably includes the first hole-transport layer 112-1 and the second hole-transport layer 112-2 (FIG. 1). The hole-transport layer 112 may further include a plurality of hole-transport layers.

The hole-transport layer 112 can be formed using an organic compound having a hole-transport property. As the organic compound having a hole-transport property used for the hole-transport layer 112, the organic compound having a hole-transport property that can be used as the host material or the organic compound having a hole-transport property that can be used in the composite material can be used.

In the case where the hole-transport layer 112 includes a plurality of layers, the organic compound having a hole-transport property included in the hole-transport layer that is closer to the light-emitting layer 113 among the adjacent hole-transport layers preferably has a deeper HOMO level than the organic compound of the other hole-transport layer, and the difference between the HOMO levels is preferably less than or equal to 0.2 V.

In the case where the hole-injection layer 111 is formed using a composite material, the organic compound having a hole-transport property used for the hole-transport layer 112 in contact with the hole-injection layer 111 preferably has a deeper HOMO level than the organic compound having a hole-transport property used in the composite material, and the difference between the HOMO levels is preferably less than or equal to 0.2 eV.

Owing to such a relation between the HOMO levels, holes are injected into each layer smoothly, which prevents an increase in driving voltage and deficiency of holes in the light-emitting layer.

The organic compound having a hole-transport property used for the hole-transport layer 112 preferably includes a skeleton having a function of transporting holes. The skeleton having a function of transporting holes is preferably a carbazole skeleton, a dibenzofuran skeleton, a dibenzothiophene skeleton, or an anthracene skeleton, with which the HOMO level of the organic compound does not become too shallow, and a dibenzofuran skeleton is particularly preferable. The hole-injection layer 111 and adjacent layers in the plurality of hole-transport layers 112 preferably have the same skeleton, in which case holes can be injected smoothly. From the same reason, the hole-injection layer 111 and adjacent layers in the plurality of hole-transport layers 112 preferably contain the same organic compound having a hole-transport property.

In the case where a plurality of hole-transport layers are stacked, the first hole-transport layer 112-1 is closer to the anode 101 side than the second hole-transport layer 112-2 is. Note that the second hole-transport layer 112-2 also functions as an electron-blocking layer in some cases.

The light-emitting device of one embodiment of the present invention having the above-described structure can have a significantly long lifetime.

Next, examples of other structures and materials of the aforementioned light-emitting device will be described. As described above, the light-emitting device in this embodiment of the present invention includes, between the pair of electrodes of the anode 101 and the cathode 102, the EL layer 103 including a plurality of layers, and the EL layer 103 includes at least the light-emitting layer 113 and the electron-transport layer 114 from the anode 101 side. As the layers included in the EL layer 103, other various layer structures such as a hole-injection layer, a hole-transport layer, an electron-injection layer, a carrier-blocking layer, an exciton-blocking layer, and a charge-generation layer can be employed.

The anode 101 is preferably formed using a metal, an alloy, or a conductive compound having a high work function (specifically, 4.0 eV or more), a mixture thereof, or the like. Specifically, for example, indium oxide-tin oxide (ITO: Indium Tin Oxide), indium oxide-tin oxide containing silicon or silicon oxide, indium oxide-zinc oxide, indium oxide containing tungsten oxide and zinc oxide (IWZO), and the like can be given. These conductive metal oxide films are usually formed by a sputtering method but may also be formed by application of a sol-gel method or the like. An example of the formation method is a method in which indium oxide-zinc oxide is formed by a sputtering method using a target in which 1 to 20 wt % zinc oxide is added to indium oxide. Indium oxide containing tungsten oxide and zinc oxide (IWZO) can also be formed by a sputtering method using a target containing 0.5 to 5 wt % tungsten oxide and 0.1 to 1 wt % zinc oxide with respect to indium oxide. In addition, gold (Au), platinum (Pt), nickel (Ni), tungsten (W), chromium (Cr), molybdenum (Mo), iron (Fe), cobalt (Co), copper (Cu), palladium (Pd), a nitride of a metal material (such as titanium nitride), and the like can be given. Graphene can also be used. Although the typical materials that have a high work function and are used for forming the anode are listed above, a composite material of an organic compound having a hole-transport property and a substance exhibiting an electron-accepting property with respect to the organic compound is used for the hole-injection layer 111 of one embodiment of the present invention; thus, an electrode material can be selected regardless of its work function.

Since the hole-injection layer 111, the hole-transport layer 112 (the first hole-transport layer 112-1 and the second hole-transport layer 112-2), the light-emitting layer 113, and the electron-transport layer 114 are described in detail above, the description thereof is not repeated.

A layer containing an alkali metal, an alkaline earth metal, or a compound thereof such as lithium fluoride (LiF), cesium fluoride (CsF), or calcium fluoride (CaF₂) may be provided as the electron-injection layer 115 between the electron-transport layer 114 and the cathode 102. An electride or a layer that is formed using a substance having an electron-transport property and that includes an alkali metal, an alkaline earth metal, or a compound thereof can be used as the electron-injection layer 115. Examples of the electride include a substance in which electrons are added at high concentration to a mixed oxide of calcium and aluminum.

Instead of the electron-injection layer 115, a charge-generation layer may be provided between the electron-transport layer 114 and the cathode 102. The charge-generation layer refers to a layer capable of injecting holes into a layer in contact with the cathode side of the charge-generation layer and electrons into a layer in contact with the anode side thereof when a potential is applied. The charge-generation layer includes at least a p-type layer. The p-type layer is preferably formed using any of the composite materials given above as examples of the material that can be used for the hole-injection layer 111. The p-type layer may be formed by stacking a film containing the above-described acceptor material as a material included in the composite material and a film containing an organic compound having a hole-transport property. When a potential is applied to the p-type layer, electrons are injected into the electron-transport layer and holes are injected into the cathode 102 which is a cathode; thus, the light-emitting device operates.

Note that the charge-generation layer preferably includes one or both of an electron-relay layer and an electron-injection buffer layer in addition to the p-type layer.

The electron-relay layer contains at least a substance having an electron-transport property and has a function of preventing an interaction between the electron-injection buffer layer and the p-type layer to smoothly transfer electrons. The LUMO level of the substance having an electron-transport property contained in the electron-relay layer is preferably between the LUMO level of the electron-accepting substance in the p-type layer and the LUMO level of a substance contained in a layer of the electron-transport layer 114 that is in contact with the charge-generation layer. A specific energy level of the LUMO level of the substance having an electron-transport property used for the electron-relay layer is preferably higher than or equal to −5.0 eV, further preferably higher than or equal to −5.0 eV and lower than or equal to −3.0 eV. Note that as the substance having an electron-transport property used for the electron-relay layer, a phthalocyanine-based material or a metal complex having a metal-oxygen bond and an aromatic ligand is preferably used.

For the electron-injection buffer layer, a substance having a high electron-injection property, such as an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)), can be used.

In the case where the electron-injection buffer layer contains the substance having an electron-transport property and a substance having an electron-donating property, an organic compound such as tetrathianaphthacene (abbreviation: TTN), nickelocene, or decamethylnickelocene, as well as an alkali metal, an alkaline earth metal, a rare earth metal, or a compound thereof (an alkali metal compound (including an oxide such as lithium oxide, a halide, and a carbonate such as lithium carbonate and cesium carbonate), an alkaline earth metal compound (including an oxide, a halide, and a carbonate), or a rare earth metal compound (including an oxide, a halide, and a carbonate)), can be used as the substance having an electron-donating property. As the substance having an electron-transport property, a material similar to the above-described material forming the electron-transport layer 114 can be used.

As a substance forming the cathode 102, a metal, an alloy, or an electrically conductive compound with a low work function (specifically, 3.8 eV or less), a mixture thereof, or the like can be used. Specific examples of such a cathode material include elements belonging to Group 1 or Group 2 of the periodic table, such as alkali metals e.g., lithium (Li) and cesium (Cs), magnesium (Mg), calcium (Ca), and strontium (Sr), alloys containing these elements (e.g., MgAg and AlLi), rare earth metals such as europium (Eu) and ytterbium (Yb), and alloys containing these rare earth metals. However, when the electron-injection layer is provided between the cathode 102 and the electron-transport layer, a variety of conductive materials such as Al, Ag, ITO, or indium oxide-tin oxide containing silicon or silicon oxide can be used for the cathode 102 regardless of the work function.

Films of these conductive materials can be formed by a dry process such as a vacuum evaporation method or a sputtering method, an inkjet method, a spin coating method, or the like. Alternatively, a wet process using a sol-gel method or a wet process using a paste of a metal material may be employed.

A variety of methods, regardless of whether it is a dry process or a wet process, can be used as the formation method of the EL layer 103. For example, a vacuum evaporation method, a gravure printing method, an offset printing method, a screen printing method, an ink-jet method, a spin coating method, or the like may be used.

Different deposition methods may be used to form the electrodes or the layers described above.

The structure of the layers provided between the anode 101 and the cathode 102 is not limited to the above structure. However, a structure is preferable in which a light-emitting region where holes and electrons recombine is provided at a position away from the anode 101 and the cathode 102 so as to inhibit quenching caused by the proximity of the light-emitting region and a metal used for electrodes and carrier-injection layers.

Furthermore, in order to inhibit energy transfer from an exciton generated in the light-emitting layer, the hole-transport layer and the electron-transport layer which are in contact with the light-emitting layer 113, particularly a carrier-transport layer closer to the recombination region in the light-emitting layer 113, are preferably formed using the light-emitting material of the light-emitting layer or a substance having a wider band gap than the light-emitting material included in the light-emitting layer.

Next, an embodiment of a light-emitting device with a structure where a plurality of light-emitting units are stacked (also referred to as a stacked-type element or a tandem element) will be described with reference to FIG. 1C. This light-emitting device includes a plurality of light-emitting units between an anode and a cathode. One light-emitting unit has substantially the same structure as the EL layer 103 illustrated in FIG. 1A or FIG. 1B. In other words, the light-emitting device illustrated in FIG. 1C is a light-emitting device including a plurality of light-emitting units, and the light-emitting device illustrated in FIG. 1A or FIG. 1B is a light-emitting device including one light-emitting unit.

In FIG. 1C, a first light-emitting unit 511 and a second light-emitting unit 512 are stacked between an anode 501 and a cathode 502, and a charge-generation layer 513 is provided between the first light-emitting unit 511 and the second light-emitting unit 512. The anode 501 and the cathode 502 correspond, respectively, to the anode 101 and the cathode 102 illustrated in FIG. 1A, and the materials given in the description for FIG. 1A can be used. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when a voltage is applied to the anode 501 and the cathode 502. That is, in FIG. 1C, any layer can be used as the charge-generation layer 513 as long as the layer injects electrons into the first light-emitting unit 511 and injects holes into the second light-emitting unit 512 in the case where a voltage is applied such that the potential of the anode is higher than the potential of the cathode.

The charge-generation layer 513 is preferably formed to have a structure similar to that of the charge-generation layer described in FIG. 1B. A composite material of an organic compound and a metal oxide has an excellent carrier-injection and carrier-transport property; thus, low-voltage driving and low-current driving can be achieved. In the case where the anode-side surface of a light-emitting unit is in contact with the charge-generation layer 513, the charge-generation layer 513 can also serve as a hole-injection layer of the light-emitting unit; therefore, a hole-injection layer is not necessarily provided in the light-emitting unit.

In the case where the electron-injection buffer layer is provided in the charge-generation layer 513, the electron-injection buffer layer serves as an electron-injection layer in the light-emitting unit on the anode side; therefore, an electron-injection layer is not necessarily formed in the light-emitting unit on the anode side.

The light-emitting device having two light-emitting units is described with reference to FIG. 1C; however, the same applies to a light-emitting device in which three or more light-emitting units are stacked. With a plurality of light-emitting units partitioned by the charge-generation layer 513 between a pair of electrodes as in the light-emitting device according to this embodiment, it is possible to provide a long-life element that can emit light with high luminance at a low current density. Moreover, a light-emitting apparatus that can be driven at a low voltage and has low power consumption can be achieved.

When emission colors of the light-emitting units are different, light emission of a desired color can be obtained from the light-emitting device as a whole. For example, in a light-emitting device having two light-emitting units, emission colors of red and green are obtained in the first light-emitting unit and an emission color of blue is obtained in the second light-emitting unit, whereby a light-emitting device that emits white light as the whole light-emitting device can be obtained. The light-emitting device in which three or more light-emitting units are stacked can be, for example, a tandem device in which a first light-emitting unit includes a first blue light-emitting layer, a second light-emitting unit includes a yellow or yellow-green light-emitting layer and a red light-emitting layer, and a third light-emitting unit includes a second blue light-emitting layer. The tandem device can provide white light emission like the above light-emitting device.

The above-described layers and electrodes such as the EL layer 103, the first light-emitting unit 511, the second light-emitting unit 512, and the charge-generation layer can be formed by a method such as an evaporation method (including a vacuum evaporation method), a droplet discharge method (also referred to as an ink-jet method), a coating method, or a gravure printing method. These may include a low molecular material, a middle molecular material (including an oligomer and a dendrimer), or a high molecular material.

### EMBODIMENT 2

In this embodiment, a light-emitting apparatus including the light-emitting device described in Embodiment 1 will be described.

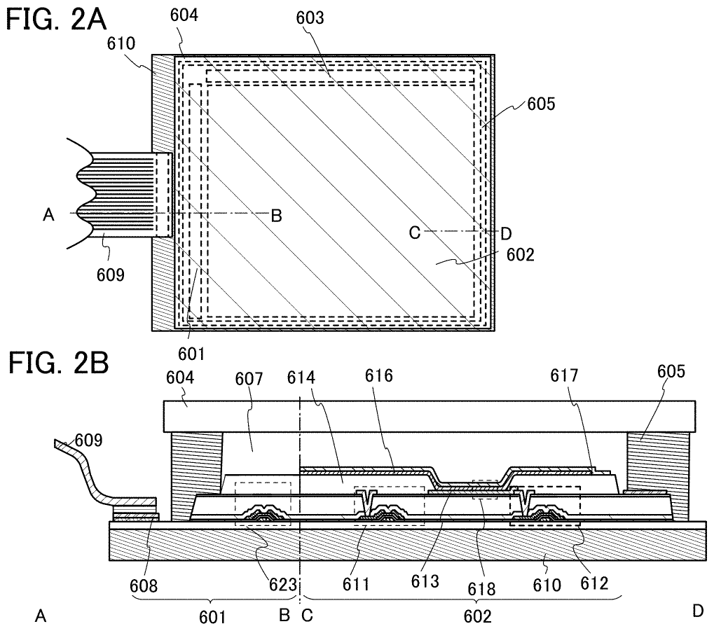

In this embodiment, the light-emitting apparatus manufactured using the light-emitting device described in Embodiment 1 is described with reference to FIG. 2. Note that FIG. 2A is a top view of the light-emitting apparatus and FIG. 2B is a cross-sectional view taken along the lines A-B and C-D in FIG. 2A. This light-emitting apparatus includes a driver circuit portion (source line driver circuit) 601, a pixel portion 602, and a driver circuit portion (gate line driver circuit) 603, which control light emission of a light-emitting device and are illustrated with dotted lines. Reference numeral 604 denotes a sealing substrate, 605 denotes a sealant, and 607 denotes a space surrounded by the sealant 605.

A lead wiring 608 is a wiring for transmitting signals to be input to the source line driver circuit 601 and the gate line driver circuit 603 and receives a video signal, a clock signal, a start signal, a reset signal, and the like from an FPC (flexible printed circuit) 609 serving as an external input terminal. Although only the FPC is illustrated here, a printed wiring board (PWB) may be attached to the FPC. The light-emitting apparatus in this specification includes, in its category, not only the light-emitting apparatus itself but also the light-emitting apparatus provided with the FPC or the PWB.

Next, a cross-sectional structure is described with reference to FIG. 2B. The driver circuit portions and the pixel portion are formed over an element substrate 610; here, the source line driver circuit 601, which is a driver circuit portion, and one pixel in the pixel portion 602 are illustrated.

The element substrate 610 may be a substrate formed of glass, quartz, an organic resin, a metal, an alloy, a semiconductor, or the like or a plastic substrate formed of FRP (Fiber Reinforced Plastics), PVF (polyvinyl fluoride), polyester, acrylic, or the like.

The structure of transistors used in pixels and driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

Here, an oxide semiconductor is preferably used for semiconductor devices such as the transistors provided in the pixels and driver circuits and transistors used for touch sensors described later, and the like. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

An oxide semiconductor that can be used in one embodiment of the present invention is described below.

Oxide semiconductors are classified into a single crystal oxide semiconductor and a non-single-crystal oxide semiconductor. Examples of a non-single-crystal oxide semiconductor include a CAAC-OS (c-axis aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, its nanocrystals are connected in the a-b plane direction, and its crystal structure has distortion. Note that distortion refers to a portion where the direction of a lattice arrangement changes between a region with a uniform lattice arrangement and another region with a uniform lattice arrangement in a region where the nanocrystals are connected.

The shape of the nanocrystal is basically a hexagon but is not always a regular hexagon and is a non-regular hexagon in some cases. A pentagonal lattice arrangement, a heptagonal lattice arrangement, and the like are included in the distortion in some cases. Note that it is difficult to observe a clear crystal grain boundary even in the vicinity of distortion in the CAAC-OS. That is, a lattice arrangement is distorted and thus formation of a crystal grain boundary is inhibited. This is because the CAAC-OS can tolerate distortion owing to a low density of oxygen atom arrangement in the a-b plane direction, a change in interatomic bond distance by substitution of a metal element, and the like.

The CAAC-OS tends to have a layered crystal structure (also referred to as a stacked-layer structure) in which a layer containing indium and oxygen (hereinafter, an In layer) and a layer containing the element M, zinc, and oxygen (hereinafter, an (M, Zn) layer) are stacked. Note that indium and the element M can be replaced with each other, and when the element M of the (M, Zn) layer is replaced with indium, the layer can be referred to as an (In, M, Zn) layer. When indium of the In layer is replaced with the element M, the layer can be referred to as an (In, M) layer.

The CAAC-OS is an oxide semiconductor with high crystallinity. By contrast, in the CAAC-OS, a reduction in electron mobility due to a crystal grain boundary is less likely to occur because it is difficult to observe a clear crystal grain boundary. Entry of impurities, formation of defects, or the like might decrease the crystallinity of an oxide semiconductor. This means that the CAAC-OS is an oxide semiconductor having small amounts of impurities and defects (e.g., oxygen vacancies (Vo)). Thus, an oxide semiconductor including the CAAC-OS is physically stable. Accordingly, the oxide semiconductor including the CAAC-OS is resistant to heat and has high reliability.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different nanocrystals in the nc-OS. Thus, the orientation in the whole film is not observed. Accordingly, in some cases, the nc-OS cannot be distinguished from an a-like OS or an amorphous oxide semiconductor, depending on an analysis method.

Note that an indium-gallium-zinc oxide (hereinafter, IGZO) that is an oxide semiconductor containing indium, gallium, and zinc has a stable structure in some cases by being formed of the above-described nanocrystals. In particular, IGZO crystals tend not to grow in the air and thus, a stable structure is obtained when IGZO is formed of smaller crystals (e.g., the above-described nanocrystals) rather than larger crystals (here, crystals with a size of several millimeters or several centimeters).

The a-like OS is an oxide semiconductor having a structure between those of the nc-OS and the amorphous oxide semiconductor. The a-like OS has a void or a low-density region. That is, the a-like OS has low crystallinity as compared with the nc-OS and the CAAC-OS.

An oxide semiconductor has various structures with different properties. Two or more of the amorphous oxide semiconductor, the polycrystalline oxide semiconductor, the a-like OS, the nc-OS, and the CAAC-OS may be included in an oxide semiconductor of one embodiment of the present invention.

A CAC (Cloud-Aligned Composite)-OS may be used as an oxide semiconductor other than the above.

A CAC-OS has a conducting function in part of the material and has an insulating function in another part of the material; as a whole, the CAC-OS has a function of a semiconductor. Note that in the case where the CAC-OS is used in an active layer of a transistor, the conducting function is to allow electrons (or holes) serving as carriers to flow, and the insulating function is to not allow electrons serving as carriers to flow. By the complementary action of the conducting function and the insulating function, the CAC-OS can have a switching function (On/Off function). In the CAC-OS, separation of the functions can maximize each function.

Furthermore, the CAC-OS includes conductive regions and insulating regions. The conductive regions have the above-described conducting function, and the insulating regions have the above-described insulating function. In some cases, the conductive regions and the insulating regions in the material are separated at the nanoparticle level. Furthermore, in some cases, the conductive regions and the insulating regions are unevenly distributed in the material. The conductive regions are sometimes observed to be coupled in a cloud-like manner with their boundaries blurred.

In the CAC-OS, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

The CAC-OS includes components having different band gaps. For example, the CAC-OS includes a component having a wide gap due to the insulating region and a component having a narrow gap due to the conductive region. In the case of such a composition, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS is used in a channel formation region of a transistor, high current drive capability in the on state of the transistor, that is, high on-state current and high field-effect mobility, can be obtained.

In other words, the CAC-OS can also be referred to as a matrix composite or a metal matrix composite.

The use of the above-described oxide semiconductor materials for the semiconductor layer makes it possible to provide a highly reliable transistor in which a change in the electrical characteristics is inhibited.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed on each display region is maintained. As a result, an electronic device with extremely low power consumption can be obtained.

For stable characteristics or the like of the transistor, a base film is preferably provided. The base film can be formed with a single layer or stacked layers using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film is not necessarily provided when not needed.

Note that an FET 623 is illustrated as a transistor formed in the driver circuit portion 601. The driver circuit may be formed with any of a variety of circuits such as a CMOS circuit, a PMOS circuit, and an NMOS circuit. Although a driver integrated type in which the driver circuit is formed over the substrate is illustrated in this embodiment, the driver circuit is not necessarily formed over the substrate, and can be formed outside the substrate.

The pixel portion 602 includes a plurality of pixels each including a switching FET 611, a current controlling FET 612, and an anode 613 electrically connected to a drain of the current controlling FET 612. One embodiment of the present invention is not limited to the structure. The pixel portion 602 may include three or more FETs and a capacitor in combination.

Note that an insulator 614 is formed to cover an end portion of the anode 613. Here, the insulator 614 can be formed using positive photosensitive acrylic here.

In order to improve the coverage with an EL layer or the like which is formed later, the insulator 614 is formed to have a curved surface with curvature at its upper or lower end portion. For example, in the case where positive photosensitive acrylic is used as a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

An EL layer 616 and a cathode 617 are formed over the anode 613. Here, as a material used for the anode 613, a material having a high work function is desirably used. For example, a single-layer film of an ITO film, an indium tin oxide film containing silicon, an indium oxide film containing zinc oxide at 2 to 20 wt %, a titanium nitride film, a chromium film, a tungsten film, a Zn film, a Pt film, or the like, a stack of a titanium nitride film and a film containing aluminum as its main component, a stack of three layers of a titanium nitride film, a film containing aluminum as its main component, and a titanium nitride film, or the like can be used. The stacked-layer structure enables low wiring resistance and favorable ohmic contact, and can function as an anode.

The EL layer 616 is formed by any of a variety of methods such as an evaporation method using an evaporation mask, an inkjet method, and a spin coating method. The EL layer 616 has the structure described in Embodiment 1. As another material included in the EL layer 616, a low molecular compound or a high molecular compound (including an oligomer or a dendrimer) may be used.

As a material used for the cathode 617, which is formed over the EL layer 616, a material having a low work function (e.g., Al, Mg, Li, or Ca, or an alloy or a compound thereof, such as MgAg, MgIn, or AlLi) is preferably used. In the case where light generated in the EL layer 616 is transmitted through the cathode 617, a stack of a thin metal film and a transparent conductive film (e.g., ITO, indium oxide containing zinc oxide at 2 to 20 wt %, indium tin oxide containing silicon, or zinc oxide (ZnO)) is preferably used for the cathode 617.

Note that a light-emitting device 618 is formed with the anode 613, the EL layer 616, and the cathode 617. The light-emitting device is the light-emitting device described in Embodiment 1. In the light-emitting apparatus of this embodiment, the pixel portion, which includes a plurality of light-emitting devices, may include both the light-emitting device described in Embodiment 1 and a light-emitting device having a different structure.

The sealing substrate 604 is attached to the element substrate 610 with the sealant 605, so that a light-emitting device 618 is provided in the space 607 surrounded by the element substrate 610, the sealing substrate 604, and the sealant 605. The space 607 is filled with a filler, and may be filled with an inert gas (such as nitrogen or argon) or the sealant. It is preferable that the sealing substrate have a recessed portion provided with a desiccant, in which case degradation due to the influence of moisture can be inhibited.

Note that an epoxy-based resin or glass frit is preferably used for the sealant 605. It is desirable that such a material transmit moisture or oxygen as little as possible. As the sealing substrate 604, a glass substrate, a quartz substrate, or a plastic substrate formed of FRP (Fiber Reinforced Plastics), PVF (polyvinyl fluoride), polyester, acrylic, or the like can be used.

Although not illustrated in FIG. 2B, a protective film may be provided over the cathode. The protective film may be formed using an organic resin film or an inorganic insulating film. The protective film may be formed so as to cover an exposed portion of the sealant 605. The protective film can be provided so as to cover surfaces and side surfaces of the pair of substrates and exposed side surfaces of a sealing layer, an insulating layer, and the like.

The protective film can be formed using a material through which impurities such as water do not permeate easily. Thus, diffusion of impurities such as water from the outside into the inside can be effectively inhibited.

As a material for the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method with favorable step coverage. One such method is an atomic layer deposition (ALD) method. A material that can be deposited by an ALD method is preferably used for the protective film. A dense protective film having reduced defects such as cracks and pinholes or a uniform thickness can be formed by an ALD method. Furthermore, damage to a process member in forming the protective film can be reduced.

By an ALD method, a uniform protective film with few defects can be formed even on a surface with a complex uneven shape or upper, side, and lower surfaces of a touch panel.

As described above, the light-emitting apparatus manufactured using the light-emitting device described in Embodiment 1 can be obtained.

The light-emitting apparatus in this embodiment is manufactured using the light-emitting device described in Embodiment 1 and thus can have favorable characteristics. Specifically, since the light-emitting device described in Embodiment 1 has a long lifetime, the light-emitting apparatus can have high reliability. Since the light-emitting apparatus using the light-emitting device described in Embodiment 1 has favorable emission efficiency, the light-emitting apparatus can achieve low power consumption.

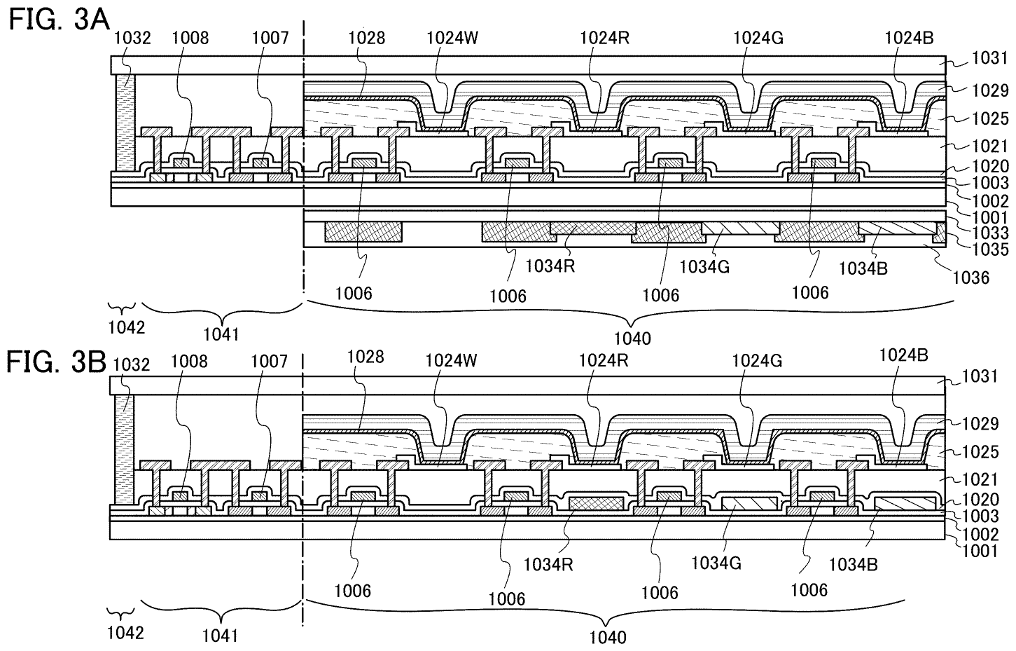

FIG. 3A and FIG. 3B each illustrate an example of a light-emitting apparatus that includes a light-emitting device exhibiting white light emission and coloring layers (color filters) and the like to display a full-color image. FIG. 3A illustrates a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, anodes 1024W, 1024R, 1024G, and 1024B of light-emitting devices, a partition 1025, an EL layer 1028, a cathode 1029 of the light-emitting devices, a sealing substrate 1031, a sealant 1032, and the like.

In FIG. 3A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 3A, light emitted from part of the light-emitting layer does not pass through the coloring layers, while light emitted from the other part of the light-emitting layer passes through the coloring layers. The light that does not pass through the coloring layers is white and the light that passes through any one of the coloring layers is red, green, or blue; thus, an image can be displayed using pixels of the four colors.

FIG. 3B illustrates an example in which the coloring layers (the red coloring layer 1034R, the green coloring layer 1034G, and the blue coloring layer 1034B) are provided between the gate insulating film 1003 and the first interlayer insulating film 1020. As in this structure, the coloring layers may be provided between the substrate 1001 and the sealing substrate 1031.

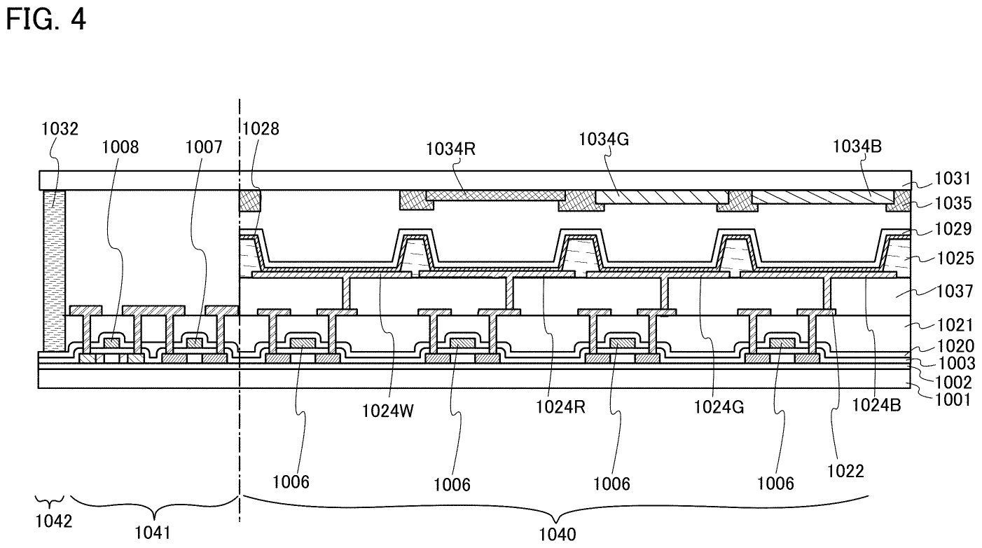

The above-described light-emitting apparatus has a structure in which light is extracted from the substrate 1001 side where FETs are formed (a bottom emission structure), but may have a structure in which light is extracted from the sealing substrate 1031 side (atop emission structure). FIG. 4 is a cross-sectional view of a light-emitting apparatus having a top emission structure. In this case, a substrate that does not transmit light can be used as the substrate 1001. The process up to the step of forming a connection electrode that connects the FET and the anode of the light-emitting device is performed in a manner similar to that of the light-emitting apparatus having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film or using any of other known materials.

The anodes 1024W, 1024R, 1024G, and 1024B of the light-emitting devices are anodes here, but may be formed as cathodes. Furthermore, in the case of a light-emitting apparatus having a top emission structure as illustrated in FIG. 4, the anodes are preferably reflective electrodes. The EL layer 1028 is formed to have a structure similar to the structure of the EL layer 103 described in Embodiment 1, with which white light emission can be obtained.

In the case of a top emission structure as illustrated in FIG. 4, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 that is positioned between pixels. The coloring layers (the red coloring layer 1034R, the green coloring layer 1034G, and the blue coloring layer 1034B) and the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display using four colors of red, yellow, green, and blue or three colors of red, green, and blue may be performed.

In the light-emitting apparatus having a top emission structure, a microcavity structure can be suitably employed. A light-emitting device with a microcavity structure is formed with the use of a reflective electrode as the anode and a transflective electrode as the cathode. The light-emitting device with a microcavity structure includes at least an EL layer between the reflective electrode and the transflective electrode. The EL layer includes at least a light-emitting layer serving as a light-emitting region.

Note that the reflective electrode is a film having a visible light reflectivity of 40% to 100%, preferably 70% to 100%, and a resistivity of 1×10⁻² Ωcm or lower. In addition, the transflective electrode is a film having a visible light reflectivity of 20% to 80%, preferably 40% to 70%, and a resistivity of 1×10⁻² Ωcm or lower.

Light emitted from the light-emitting layer included in the EL layer is reflected and resonated by the reflective electrode and the transflective electrode.

In the light-emitting device, by changing the thicknesses of the transparent conductive film, the composite material, the carrier-transport material, and the like, the optical path length between the reflective electrode and the transflective electrode can be changed. Thus, light with a wavelength that is resonated between the reflective electrode and the transflective electrode can be intensified while light with a wavelength that is not resonated therebetween can be attenuated.

Light that is reflected back by the reflective electrode (first reflected light) considerably interferes with light that directly enters the transflective electrode from the light-emitting layer (first incident light); therefore, the optical path length between the reflective electrode and the light-emitting layer is preferably adjusted to (2n−1)λ/4 (n is a natural number of 1 or larger and λ is a wavelength of light emission to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer; for example, in combination with the structure of the above-described tandem light-emitting device, a plurality of EL layers each including a single or a plurality of light-emitting layer(s) may be provided in one light-emitting device with a charge-generation layer interposed between the EL layers.

With the microcavity structure, emission intensity with a specific wavelength in the front direction can be increased, whereby power consumption can be reduced. Note that in the case of a light-emitting apparatus that displays images with subpixels of four colors, red, yellow, green, and blue, the light-emitting apparatus can have favorable characteristics because the luminance can be increased owing to yellow light emission and each subpixel can employ a microcavity structure suitable for wavelengths of the corresponding color.

The light-emitting apparatus in this embodiment is manufactured using the light-emitting device described in Embodiment 1 and thus can have favorable characteristics. Specifically, since the light-emitting device described in Embodiment 1 has a long lifetime, the light-emitting apparatus can have high reliability. Since the light-emitting apparatus using the light-emitting device described in Embodiment 1 has favorable emission efficiency, the light-emitting apparatus can achieve low power consumption.

### EMBODIMENT 3

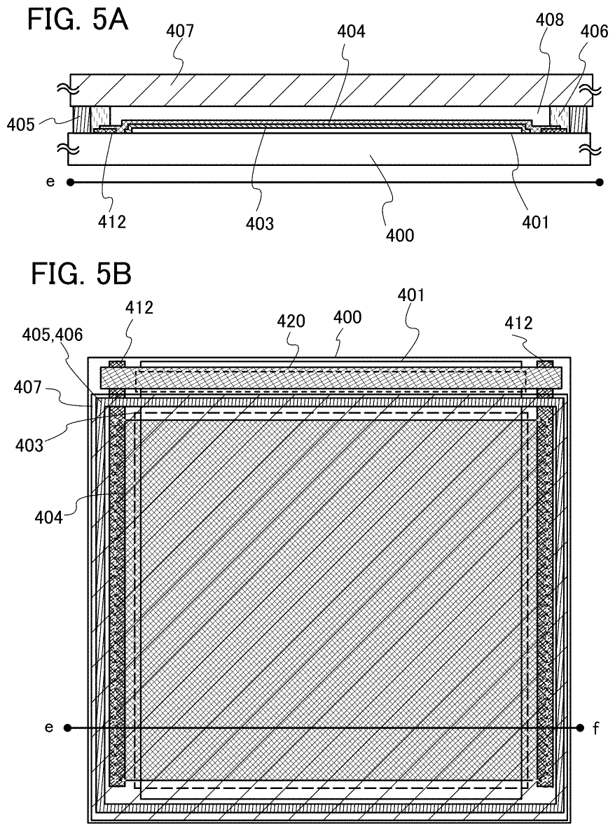

In this embodiment, an example in which the light-emitting device described in Embodiment 1 is used for a lighting device is described with reference to FIG. 5A and FIG. 5B. FIG. 5B is a top view of the lighting device, and FIG. 5A is a cross-sectional view taken along the line e-f in FIG. 5B.

In the lighting device in this embodiment, an anode 401 is formed over a substrate 400 which is a support and has a light-transmitting property. The anode 401 corresponds to the anode 101 in Embodiment 1. When light is extracted from the anode 401 side, the anode 401 is formed using a material having a light-transmitting property.

A pad 412 for applying voltage to a cathode 404 is formed over the substrate 400.

An EL layer 403 is formed over the anode 401. The structure of the EL layer 403 corresponds to, for example, the structure of the EL layer 103 in Embodiment 1, or the structure in which the light-emitting units 511 and 512 and the charge-generation layer 513 are combined. Refer to the descriptions for the structures.

The cathode 404 is formed to cover the EL layer 403. The cathode 404 corresponds to the cathode 102 in Embodiment 1. The cathode 404 is formed using a material having high reflectivity when light is extracted from the anode 401 side. The cathode 404 is connected to the pad 412, whereby voltage is applied.

As described above, the lighting device described in this embodiment includes a light-emitting device including the anode 401, the EL layer 403, and the cathode 404. Since the light-emitting device has high emission efficiency, the lighting device in this embodiment can have low power consumption.

The substrate 400 provided with a light-emitting device having the above structure is fixed to a sealing substrate 407 with sealants 405 and 406 and sealing is performed, whereby the lighting device is completed. It is possible to use only either the sealant 405 or the sealant 406. The inner sealant 406 (not illustrated in FIG. 5B) can be mixed with a desiccant that enables moisture to be adsorbed, which results in improved reliability.

When parts of the pad 412 and the anode 401 are extended to the outside of the sealants 405 and 406, the extended parts can function as external input terminals. An IC chip 420 or the like mounted with a converter or the like may be provided over the external input terminals.

The lighting device described in this embodiment includes, as an EL element, the light-emitting device described in Embodiment 1; thus, the light-emitting apparatus can have high reliability. In addition, the light-emitting apparatus can have low power consumption.

### EMBODIMENT 4

In this embodiment, examples of electronic devices each including the light-emitting device described in Embodiment 1 will be described. The light-emitting device described in Embodiment 1 has a long lifetime and high reliability. As a result, the electronic devices described in this embodiment can each include a light-emitting portion having high reliability.

Examples of the electronic devices including the above light-emitting device include a television device (also referred to as a television or a television receiver), a monitor for a computer or the like, a digital camera, a digital video camera, a digital photo frame, a cellular phone (also referred to as a mobile phone or a mobile phone device), a portable game machine, a portable information terminal, an audio playback device, and a large game machine such as a pachinko machine. Specific examples of these electronic devices are described below.

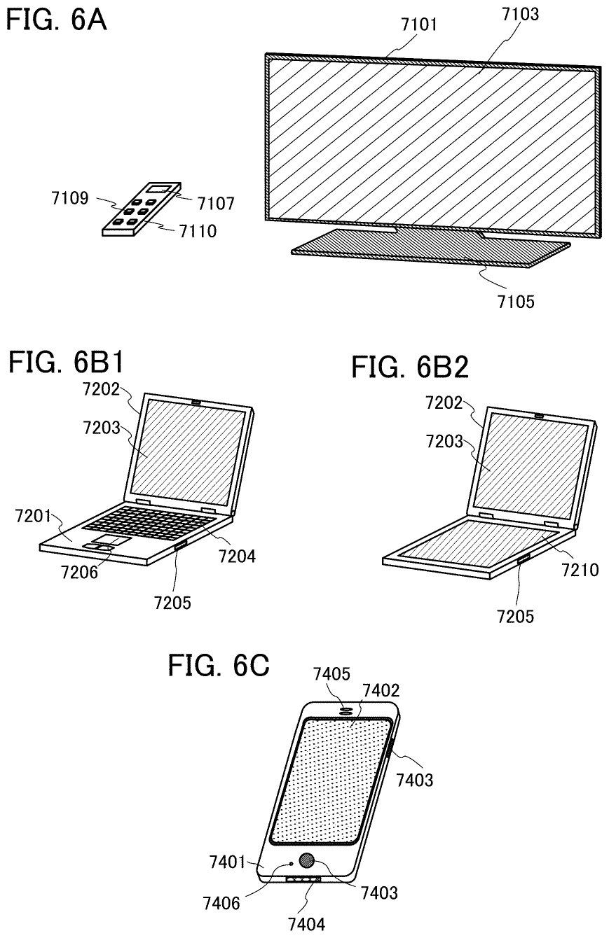

FIG. 6A illustrates an example of a television device. In the television device, a display portion 7103 is incorporated in a housing 7101. Here, the housing 7101 is supported by a stand 7105. Images can be displayed on the display portion 7103, and in the display portion 7103, the light-emitting devices described in Embodiment 1 are arranged in a matrix.

The television device can be operated with an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, and the like. With the use of the receiver, a general television broadcast can be received. Moreover, when the television device is connected to a communication network with or without wires via the modem, one-way (from a sender to a receiver) or two-way (between a sender and a receiver or between receivers) data communication can be performed.

FIG. 6B1 illustrates a computer, which includes a main body 7201, a housing 7202, a display portion 7203, a keyboard 7204, an external connection port 7205, a pointing device 7206, and the like. Note that this computer is manufactured using the light-emitting devices described in Embodiment 1 and arranged in a matrix in the display portion 7203. The computer in FIG. 6B1 may have a mode illustrated in FIG. 6B2. A computer in FIG. 6B2 is provided with a second display portion 7210 instead of the keyboard 7204 and the pointing device 7206. The second display portion 7210 is a touch panel, and input operation can be performed by touching display for input on the second display portion 7210 with a finger or a dedicated pen. The second display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIG. 6C illustrates an example of a portable terminal. A cellular phone is provided with a display portion 7402 incorporated in a housing 7401, operation buttons 7403, an external connection port 7404, a speaker 7405, a microphone 7406, and the like. Note that a cellular phone 7400 has the display portion 7402 including the light-emitting devices described in Embodiment 1 and arranged in a matrix.

When the display portion 7402 of the portable terminal illustrated in FIG. 6C is touched with a finger or the like, data can be input into the portable terminal. In this case, operations such as making a call and creating an e-mail can be performed by touching the display portion 7402 with a finger or the like.

The display portion 7402 has mainly three screen modes. The first mode is a display mode mainly for displaying images. The second mode is an input mode mainly for inputting data such as text. The third mode is a display-and-input mode in which the two modes, the display mode and the input mode, are combined.

For example, in the case of making a call or creating an e-mail, a text input mode mainly for inputting text is selected for the display portion 7402 so that text displayed on the screen can be input. In this case, it is preferable to display a keyboard or number buttons on almost the entire screen of the display portion 7402.

When a sensing device including a sensor for sensing inclination, such as a gyroscope sensor or an acceleration sensor, is provided inside the portable terminal, display on the screen of the display portion 7402 can be automatically changed by determining the orientation (horizontal or vertical) of the portable terminal.

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is a signal of moving image data, the screen mode is switched to the display mode, and when the signal is a signal of text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 can also function as an image sensor. For example, an image of a palm print, a fingerprint, or the like is taken when the display portion 7402 is touched with the palm or the finger, whereby personal authentication can be performed. Furthermore, by using a backlight that emits near-infrared light or a sensing light source that emits near-infrared light in the display portion, an image of a finger vein, a palm vein, or the like can be taken.

Note that the structure described in this embodiment can be combined with any of the structures described in Embodiment 1 to Embodiment 3 as appropriate.

As described above, the application range of the light-emitting apparatus having the light-emitting device described in Embodiment 1 is extremely wide, so that this light-emitting apparatus can be used in electronic devices in a variety of fields. By using the light-emitting device described in Embodiment 1, an electronic device with high reliability can be obtained.

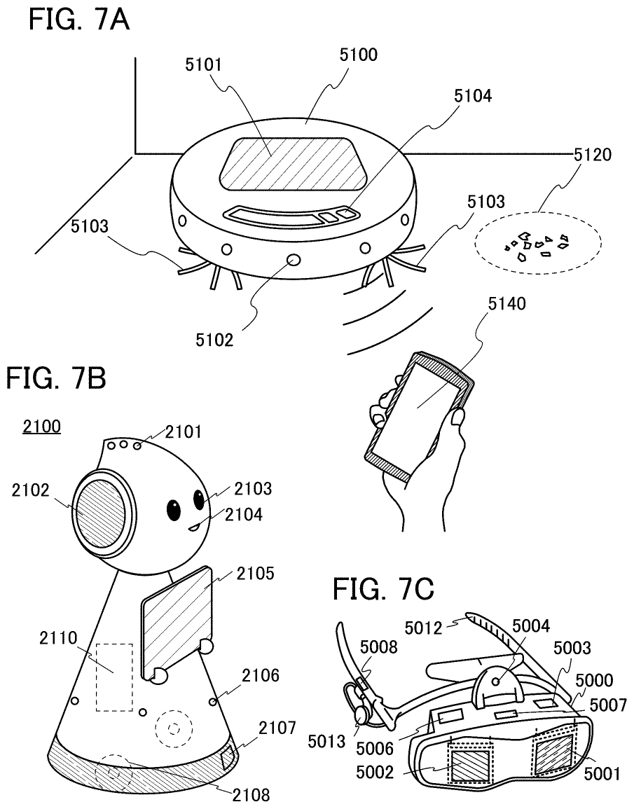

FIG. 7A is a schematic diagram illustrating an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and sucks up the dust through the inlet provided on the bottom surface.

The cleaning robot 5100 can determine whether there is an obstacle such as a wall, furniture, or a step by analyzing images taken by the cameras 5102. When an object that is likely to be caught in the brush 5103, such as a wire, is detected by image analysis, the rotation of the brush 5103 can be stopped.

The display 5101 can display the remaining capacity of a battery, the amount of collected dust, and the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. The portable electronic device 5140 can display images taken by the cameras 5102. Accordingly, an owner of the cleaning robot 5100 can monitor the room even from the outside. The owner can also check the display on the display 5101 by the portable electronic device such as a smartphone.

The light-emitting apparatus of one embodiment of the present invention can be used for the display 5101.

A robot 2100 illustrated in FIG. 7B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of capturing an image of the surroundings of the robot 2100. The obstacle sensor 2107 can detect the presence of an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 7C illustrates an example of a goggle-type display. The goggle-type display includes, for example, a housing 5000, a display portion 5001, a speaker 5003, an LED lamp 5004, a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, a display portion 5002, a support 5012, and an earphone 5013.

The light-emitting apparatus of one embodiment of the present invention can be used for the display portion 5001 and the second display portion 5002.

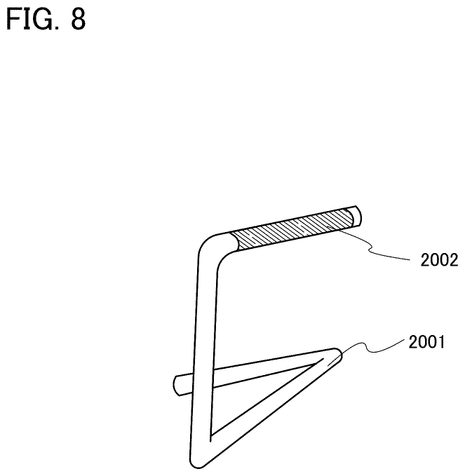

FIG. 8 illustrates an example in which the light-emitting device described in Embodiment 1 is used for a table lamp which is a lighting device. The table lamp illustrated in FIG. 8 includes a housing 2001 and a light source 2002, and the lighting device described in Embodiment 2 may be used for the light source 2002.

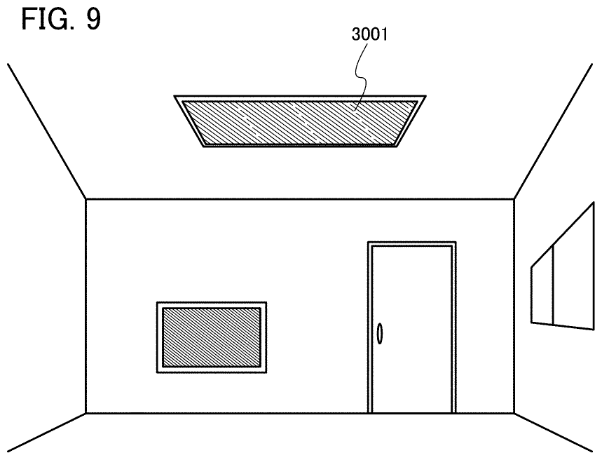

FIG. 9 illustrates an example in which the light-emitting device described in Embodiment 1 is used for an indoor lighting device 3001. Since the light-emitting device described in Embodiment 1 has high reliability, the lighting device can have high reliability. Furthermore, since the light-emitting device described in Embodiment 1 can have a large area, the light-emitting device can be used for a large-area lighting device. Furthermore, since the light-emitting device described in Embodiment 1 is thin, the light-emitting device can be used for a lighting device having a reduced thickness.

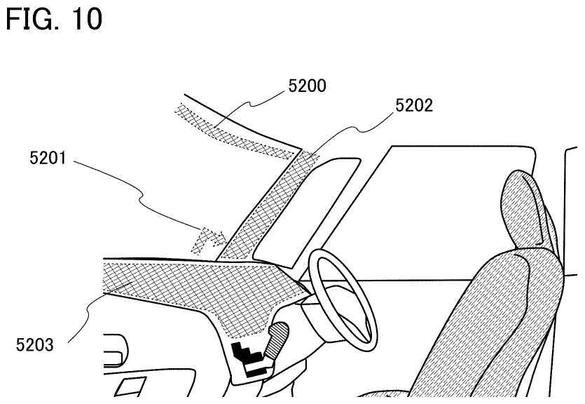

The light-emitting device described in Embodiment 1 can also be used for an automobile windshield or an automobile dashboard. FIG. 10 illustrates one mode in which the light-emitting device described in Embodiment 1 is used for an automobile windshield and an automobile dashboard. A display region 5200 to a display region 5203 each include the light-emitting device described in Embodiment 1.

The display region 5200 and the display region 5201 are each a display device which is provided in the automobile windshield and in which the light-emitting device described in Embodiment 1 is incorporated. When the light-emitting device described in Embodiment 1 is fabricated using electrodes having light-transmitting properties as an anode and a cathode, what is called a see-through display device, through which the opposite side can be seen, can be obtained. Such see-through display can be provided even in the automobile windshield without hindering the view. In the case where a driving transistor or the like is provided, a transistor having a light-transmitting property, such as an organic transistor including an organic semiconductor material or a transistor including an oxide semiconductor, is preferably used.

The display region 5202 is a display device which is provided in a pillar portion and in which the light-emitting device described in Embodiment 1 is incorporated. The display region 5202 can compensate for the view hindered by the pillar by displaying an image taken by an imaging unit provided in the car body. Similarly, the display region 5203 provided in the dashboard portion can display an image taken by an imaging means provided on the outside of the automobile, so that the view hindered by the car body can be compensated for to avoid blind areas and enhance the safety. Displaying an image so as to compensate for the area that cannot be seen makes it possible to confirm safety more naturally and comfortably.

The display region 5203 can provide a variety of kinds of information by displaying navigation data, a speedometer, a tachometer, a mileage, a fuel meter, a gearshift state, air-condition setting, and the like. The content or layout of the display can be changed freely in accordance with the preference of a user. Note that such information can also be displayed on the display region 5200 to the display region 5202. The display region 5200 to the display region 5203 can also be used as lighting devices.

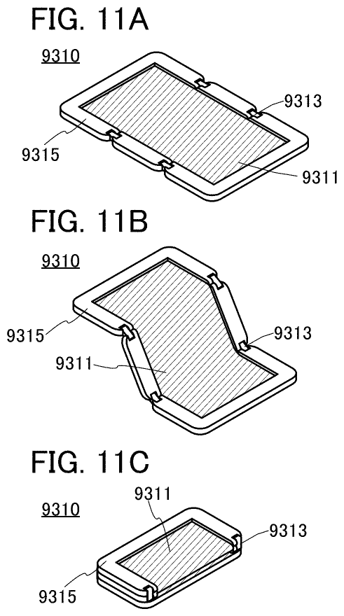

FIG. 11A to FIG. 11C illustrate a foldable portable information terminal 9310. FIG. 11A illustrates the portable information terminal 9310 that is opened. FIG. 11B illustrates the portable information terminal 9310 that is in the state of being changed from one of an opened state and a folded state to the other. FIG. 11C illustrates the portable information terminal 9310 that is folded. The portable information terminal 9310 is excellent in portability when folded, and is excellent in display browsability when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

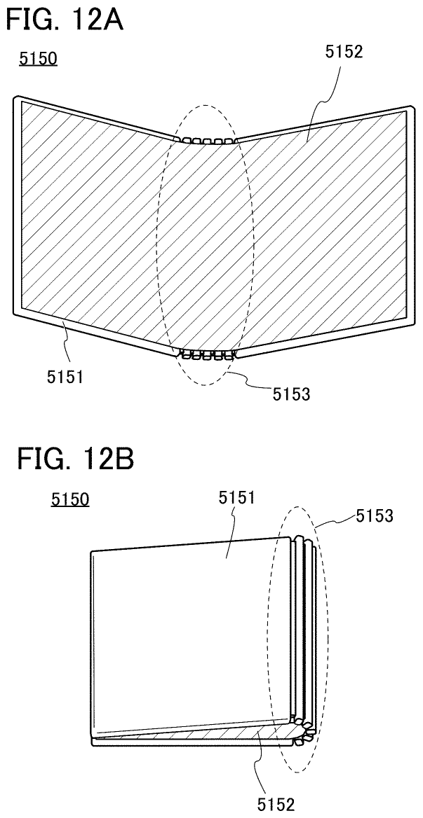

FIG. 12A and FIG. 12B illustrate a foldable portable information terminal 5150. The foldable portable information terminal 5150 includes a housing 5151, a display region 5152, and a bend portion 5153. FIG. 12A illustrates the portable information terminal 5150 that is opened. FIG. 12B illustrates the portable information terminal 5150 that is folded. The portable information terminal 5150 is compact in size and has excellent portability when folded, despite its large display region 5152.

The display region 5152 can be folded in half with the bend portion 5153. The bend portion 5153 includes a stretchable member and a plurality of supporting members. When the display region is folded, the stretchable member stretches and the bend portion 5153 is folded with a radius of curvature of greater than or equal to 2 mm, preferably greater than or equal to 3 mm.

Note that the display region 5152 may be a touch panel (an input/output device) including a touch sensor (an input device). The light-emitting apparatus of one embodiment of the present invention can be used for the display region 5152.

### EXAMPLE 1

Described in this example are fabrication methods of a light-emitting device 1 and a comparative light-emitting device 2 of one embodiment of the present invention and a comparative light-emitting device 1 for comparison. Structural formulae of materials used in this example are shown below.

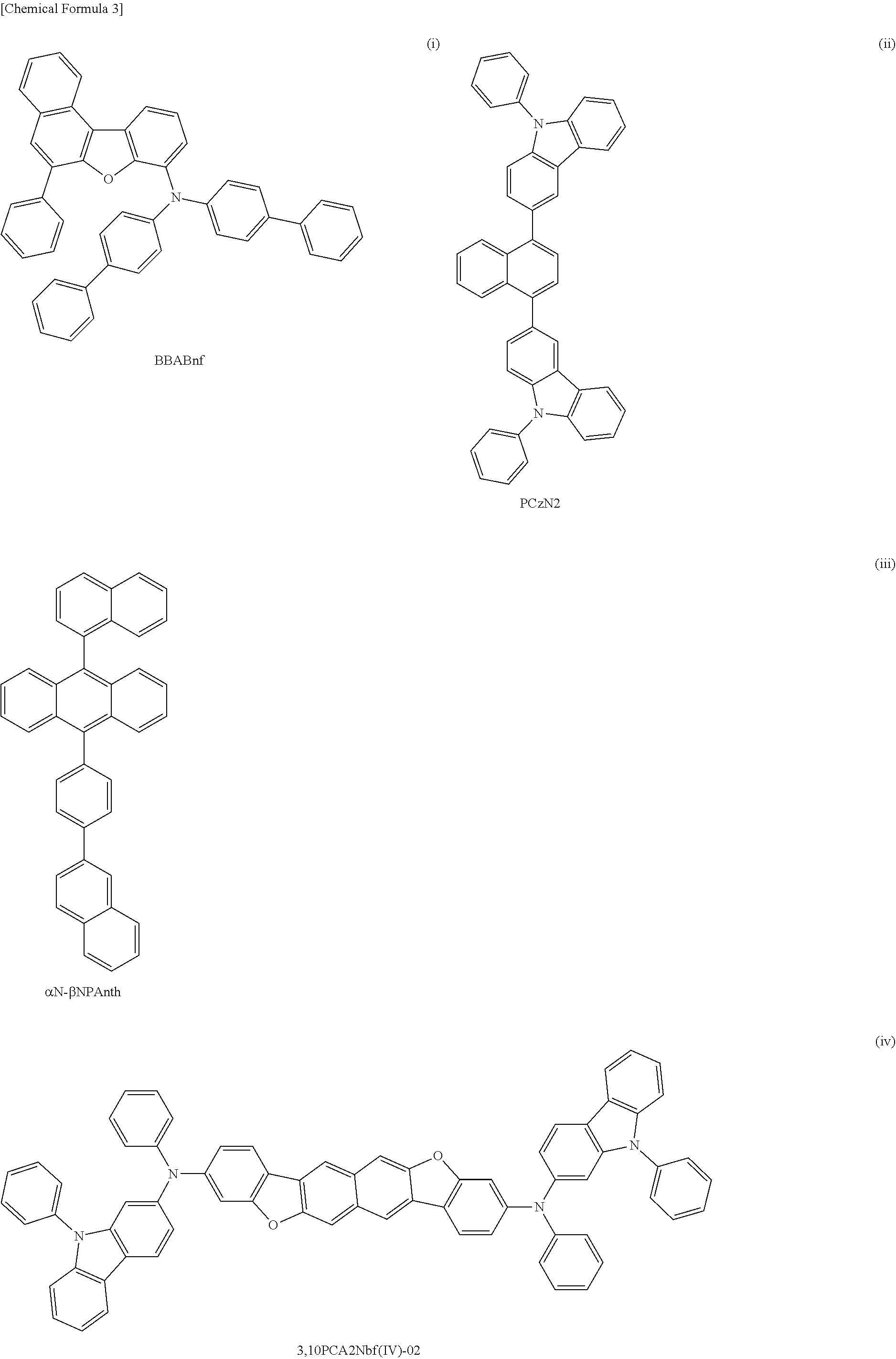

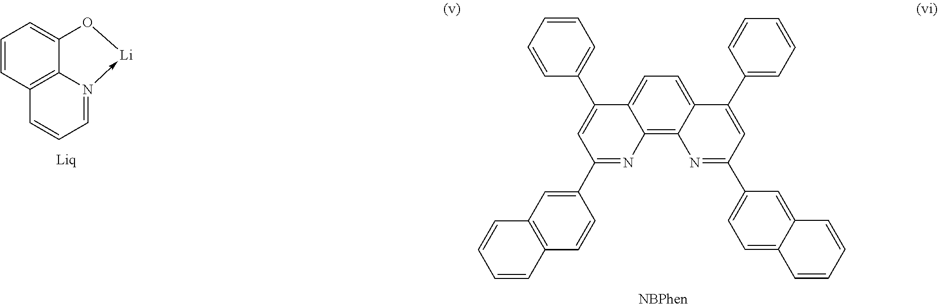

### <<Fabrication Method of Light-Emitting Device 1>>

First, indium tin oxide containing silicon oxide (ITSO) was deposited on a glass substrate by a sputtering method to form the anode 101. Note that the film thickness was 70 nm and the area of the electrode was 4 mm² (2 mm×2 mm).

Next, in pretreatment for forming the light-emitting device over the substrate, the surface of the substrate was washed with water and baked at 200° C. for one hour, and then UV ozone treatment was performed for 370 seconds.

After that, the substrate was transferred into a vacuum evaporation apparatus in which the pressure was reduced to approximately 10⁻⁴ Pa, vacuum baking at 170° C. for 30 minutes was performed in a heating chamber in the vacuum evaporation apparatus, and then the substrate was cooled down for approximately 30 minutes.

Then, the substrate on which the anode 101 was formed was fixed to a substrate holder provided in the vacuum evaporation apparatus such that the surface on which the anode 101 was formed faced downward. On the anode 101, N,N-bis(4-biphenyl)-6-phenylbenzo[b]naphtho[1,2-d]furan-8-amine (abbreviation: BBABnf) represented by Structural Formula (i) above and an electron acceptor material (OCHD-001) were deposited by co-evaporation to a thickness of 10 nm at a mass ratio of 1:0.1 (=BBABnf: OCHD-001) by an evaporation method using resistance heating, whereby the hole-injection layer 111 was formed.

Next, as the first hole-transport layer 112-1, BBABnf was deposited by evaporation to a thickness of 20 nm over the hole-injection layer 111, and then, as the second hole-transport layer 112-2, 3,3′-(naphthalene-1,4-diyl)bis(9-phenyl-9H-carbazole) (abbreviation: PCzN2) represented by Structural Formula (ii) above was deposited by evaporation to a thickness of 10 nm, whereby the hole-transport layer 112 was formed. Note that the second hole-transport layer 112-2 also functions as an electron-blocking layer.

Subsequently, 9-(1-naphthyl)-10-[4-(2-naphthyl)phenyl]anthracene (abbreviation: αN-βNPAnth) represented by Structural Formula (iii) above, and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) represented by Structural Formula (iv) were deposited by co-evaporation to a thickness of 25 nm at a mass ratio of 1:0.015 (=αN-βNPAnth: 3,10PCA2Nbf(IV)-02), so that the light-emitting layer 113 was formed.

After that, over the light-emitting layer 113, OCET010 and 8-hydroxyquinolinato-lithium (abbreviation: Liq) represented by Structural Formula (v) above were deposited by co-evaporation to a thickness of 12.5 nm at a mass ratio of 1:2 (=OCET010: Liq); then, they were deposited by co-evaporation to a thickness of 12.5 nm at a mass ratio of 2:1 (=OCET010: Liq), so that the electron-transport layer 114 was formed. Note that OCET010 is an organic compound having an electron-transport property.

After the formation of the electron-transport layer 114, Liq was deposited by evaporation to a thickness of 1 nm to form the electron-injection layer 115, and then aluminum was deposited by evaporation to a thickness of 200 nm to form the cathode 102, whereby the light-emitting device 1 of this example was fabricated.

### <<Fabrication Method of Light-Emitting Device 2>>

The light-emitting device 2 was fabricated in the same manner as the light-emitting device 1 except that OCET010 in the light-emitting device 1 was replaced with 2,9-di(2-naphthyl)-4,7-diphenyl-1,10-phenanthroline (abbreviation: NBPhen) represented by Structural Formula (vi) above.

### <<Fabrication Method of Comparative Light-Emitting Device 1>>

The comparative light-emitting device 1 was fabricated in the same manner as the light-emitting device 1 except that OCET010 in the light-emitting device 1 was replaced with αN-βNPAnth represented by Structural Formula (iii) above.

The element structures of the light-emitting device 1, the light-emitting device 2, and the comparative light-emitting device 1 are listed in the following table.

TABLE 1

| | Hole- | Hole- | | | Electron- | | Electron- |
|---|---|---|---|---|---|---|---|
| | injection | transport layer | | Light-emitting | transport layer | | injection |
| | layer | 1 | 2 | layer | 1 | 2 | layer |
| | 10 nm | 20 nm | 10 nm | 25 nm | 12.5 nm | 12.5 nm | 1 nm |
| Light-emitting | BBABnf: | BBABnf | PCzN2 | αN-βNPAnth: | OCET010:Liq | | Liq |
| device 1 | OCHD-001 | | | 3,10PCANbf(IV)-02 | (1:2) | (2:1) | |
| Light-emitting | (1:0.1) | | | (1:0.015) | NBPhen:Liq | | |
| device 2 | | | | | (1:2) | (2:1) | |
| Comparative | | | | | aN-bNPAnth:Liq | | |
| light-emitting | | | | | (1:2) | (2:1) | |
| device 1 | | | | | | | |

These light-emitting devices were subjected to sealing with a glass substrate (a sealant was applied to surround the elements, followed by UV treatment and one-hour heat treatment at 80° C. at the time of sealing) in a glove box containing a nitrogen atmosphere so that the light-emitting devices are not exposed to the air. Then, the initial characteristics and reliability of the light-emitting device 1, the light-emitting device 2, and the comparative light-emitting device 1 were measured. Note that the measurement was performed at room temperature.

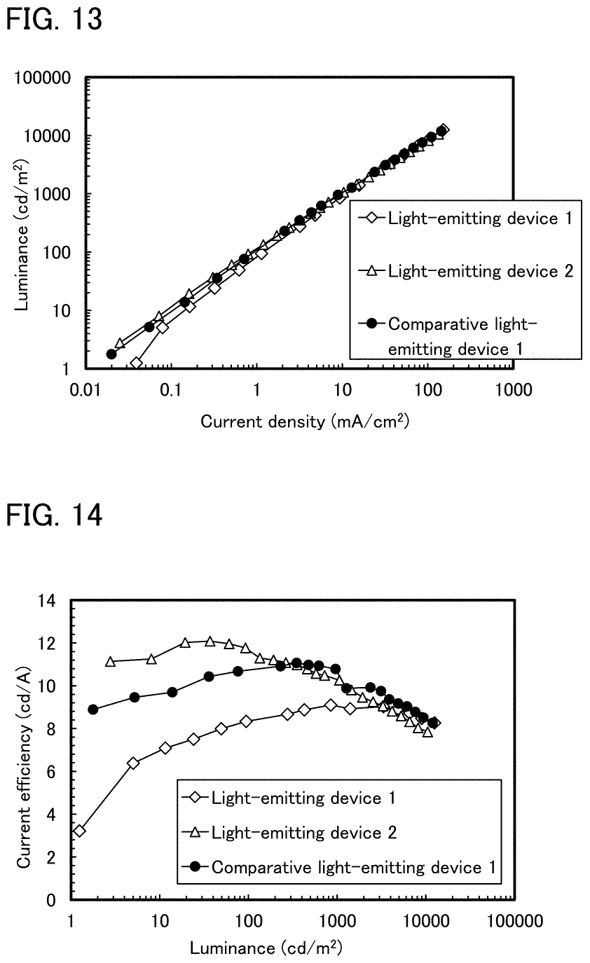

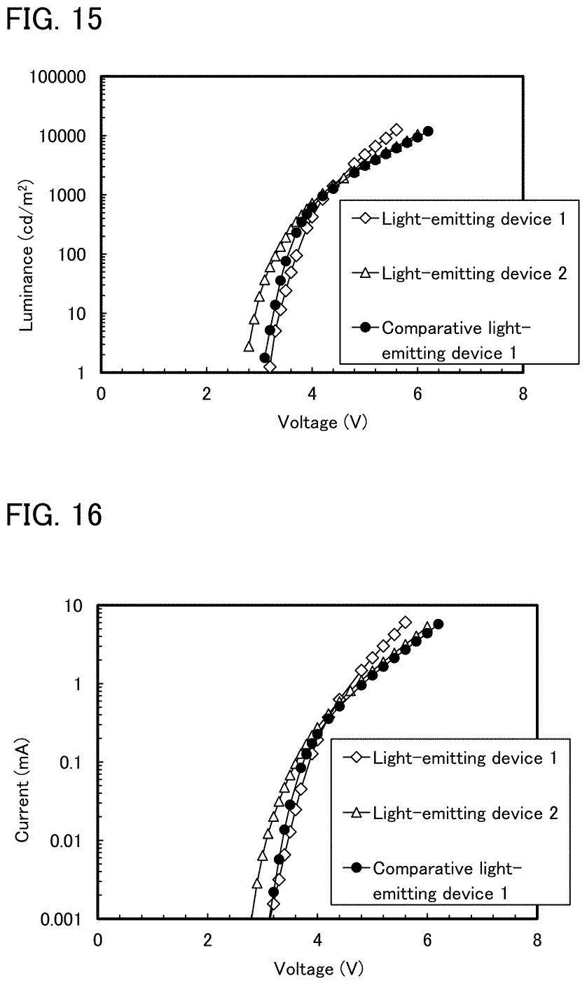

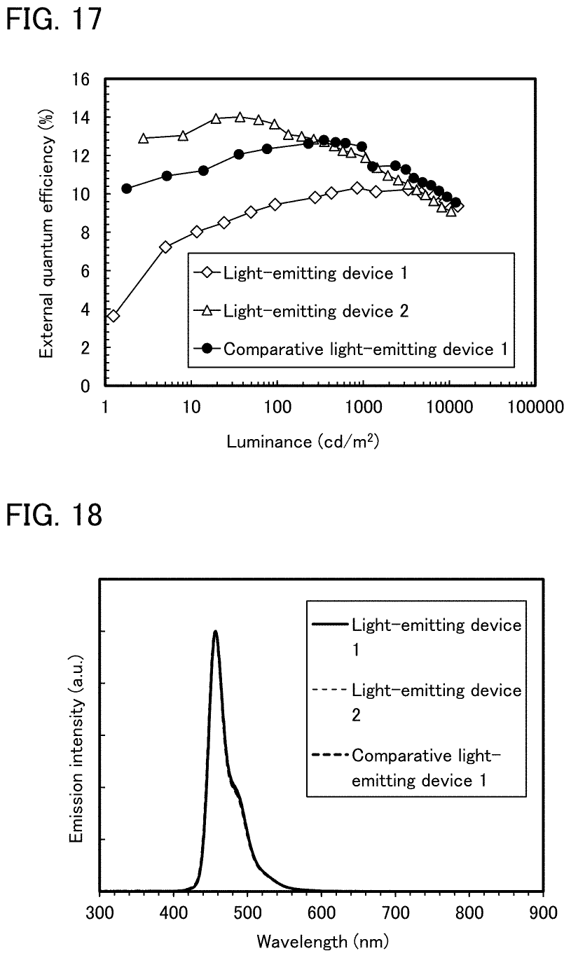

FIG. 13 shows the luminance-current density characteristics of the light-emitting device 1, the light-emitting device 2, and the comparative light-emitting device 1; FIG. 14, the current efficiency-luminance characteristics thereof, FIG. 15, the luminance-voltage characteristics thereof; FIG. 16, the current-voltage characteristics thereof, FIG. 17, the external quantum efficiency-luminance characteristics thereof; and FIG. 18, the emission spectra thereof. Table 2 shows the main characteristics of the light-emitting device 1, the light-emitting device 2, and the comparative light-emitting device 1 at around 1000 cd/m².

TABLE 2

| | | | Current | | | Current | External |
|---|---|---|---|---|---|---|---|
| | Voltage | Current | density | Chromaticity | Chromaticity | efficiency | quantum |
| | (V) | (mA) | (mA/cm²) | x | y | (cd/A) | efficiency (%) |
| Light-emitting | 4.2 | 0.37 | 9.3 | 0.14 | 0.10 | 9.1 | 10.3 |
| device 1 | | | | | | | |
| Light-emitting | 4.2 | 0.41 | 10.4 | 0.14 | 0.10 | 10.3 | 11.9 |
| device 2 | | | | | | | |
| Comparative light- | 4.2 | 0.36 | 8.9 | 0.14 | 0.10 | 10.8 | 12.5 |
| emitting device 1 | | | | | | | |

FIG. 13 to FIG. 18 and Table 2 show that the three devices are blue-light-emitting devices with favorable initial characteristics.

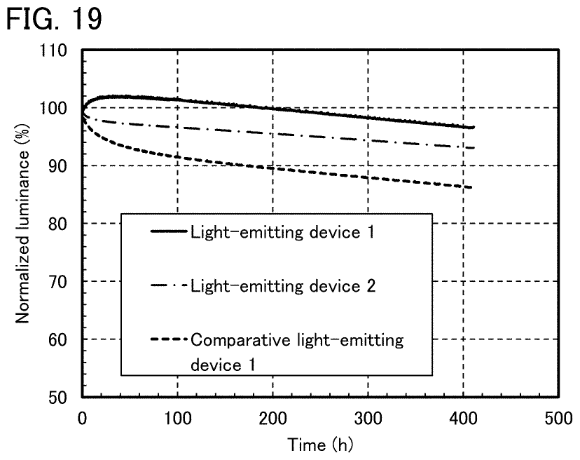

A graph showing a change in luminance over driving time at a current density of 50 mA/cm² is shown in FIG. 19. FIG. 19 indicates that the light-emitting device 1 and the light-emitting device 2, which are the light-emitting devices of embodiments of the present invention, have a longer lifetime than the comparative light-emitting device 1. In particular, the light-emitting device 1 has a longer lifetime with an increase in luminance at the initial driving stage. The light-emitting device 2 has a small slope of long-term decay and is resistant to long-term driving.

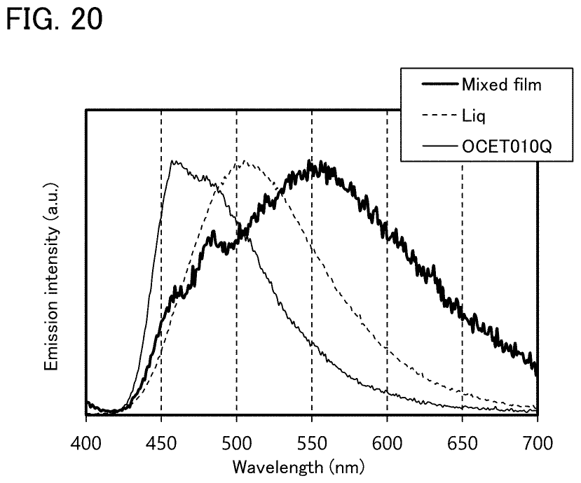

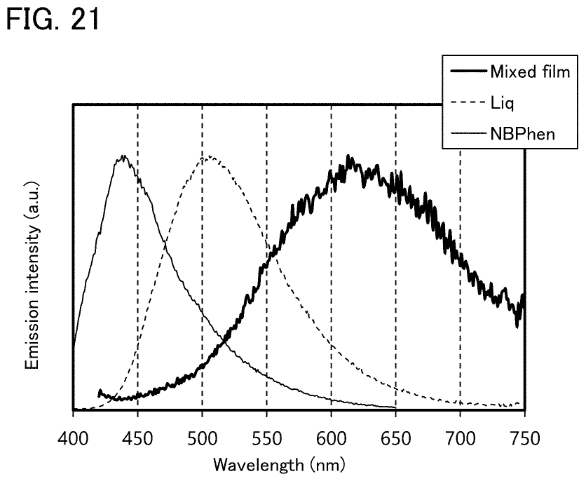

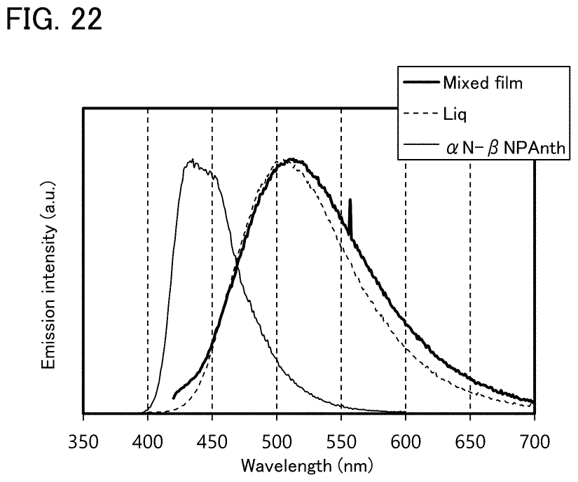

Shown here are the results of measuring the photoluminescence properties of the materials used in the electron-transport layer of each device. For the measurement, a fluorescence spectrophotometer (FS920 produced by Hamamatsu Photonics K.K.) or a fluorescence spectrophotometer (FP-8600 produced by JASCO Corporation) was used. FIG. 20 shows the emission spectra of an OCET010Q film, a Liq film, and a mixed film of OCET010 and Liq mixed at a mass ratio of 1:1, which are used in the light-emitting device 1; FIG. 21 shows the emission spectra of an NBPhen film, a Liq film, and a mixed film of NBPhen and Liq mixed at a mass ratio of 1:1, which are used in the light-emitting device 2; and FIG. 22 shows the emission spectra of an αN-βNPAnth film, a Liq film, and a mixed film of αN-βNPAnth and Liq mixed at a mass ratio of 1:1, which are used in the comparative light-emitting device 1.

In FIG. 20, the emission spectrum of the mixed film of OCET010 and Liq mixed at a mass ratio of 1:1 shifts to a much longer wavelength side than the emission spectra of the OCET010 film and the Liq film, suggesting that OCET010 and Liq form an exciplex. It is also suggested that NBPhen and Liq form an exciplex according to FIG. 21. By contrast, in FIG. 22, the spectrum of the mixed film of αN-βNPAnth and Liq is almost the same as that of Liq though it is somewhat broader on the longer wavelength side; thus, an exciplex is probably not formed.

Note that an exciplex is formed by interaction of molecular orbitals of two substances; the exciplex probably emits light having a peak at a wavelength corresponding to the difference between a shallower HOMO level and a deeper LUMO level of the levels of the two substances.

The HOMO level and the LUMO level can be calculated through cyclic voltammetry (CV) measurement.

An electrochemical analyzer (manufactured by BAS Inc., model No. ALS model 600A or 600C) was used as a measurement apparatus. To prepare a solution for the CV measurement, dehydrated dimethylformamide (DMF) (manufactured by Sigma-Aldrich Inc., 99.8%, catalog No. 22705-6) was used as a solvent, tetra-n-butylammonium perchlorate (n-Bu₄NClO₄) (manufactured by Tokyo Chemical Industry Co., Ltd., catalog No. T0836) as a supporting electrolyte was dissolved at a concentration of 100 mmol/L, and the object to be measured was dissolved at a concentration of 2 mmol/L. A platinum electrode (PTE platinum electrode manufactured by BAS Inc.) was used as a working electrode, another platinum electrode (Pt counter electrode for VC-3 (5 cm) manufactured by BAS Inc.) was used as an auxiliary electrode, and an Ag/Ag⁺ electrode (RE7 reference electrode for non-aqueous solvent manufactured by BAS Inc.) was used as a reference electrode. Note that the measurement was conducted at room temperature (20 to 25° C.). The scan speed in the CV measurement was fixed to 0.1 V/sec, and an oxidation potential Ea [V] and a reduction potential Ec [V] with respect to the reference electrode were measured. Ea is an intermediate potential of an oxidation-reduction wave, and Ec is an intermediate potential of a reduction-oxidation wave. Here, since the potential energy of the reference electrode used in this example with respect to the vacuum level is known to be −4.94 [eV], the HOMO level and the LUMO level can be calculated by the following formulae: HOMO level [eV]=−4.94−Ea and LUMO level [eV]=−4.94−Ec (where the potential values can be converted into electron volts to be calculated because Ea and Ec denote a one-electron oxidation potential and a one-electron reduction potential, respectively).

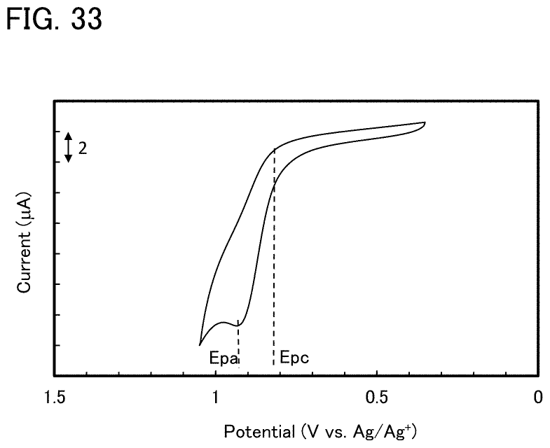

FIG. 33 shows the oxidation-reduction wave of OCET010. In the oxidation-reduction wave of OCET010, the oxidation peak potential (Epa) was observed at 0.936 V and the reduction peak potential (Epc) was observed at 0.822 V. Accordingly, Ea was found to be 0.88 V and the HOMO level of OCET010 was calculated to be −5.82 eV.

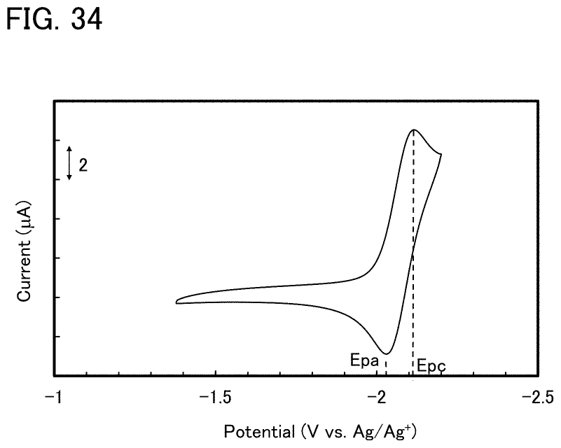

FIG. 34 shows the reduction-oxidation wave of OCET010. In the reduction-oxidation wave of OCET010, the reduction peak potential (Epc) was observed at −2.113 V and the oxidation peak potential (Epa) was observed at −2.029 V. Accordingly, Ec was found to be −2.07 V and the LUMO level of OCET010 was calculated to be −2.87 eV.

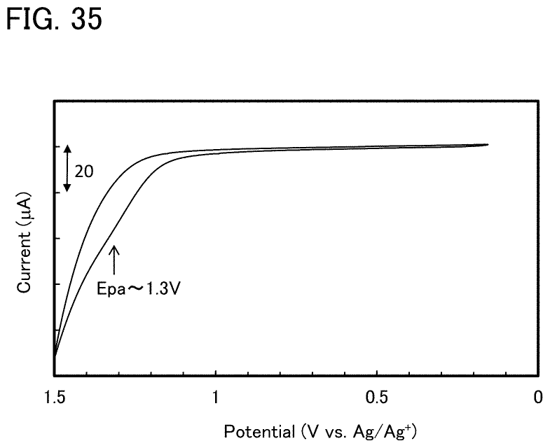

FIG. 35 shows the oxidation-reduction wave of NBPhen. In the oxidation-reduction wave of NBPhen, the oxidation peak potential (Epa) was observed at approximately 1.3 V as a broad shoulder peak. In contrast, the reduction peak potential (Epc) was not observed; thus, it was assumed that the difference between Epa and Epc was approximately 0.1 V (because the difference between Epa and Epc is known to be a little less than 60 mV in an ideal diffusion system with a sufficient high electron mobility). That is, Epc in the oxidation-reduction wave of NBPhen was set to 1.2 V here. Accordingly, Ea of NPBhen was found to be 1.25 V; the HOMO level of NBPhen was calculated to be approximately −6.2 eV because calculation should be performed to the first decimal place as significant figures according to the broad peak of Epa and the above assumption.

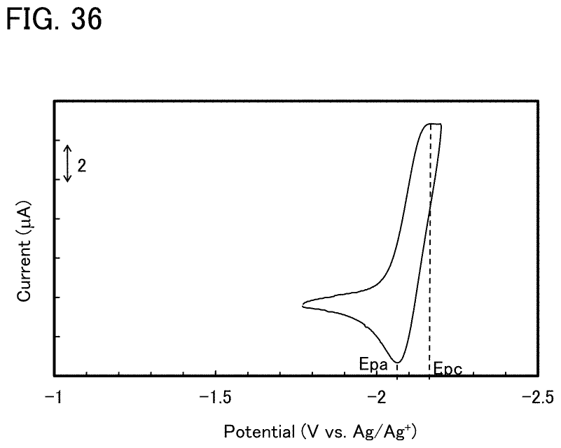

FIG. 36 shows the reduction-oxidation wave of NBPhen. In the reduction-oxidation wave of NBPhen, the reduction peak potential (Epc) was observed at −2.166 V and the oxidation peak potential (Epa) was observed at −2.062 V. Accordingly, Ec was found to be −2.12 V and the LUMO level of NBPhen was calculated to be −2.83 eV.

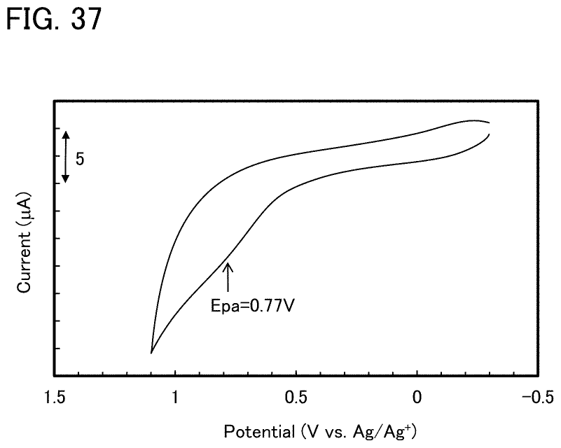

FIG. 37 shows the oxidation-reduction wave of Liq. In the oxidation-reduction wave of Liq, the oxidation peak potential (Epa) was observed at approximately 0.77 eV as a shoulder peak. In contrast, the reduction peak potential (Epc) was not observed; thus, it was assumed that the difference between Epa and Epc was approximately 0.1 V (because the difference between Epa and Epc is known to be a little less than 60 mV in an ideal diffusion system with a sufficient high electron mobility). That is, Epc in the oxidation-reduction wave of Liq was set to 0.67 V here. Accordingly, Ea of Liq was calculated to be 0.72 eV; the HOMO level of Liq was calculated to be approximately −5.7 eV because calculation should be performed to the first decimal place as significant figures according to the above assumption.

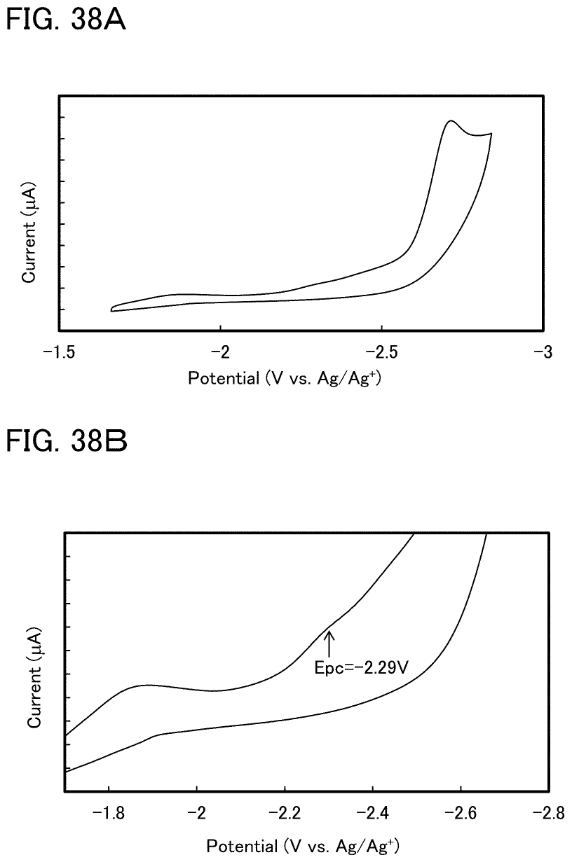

FIG. 38 shows the reduction-oxidation wave of Liq. Note that FIG. 38B shows an enlarged view in the range of −1.7 V to −2.8 V in FIG. 38A. In the reduction-oxidation wave of Liq, the reduction peak potential (Epc) was observed at approximately −2.29 V as a shoulder peak. In contrast, the oxidation peak potential (Epa) was not observed; thus, it was assumed that the difference between Epa and Epc was approximately 0.1 V (because the difference between Epa and Epc is known to be a little less than 60 mV in an ideal diffusion system with a sufficient high electron mobility). That is, Epc in the reduction-oxidation wave of Liq was assumed to be −2.19 V here. Accordingly, Ec of Liq was calculated to be −2.24 eV; the LUMO level of Liq was calculated to be −2.7 eV because calculation should be performed to the first decimal place as significant figures according to the above assumption.

Table 3 shows the HOMO level and the LUMO level calculated above for each of OCET010 and NBPhen, which are organic compounds having electron-transport properties used for the electron-transport layers of the light-emitting device 1 and the light-emitting device 2; the difference between the LUMO level of each of the two materials and the HOMO level of Liq, which is an organometallic complex of an alkali metal (ΔE_{LUMO-HOMO}); the peak wavelength of the emission spectrum of an exciplex of each of the materials and Liq (λp_{Ex}); the value obtained by converting the peak wavelength into energy (E_{Ex}); and the value obtained by subtracting E_{Ex} from ΔE_{LUMO-HOMO} (ΔE_{HL}−E_{Ex}). Since the significant figures of the HOMO level of Liq are to the first decimal place as described above, the significant figures of each of ΔE_{LUMO-HOMO} and ΔE_{HL}-E_{Ex} are to the first decimal place.

TABLE 3

| | | | ΔE_{LUMO-} | | | ΔE_{HL}- |
|---|---|---|---|---|---|---|
| | HOMO | LUMO | _{HOMO} | λp_{Ex} | E_{Ex} | E_{Ex} |
| | (eV) | (eV) | (eV) | (nm) | (eV) | (eV) |
| OCET010 | −5.82 | −2.87 | 2.8 | 560 | 2.21 | 0.6 |
| NBPhen | −6.2 | −2.83 | 2.9 | 621 | 2.00 | 0.9 |

*HOMO of Liq = −5.7 eV, LUMO = −2.7 eV

FIG. 20 and FIG. 21 show that each of OCET010 and NBPhen probably forms an exciplex with Liq, which is an organometallic complex of an alkali metal, in the electron-transport layers of the light-emitting device 1 and the light-emitting device 2 (note that the exciplex can be specified by the observation of no new absorption peak in the absorption spectrum of the mixed film after the mixture). As described above, the value obtained by converting the peak wavelength of the emission spectrum of the exciplex into energy is generally expected to be a value close to the difference between the HOMO level of Liq and the LUMO level of OCET010 or the difference between the HOMO level of Liq and the LUMO level of NBPhen; however, the light-emitting device of this invention exhibits large ΔE_{HL}-E_{Ex} values, 0.6 eV and 0.9 eV, as shown in Table 3. It was thus found that the light-emitting device of one embodiment of the present invention had a ΔE_{HL}-E_{Ex} of 0.5 eV or more, and the value obtained by converting into energy the peak wavelength of the emission spectrum of the exciplex formed in the electron-transport layer of the light-emitting device was smaller than the difference between the HOMO level of Liq and the LUMO level of OCET010 or NBPhen by greater than or equal to 0.5 eV.

The light-emitting device 2 in which the peak wavelength of the emission spectrum of the exciplex was greater than or equal to 570 nm had a smaller slope of long-term decay than the light-emitting device 1 in which the peak wavelength was less than or equal to 570 nm. The peak wavelength of the emission spectrum of the exciplex in the light-emitting device 2 was greater than or equal to 610 nm, indicating that the light-emitting device 2 had higher emission efficiency.

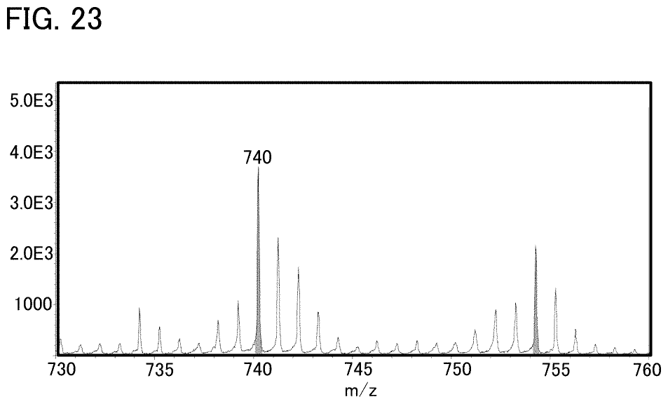

Then, the mixed film of NBPhen and Liq used in the electron-transport layer 114 of the light-emitting device 2 was analyzed by ToF-SIMS (Time-of-Flight Secondary Ion Mass Spectrometry), and part of the results is shown in FIG. 23. FIG. 23 shows the results in the ToF-SIMS analysis with m/z of positive ions in the range of 730 to 760. Ions detected at m/z=740 in the graph correspond to ions of the molecular weight of NBPhen+the molecular weight of Liq+the atomic weight of Li−2. This is a distinctive result obtained by measuring the materials of the electron-transport layer in the light-emitting device of the present invention.

In the light-emitting device including the electron-transport layer containing an organic compound having an electron-transport property and an organic compound of an alkali metal, when positive ions are detected at m/z=M_{E}+M_{ACom}+M_{A}−2 (where M_{E} is the molecular weight of the organic compound having an electron-transport property, M_{ACom} is the molecular weight of an organometallic complex of an alkali metal, and MA is the molecular weight of the alkali metal) by measuring the electron-transport layer or a film equivalent to the electron-transport layer by mass spectrometry, and when the aforementioned ΔE_{LUMO-HOMO} (the difference between the LUMO level of the organic compound having an electron-transport property and the HOMO level of the organometallic complex of an alkali metal) is less than or equal to 2.9 eV, the light-emitting device can have a long lifetime as the light-emitting device 1 and the light-emitting device 2 described above. Note that the electron-transport layer of the comparative light-emitting device 1 uses the mixed film of αN-βNPAnth and Liq; an exciplex is not formed in the mixed film in which αN-βNPAnth and Liq are mixed at a mass ratio of 1:1 and the ΔE_{LUMO-HOMO} of the mixed film is 3.0 eV.

### EXAMPLE 2

Described in this example is a fabrication method of a light-emitting device 3 of one embodiment of the present invention. Structural formulae of materials used in this example are shown below.

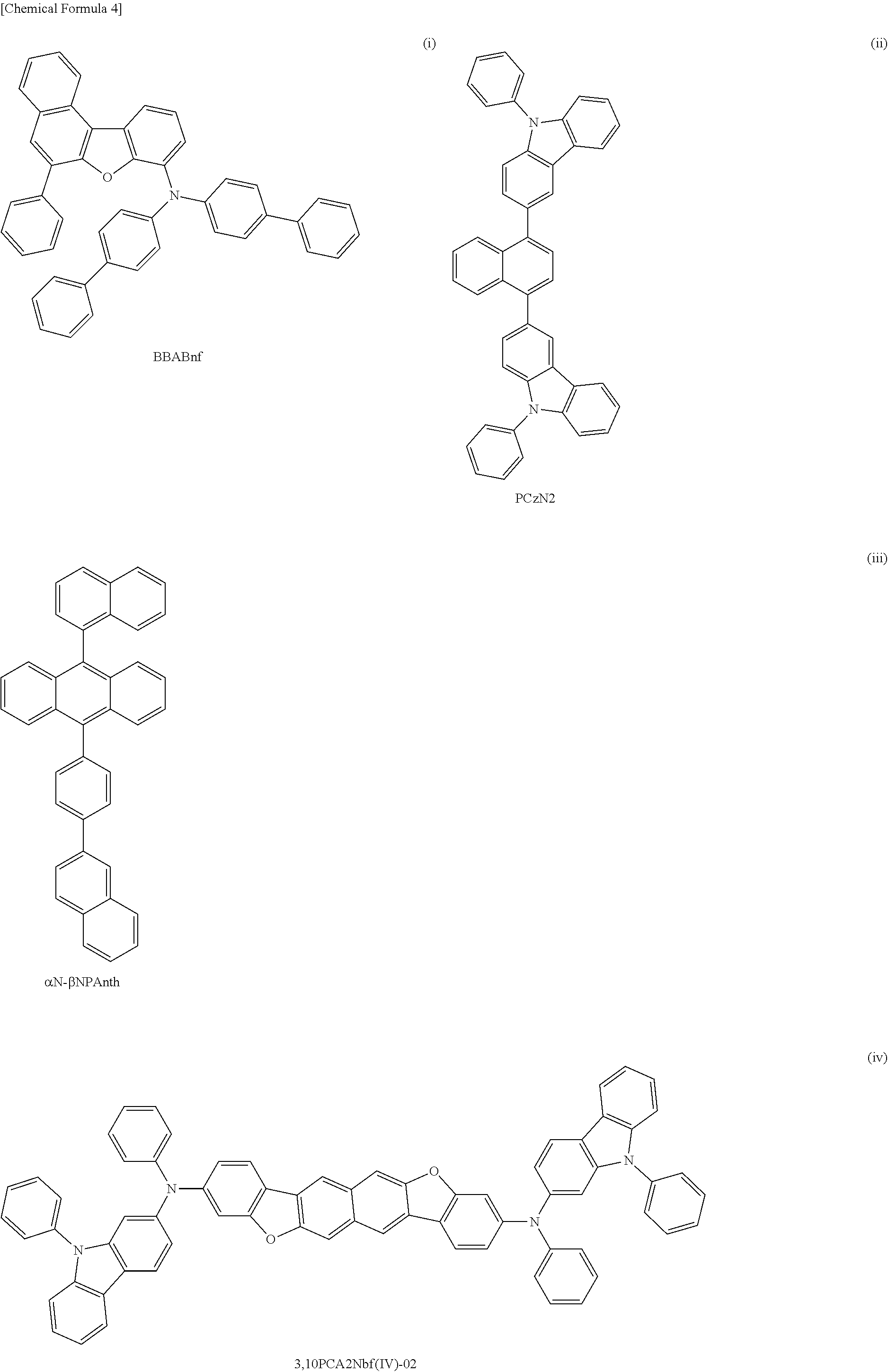

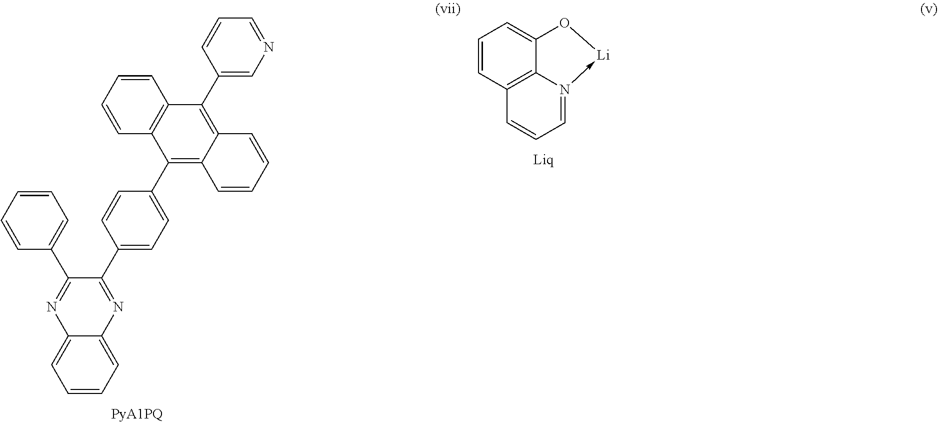

### <<Fabrication Method of Light-Emitting Device 3>>

First, indium tin oxide containing silicon oxide (ITSO) was deposited on a glass substrate by a sputtering method to form the anode 101. Note that the film thickness was 70 nm and the area of the electrode was 4 mm² (2 mm×2 mm).

Next, in pretreatment for forming the light-emitting device over the substrate, the surface of the substrate was washed with water and baked at 200° C. for one hour, and then UV ozone treatment was performed for 370 seconds.

After that, the substrate was transferred into a vacuum evaporation apparatus in which the pressure was reduced to approximately 10⁻⁴ Pa, vacuum baking at 170° C. for 30 minutes was performed in a heating chamber in the vacuum evaporation apparatus, and then the substrate was cooled down for approximately 30 minutes.

Then, the substrate on which the anode 101 was formed was fixed to a substrate holder provided in the vacuum evaporation apparatus such that the surface on which the anode 101 was formed faced downward. On the anode 101, N,N-bis(4-biphenyl)-6-phenylbenzo[b]naphtho[1,2-d]furan-8-amine (abbreviation: BBABnf) represented by Structural Formula (i) above and an electron acceptor material (OCHD-001) were deposited by co-evaporation to a thickness of 10 nm at a mass ratio of 1:0.1 (=BBABnf: OCHD-001) by an evaporation method using resistance heating, whereby the hole-injection layer 111 was formed.

Next, as the first hole-transport layer 112-1, BBABnf was deposited by evaporation to a thickness of 20 nm over the hole-injection layer 111, and then, as the second hole-transport layer 112-2, 3,3′-(naphthalene-1,4-diyl)bis(9-phenyl-9H-carbazole) (abbreviation: PCzN2) represented by Structural Formula (ii) above was deposited by evaporation to a thickness of 10 nm, whereby the hole-transport layer 112 was formed. Note that the second hole-transport layer 112-2 also functions as an electron-blocking layer.

Subsequently, 9-(1-naphthyl)-10-[4-(2-naphthyl)phenyl]anthracene (abbreviation: α,N-βNPAnth) represented by Structural Formula (iii) above, and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) represented by Structural Formula (iv) were deposited by co-evaporation to a thickness of 25 nm at a mass ratio of 1:0.015 (=α,N-βNPAnth: 3,10PCA2Nbf(IV)-02), so that the light-emitting layer 113 was formed.

After that, over the light-emitting layer 113, 2-phenyl-3-[10-(3-pyridyl)-9-anthryl]phenylquinoxaline (abbreviation: PyA1PQ) represented by Structural Formula (viii) above, and 8-hydroxyquinolinato-lithium (abbreviation: Liq) represented by Structural Formula (vi) above were deposited by co-evaporation to a thickness of 12.5 nm at a mass ratio of 1:2 (=PyA1PQ: Liq); then, they were deposited by co-evaporation to a thickness of 12.5 nm at a mass ratio of 2:1 (=PyA1PQ: Liq), so that the electron-transport layer 114 was formed.

After the formation of the electron-transport layer 114, Liq was deposited by evaporation to a thickness of 1 nm to form the electron-injection layer 115, and then aluminum was deposited by evaporation to a thickness of 200 nm to form the cathode 102, whereby the light-emitting device 3 of this example was fabricated.

The element structure of the light-emitting device 3 is listed in the following table.

TABLE 4

| | Hole- | | | | | | Electron- |
|---|---|---|---|---|---|---|---|
| | injection | Hole-transport layer | | | Electron-transport layer | | injection |
| | layer | 1 | 2 | Light-emitting layer | 1 | 2 | layer |
| | 10 nm | 20 nm | 10 nm | 25 nm | 12.5 nm | 12.5 nm | 1 nm |
| Light- | BBABnf: | BBABnf | PCzN2 | αN-βNPAnth: | PyA1PQ:Liq | | Liq |
| emitting | OCHD-001 | | | 3,10PCANbf(IV)-02 | (1:2) | (2:1) | |
| device 3 | (1:0.1) | | | (1:0.015) | | | |

This light-emitting device was subjected to sealing with a glass substrate (a sealant was applied to surround the element, followed by UV treatment and one-hour heat treatment at 80° C. at the time of sealing) in a glove box containing a nitrogen atmosphere so that the light-emitting device is not exposed to the air. Then, the initial characteristics and reliability of the light-emitting device 3 were measured. Note that the measurement was performed at room temperature.

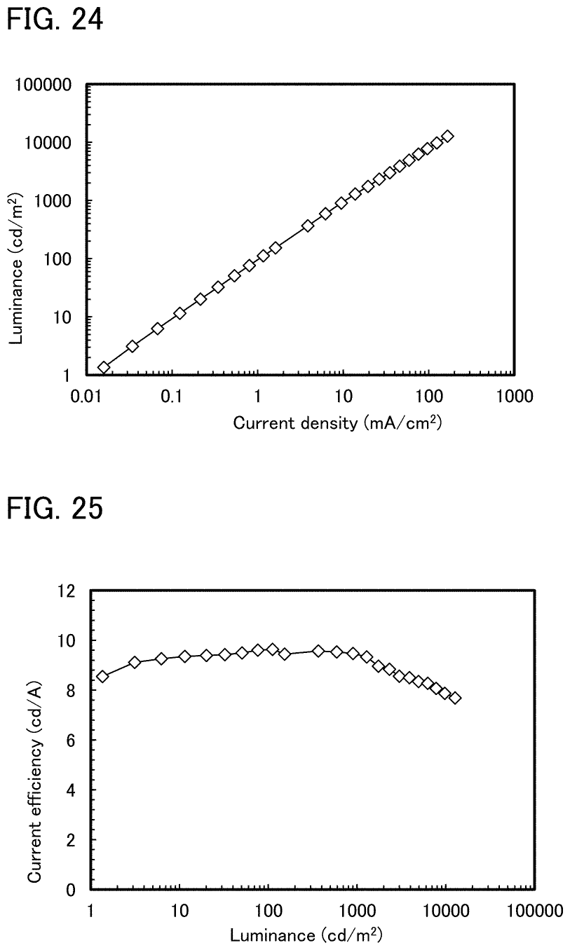

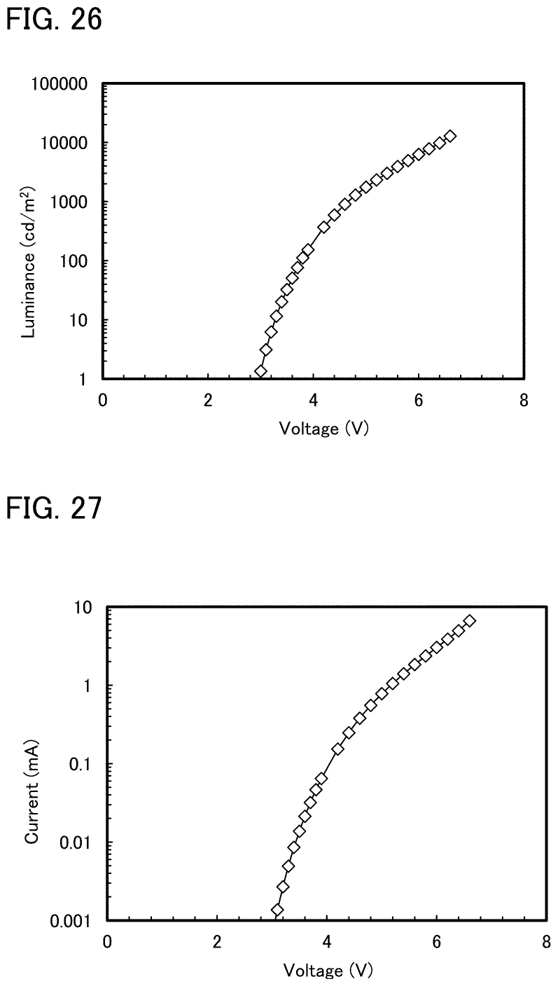

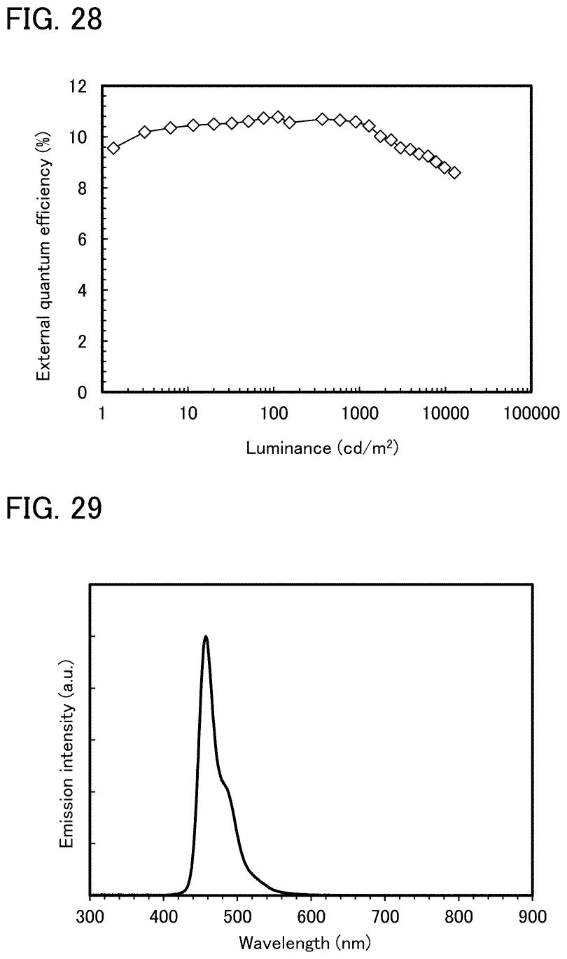

FIG. 24 shows the luminance-current density characteristics of the light-emitting device 3; FIG. 25, the current efficiency-luminance characteristics thereof; FIG. 26, the luminance-voltage characteristics thereof, FIG. 27, the current-voltage characteristics thereof; FIG. 28, the external quantum efficiency-luminance characteristics thereof; and FIG. 29, the emission spectrum thereof. Table 5 shows the main characteristics of the light-emitting device 3 at around 1000 cd/m².

TABLE 5

| | | | | | | Current | External |
|---|---|---|---|---|---|---|---|
| | Voltage | Current | Current density | | | efficiency | quantum |
| | (V) | (mA) | (mA/cm² ) | Chromaticity x | Chromaticity y | (cd/A) | efficiency (%) |
| Light-emitting | 4.6 | 0.38 | 9.5 | 0.14 | 0.11 | 9.5 | 10.6 |
| device 3 | | | | | | | |

FIG. 24 to FIG. 29 and Table 5 show that the light-emitting device 3 is a blue-light-emitting device with favorable initial characteristics.

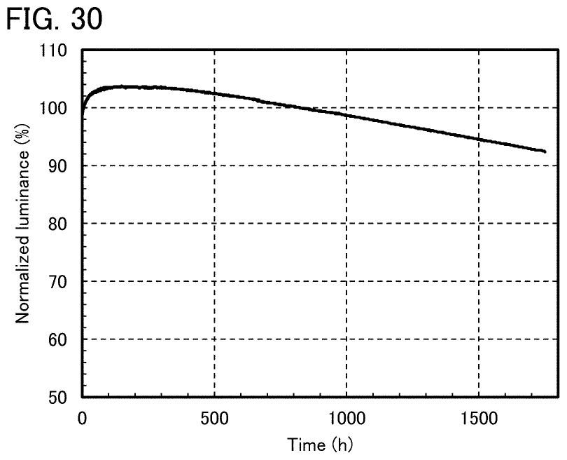

A graph showing a change in luminance over driving time at a current density of 50 mA/cm² is shown in FIG. 30. As shown in FIG. 30, the light-emitting device 3 of one embodiment of the present invention has reduced initial decay with an increase in luminance at the initial driving stage; furthermore, the light-emitting device 3 has a small slope of long-term decay to have a significantly long lifetime.

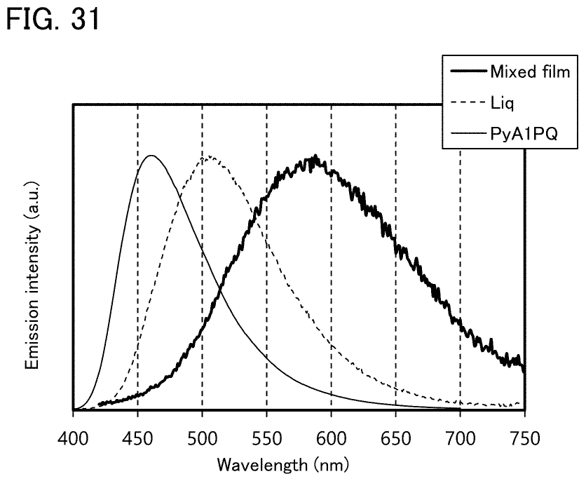

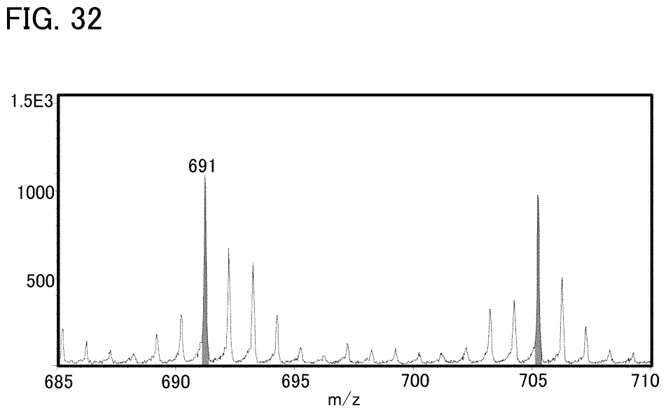

Shown here are the results of measuring the photoluminescence properties of the materials used in the electron-transport layer of the light-emitting device 3. For the measurement, a fluorescence spectrophotometer (FS920 produced by Hamamatsu Photonics K.K.) was used. FIG. 31 shows the emission spectra of a PyA1PQ film, a Liq film, and a mixed film of PyA1PQ and Liq mixed at a mass ratio of 1:1, which are used in the light-emitting device 3.

In FIG. 31, the emission spectrum of the mixed film of PyA1PQ and Liq mixed at a mass ratio of 1:1 shifts to a much longer wavelength side than the emission spectra of the PyA1PQ film and the Liq film, suggesting that PyA1PQ and Liq form an exciplex.

Note that an exciplex is formed by interaction of molecular orbitals of two substances; the exciplex probably emits light having a peak at a wavelength corresponding to the difference between a shallower HOMO level and a deeper LUMO level of the levels of the two substances.

Table 6 shows the HOMO level and the LUMO level of PyA1PQ, which is an organic compound having an electron-transport property used for the electron-transport layer of the light-emitting device 3; the difference between the LUMO level of PyA1PQ and the HOMO level of Liq, which is an organometallic complex of an alkali metal (ΔE_{LUMO-HOMO}); the peak wavelength of the emission spectrum of an exciplex of PyA1PQ and Liq (λp_{Ex}); the value obtained by converting the peak wavelength into energy (E_{Ex}); and the value obtained by subtracting E_{Ex} from ΔE_{HOMO-LUMO} (ΔE_{HL}-E_{Ex}). The measurement method and calculation method of the HOMO level and the LUMO level are omitted because described in Example 1. Refer to the description in Example 1. As in Example 1, since the significant figures of the HOMO level of Liq are to the first decimal place, the significant figures of each of ΔE_{LUMO-HOMO} and ΔE_{HL}-E_{Ex} are to the first decimal place.

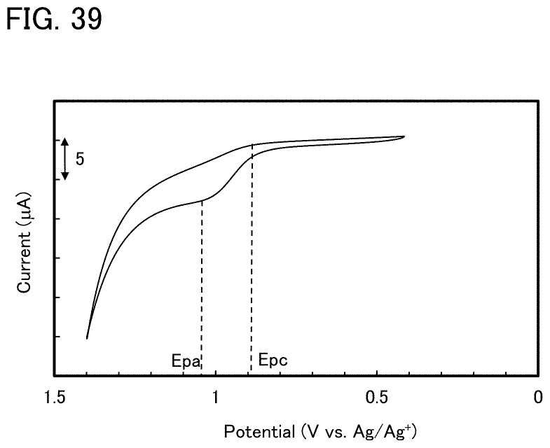

FIG. 39 shows the oxidation-reduction wave of PyA1PQ. In the oxidation-reduction wave of PyA1PQ, the oxidation peak potential (Epa) was observed at 1.045 V and the reduction peak potential (Epc) was observed at 0.885 V. Accordingly, Ea was found to be 0.97 V and the HOMO level of PyA1PQ was calculated to be −5.91 eV.

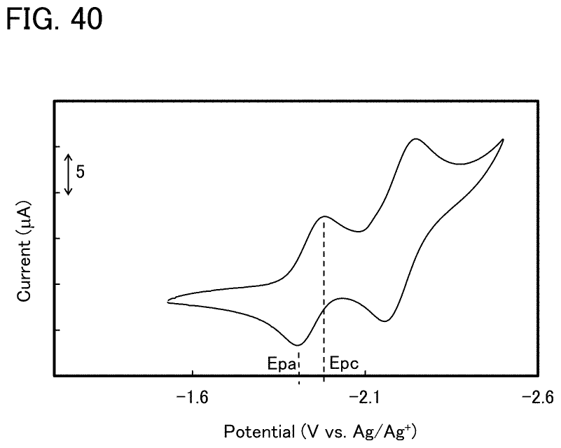

FIG. 40 shows the reduction-oxidation wave of PyA1PQ. In the reduction-oxidation wave of PyA1PQ, the reduction peak potential (Epc) was observed at −1.984 V and the oxidation peak potential (Epa) was observed at −1.904 V. Accordingly, Ec was found to be −1.94 V and the LUMO level of PyA1PQ was calculated to be −3.00 eV.

TABLE 6

| | | | ΔE_{LUMO-} | | | |
|---|---|---|---|---|---|---|
| | HOMO | LUMO | _{HOMO} | λp_{Ex} | E_{Ex} | ΔE_{HL}-E_{Ex} |
| | (eV) | (eV) | (eV) | (nm) | (eV) | (eV) |
| PyA1PQ | −5.91 | −3.00 | 2.7 | 588 | 2.11 | 0.6 |

*HOMO of Liq = −5.7 eV, LUMO = −2.7 eV

FIG. 31 shows that PyA1PQ probably forms an exciplex with Liq in the electron-transport layer of the light-emitting device 3 (note that the exciplex can be specified by the observation of no new absorption peak in the absorption spectrum of the mixed film after the mixture). As described above, the value obtained by converting the peak wavelength of the emission spectrum of the exciplex into energy is generally expected to be a value close to the difference between the HOMO level of Liq and the LUMO level of PyA1PQ; however, the light-emitting device 3 exhibits a large ΔE_{HL}-E_{Ex} value, 0.6 eV, as shown in Table 6. It was thus found that the light-emitting device of one embodiment of the present invention had a ΔE_{HL}-E_{Ex} of 0.5 eV or more, and the value obtained by converting into energy the peak wavelength of the emission spectrum of the exciplex formed in the electron-transport layer of the light-emitting device was smaller than the difference between the HOMO level of Liq and the LUMO level of PyA1PQ by greater than or equal to 0.5 eV.

The light-emitting device 3 in which the peak wavelength of the emission spectrum of the exciplex was greater than or equal to 570 nm had a small slope of long-term decay. The peak wavelength of the emission spectrum of the exciplex in the light-emitting device 3 is greater than or equal to 570 nm and less than 610 nm; thus, the light-emitting device 3 is a significantly long lifetime light-emitting device having an increase in luminance at the initial driving stage and a small slope of long-term decay.

Then, the mixed film of PyA1PQ and Liq used in the electron-transport layer 114 of the light-emitting device 3 was analyzed by ToF-SIMS, and part of the results is shown in FIG. 32. FIG. 32 shows the results in the ToF-SIMS analysis with m/z of positive ions in the range of 685 to 710. Ions detected at m/z=691 in the graph correspond to ions of PyA1PQ (molecular weight)+Liq (molecular weight)+Li (molecular weight)−2. This is a distinctive result obtained by measuring the materials of the electron-transport layer in the light-emitting device of the present invention.

In the light-emitting device, when positive ions are detected at m/z=M_{E}+M_{ACom}+M_{A}−2 (where M_{E} is the molecular weight of the organic compound having an electron-transport property, M_{ACom} is the molecular weight of an organometallic complex of an alkali metal, and MA is the molecular weight of the alkali metal) by measuring the electron-transport layer or a film equivalent to the electron-transport layer by mass spectrometry, and when the aforementioned ΔE_{LUMO-HOMO} (the difference between the LUMO level of the organic compound having an electron-transport property and the HOMO level of the organometallic complex of an alkali metal) is less than or equal to 2.9 eV, the light-emitting device can have a long lifetime as the light-emitting device 3 described above.

### EXAMPLE 3

Described in this example is a fabrication method of a light-emitting device 4 of one embodiment of the present invention. Structural formulae of materials used in this example are shown below.

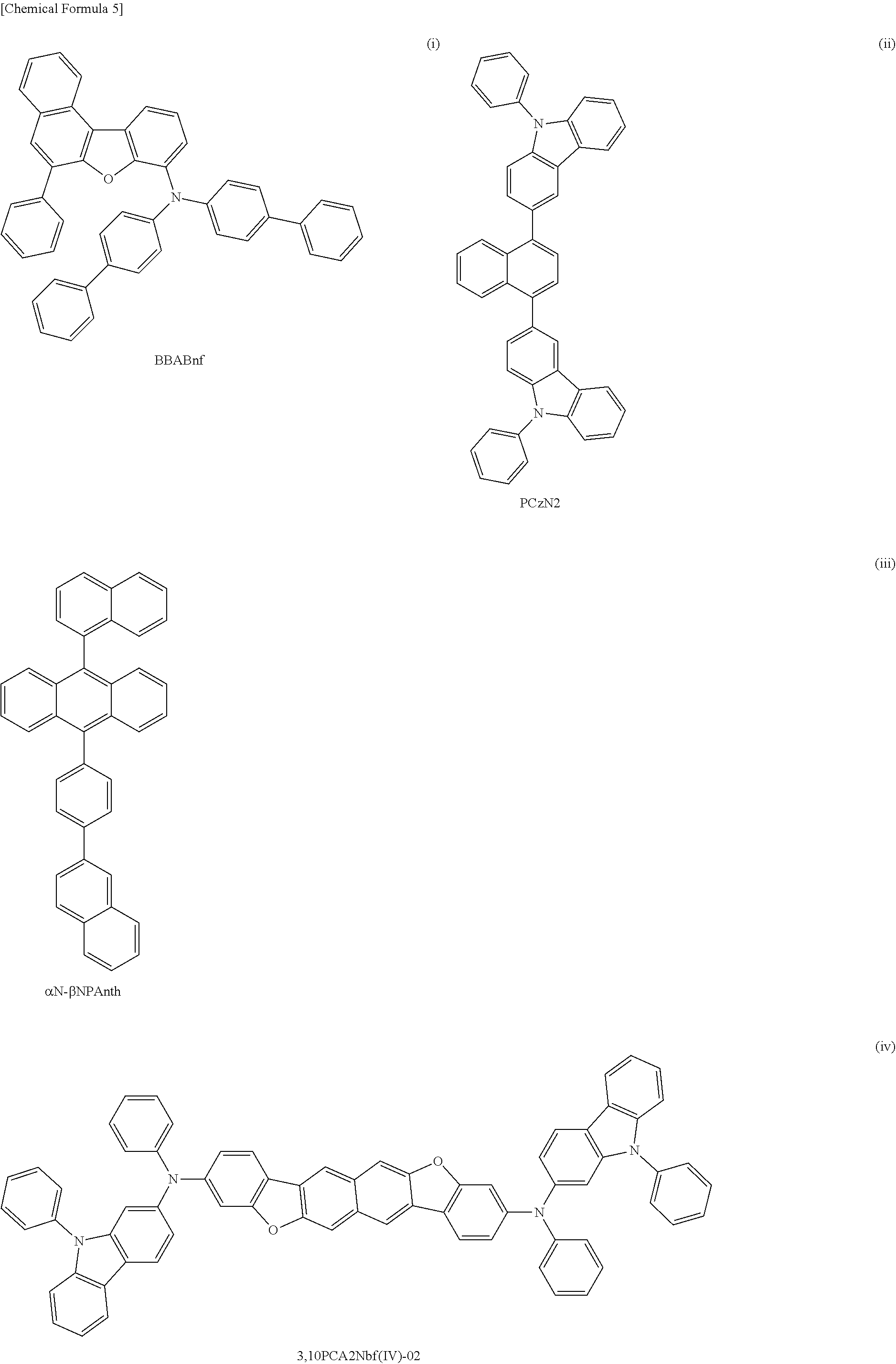

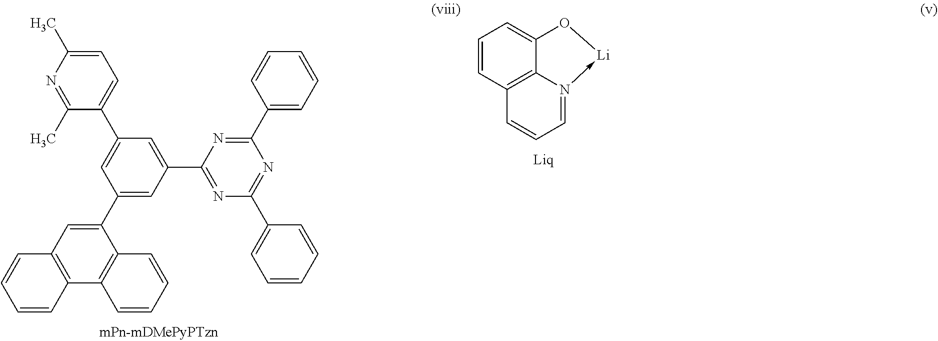

### <<Fabrication Method of Light-Emitting Device 4>>

First, indium tin oxide containing silicon oxide (ITSO) was deposited on a glass substrate by a sputtering method to form the anode 101. Note that the film thickness was 70 nm and the area of the electrode was 4 mm² (2 mm×2 mm).

Next, in pretreatment for forming the light-emitting device over the substrate, the surface of the substrate was washed with water and baked at 200° C. for one hour, and then UV ozone treatment was performed for 370 seconds.

After that, the substrate was transferred into a vacuum evaporation apparatus in which the pressure was reduced to approximately 10⁻⁴ Pa, vacuum baking at 170° C. for 30 minutes was performed in a heating chamber in the vacuum evaporation apparatus, and then the substrate was cooled down for approximately 30 minutes.

Then, the substrate on which the anode 101 was formed was fixed to a substrate holder provided in the vacuum evaporation apparatus such that the surface on which the anode 101 was formed faced downward. On the anode 101, N,N-bis(4-biphenyl)-6-phenylbenzo[b]naphtho[1,2-d]furan-8-amine (abbreviation: BBABnf) represented by Structural Formula (i) above and an electron acceptor material (OCHD-001) were deposited by co-evaporation to a thickness of 10 nm at a mass ratio of 1:0.1 (=BBABnf: OCHD-001) by an evaporation method using resistance heating, whereby the hole-injection layer 111 was formed.

Next, as the first hole-transport layer 112-1, BBABnf was deposited by evaporation to a thickness of 20 nm over the hole-injection layer 111, and then, as the second hole-transport layer 112-2, 3,3′-(naphthalene-1,4-diyl)bis(9-phenyl-9H-carbazole) (abbreviation: PCzN2) represented by Structural Formula (ii) above was deposited by evaporation to a thickness of 10 nm, whereby the hole-transport layer 112 was formed. Note that the second hole-transport layer 112-2 also functions as an electron-blocking layer.

Subsequently, 9-(1-naphthyl)-10-[4-(2-naphthyl)phenyl]anthracene (abbreviation: α,N-βNPAnth) represented by Structural Formula (iii) above, and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) represented by Structural Formula (iv) were deposited by co-evaporation to a thickness of 25 nm at a mass ratio of 1:0.015 (=αN-βNPAnth: 3,10PCA2Nbf(IV)-02), so that the light-emitting layer 113 was formed.

After that, over the light-emitting layer 113, 2-[3-(2,6-dimethyl-3-pyridinyl)-5-(9-phenanthrenyl)phenyl]-4,6-diphenyl-1,3,5-triazine (abbreviation: mPn-mDMePyPTzn) represented by Structural Formula (viii) above, and 8-hydroxyquinolinato-lithium (abbreviation: Liq) represented by Structural Formula (vi) above were deposited by co-evaporation to a thickness of 12.5 nm at a mass ratio of 1:2 (=mPn-mDMePyPTzn: Liq); then, they were deposited by co-evaporation to a thickness of 12.5 nm at a mass ratio of 2:1 (=mPn-mDMePyPTzn: Liq), so that the electron-transport layer 114 was formed.

After the formation of the electron-transport layer 114, Liq was deposited by evaporation to a thickness of 1 nm to form the electron-injection layer 115, and then aluminum was deposited by evaporation to a thickness of 200 nm to form the cathode 102, whereby the light-emitting device 4 of this example was fabricated.

The element structure of the light-emitting device 4 is listed in the following table.

TABLE 7

| | Hole- | | | | | | Electron- |
|---|---|---|---|---|---|---|---|
| | injection | Hole-transport layer | | | Electron-transport layer | | injection |
| | layer | 1 | 2 | Light-emitting layer | 1 | 2 | layer |
| | 10 nm | 20 nm | 10 nm | 25 nm | 12.5 nm | 12.5 nm | 1 nm |
| Light- | BBABnf: | BBABnf | PCzN2 | αN-βNPAnth: | mPn-mDMePyPTzn:Liq | | Liq |
| emitting | OCHD- | | | 3,10PCANbf(IV)-02 | (1:2) | (2:1) | |

| | | |
|---|---|---|
| device 4 | 001 | (1:0.015) |
| | (1:0.1) | |

This light-emitting device was subjected to sealing with a glass substrate (a sealant was applied to surround the element, followed by UV treatment and one-hour heat treatment at 80° C. at the time of sealing) in a glove box containing a nitrogen atmosphere so that the light-emitting device is not exposed to the air. Then, the initial characteristics and reliability of the light-emitting device 4 were measured. Note that the measurement was performed at room temperature.

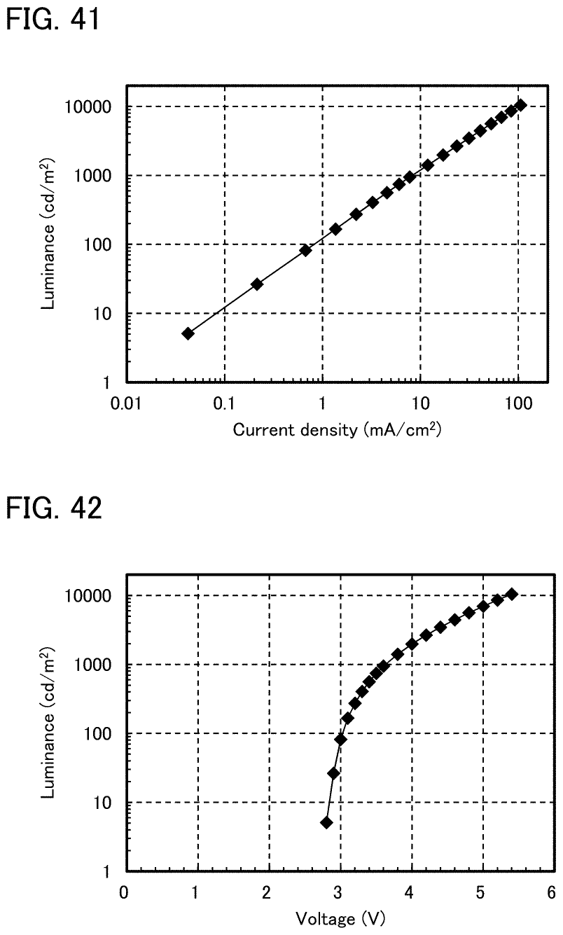

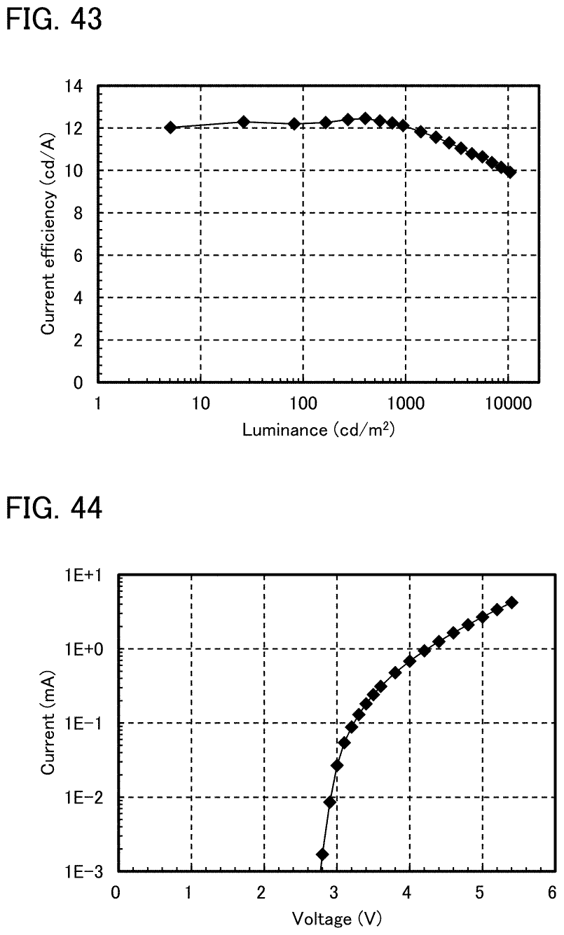

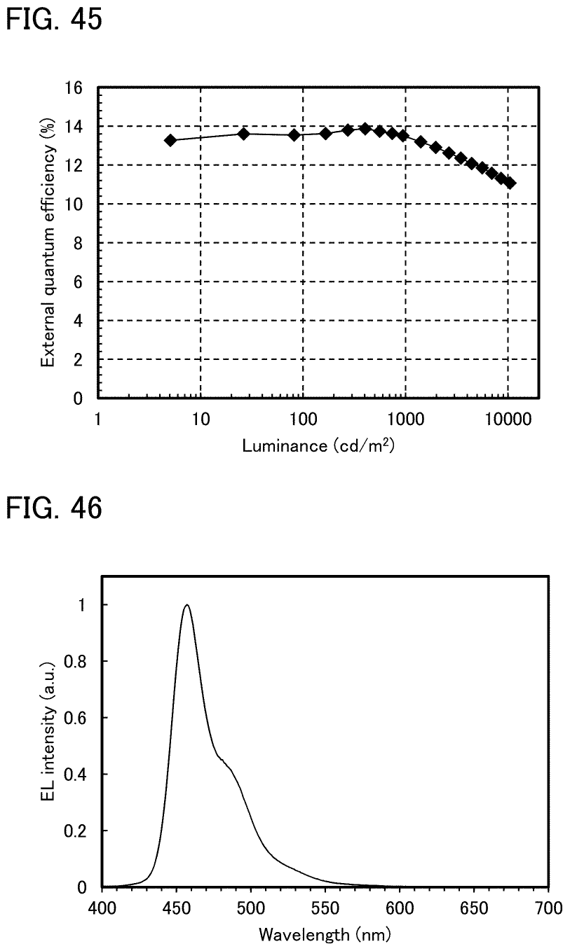

FIG. 41 shows the luminance-current density characteristics of the light-emitting device 4; FIG. 42, the luminance-voltage characteristics thereof; FIG. 43, the current efficiency-luminance characteristics thereof; FIG. 44, the current-voltage characteristics thereof; FIG. 45, the external quantum efficiency-luminance characteristics thereof; and FIG. 46, the emission spectrum thereof. Table 8 shows the main characteristics of the light-emitting device 3 at around 1000 cd/m².

TABLE 8

| | | | | | | Current | External |
|---|---|---|---|---|---|---|---|
| | Voltage | Current | Current density | Chromaticity | Chromaticity | efficiency | quantum |
| | (V) | (mA) | (mA/cm²) | x | y | (cd/A) | efficiency (%) |
| Light-emitting device 4 | 3.6 | 0.31 | 7.8 | 0.14 | 0.10 | 12.1 | 13.5 |

FIG. 41 to FIG. 46 and Table 8 show that the light-emitting device 4 is a blue-light-emitting device with favorable initial characteristics.

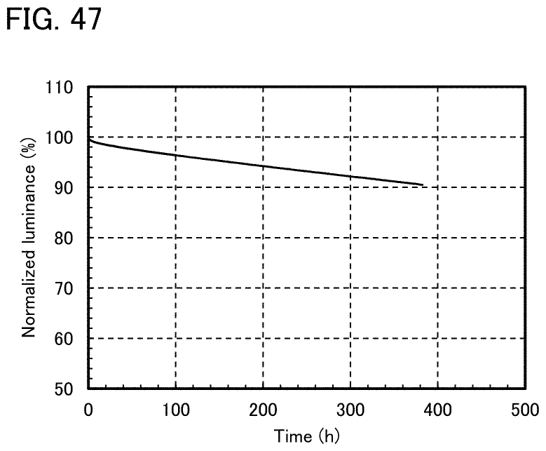

A graph showing a change in luminance over driving time at a current density of 50 mA/cm² is shown in FIG. 47. As shown in FIG. 47, the light-emitting device 4 of one embodiment of the present invention has a long lifetime.

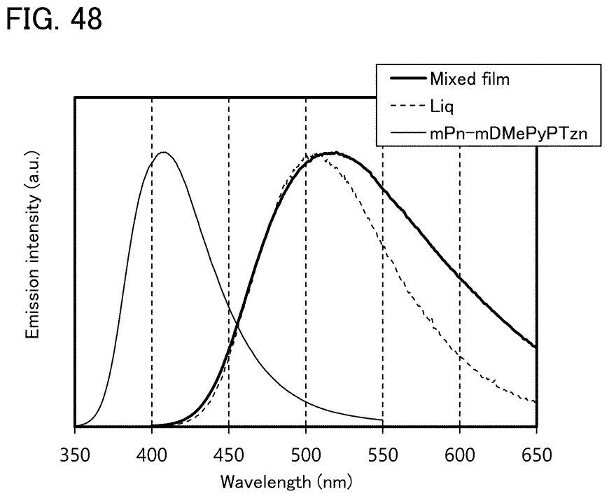

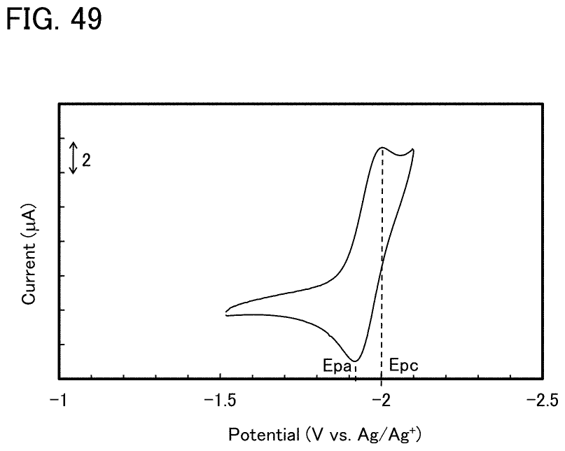

Shown here are the results of measuring the photoluminescence properties of the materials used in the electron-transport layer of the light-emitting device 4. FIG. 48 shows the emission spectra of a mPn-mDMePyPTzn film, a Liq film, and a mixed film of mPn-mDMePyPTzn and Liq mixed at a mass ratio of 1:1, which are used in the light-emitting device 4. Note that a fluorescence spectrophotometer (FP-8600 produced by JASCO Corporation) was for the measurement of the mPn-mDMePyPTzn film, and a fluorescence spectrophotometer (FS920 produced by Hamamatsu Photonics K.K.) was used for the measurement of the other films.

In FIG. 48, the emission spectrum of the mixed film of mPn-mDMePyPTzn and Liq mixed at a mass ratio of 1:1 shifts to a longer wavelength side than the emission spectra of the mPn-mDMePyPTzn film and the Liq film, suggesting that mPn-mDMePyPTzn and Liq form an exciplex.

Note that an exciplex is formed by interaction of molecular orbitals of two substances; the exciplex probably emits light having a peak at a wavelength corresponding to the difference between a shallower HOMO level and a deeper LUMO level of the levels of the two substances.

Table 9 shows the HOMO level and the LUMO level of mPn-mDMePyPTzn, which is an organic compound having an electron-transport property used for the electron-transport layer of the light-emitting device 4; the difference between the LUMO level of mPn-mDMePyPTzn and the HOMO level of Liq, which is an organometallic complex of an alkali metal (ΔE_{LUMO-HOMO}); the peak wavelength of the emission spectrum of an exciplex of mPn-mDMePyPTzn and Liq (λp_{Ex}); the value obtained by converting the peak wavelength into energy (E_{Ex}); and the value obtained by subtracting E_{Ex} from ΔE_{HOMO-LUMO} (ΔE_{HL}-E_{Ex}). The measurement method and calculation method of the HOMO level and the LUMO level are omitted because described in Example 1. Refer to the description in Example 1. As in Example 1, since the significant figures of the HOMO level of Liq are to the first decimal place, the significant figures of each of ΔE_{LUMO-HOMO} and ΔE_{HL}-E_{Ex} are to the first decimal place.

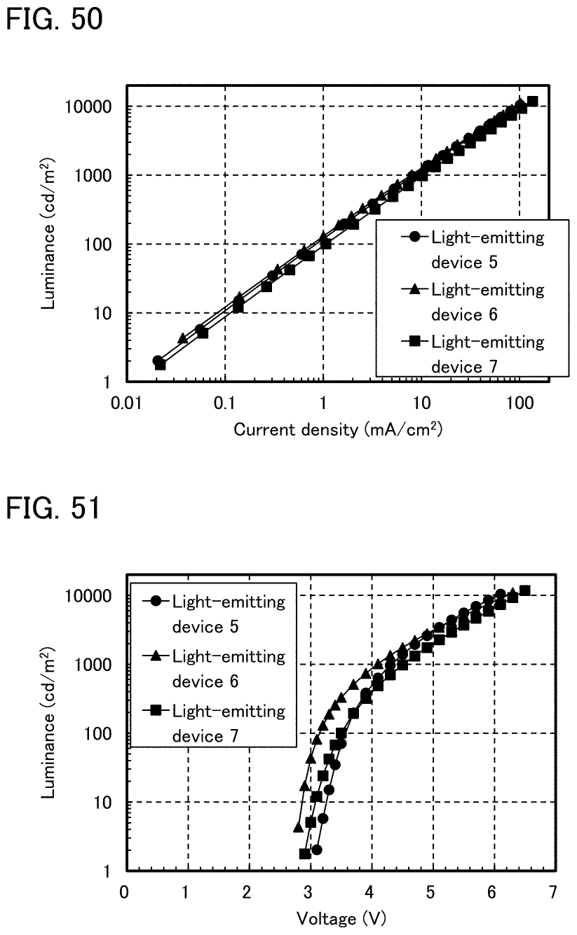

FIG. 49 shows the reduction-oxidation wave of mPn-mDMePyPTzn. In the reduction-oxidation wave of mPn-mDMePyPTzn, the reduction peak potential (Epc) was observed at −2.001 V and the oxidation peak potential (Epa) was observed at −1.917 V. Accordingly, Ec was found to be −1.96 V and the LUMO level of mPn-mDMePyPTzn was calculated to be −2.98 eV.

TABLE 9

| | | | ΔE_{LUMO-} | | | ΔE_{HL}- |
|---|---|---|---|---|---|---|
| | HOMO | LUMO | _{HOMO} | λp_{Ex} | E_{Ex} | E_{Ex} |
| | (eV) | (eV) | (eV) | (nm) | (eV) | (eV) |
| mPn- | — | −2.98 | 2.7 | 520 | 2.38 | 0.3 |
| mDMePyPTzn | | | | | | |

*HOMO of Liq = −5.7 eV, LUMO = −2.7 eV

FIG. 49 shows that mPn-mDMePyPTzn probably forms an exciplex with Liq in the electron-transport layer of the light-emitting device 4 (note that the exciplex can be specified by the observation of no new absorption peak in the absorption spectrum of the mixed film after the mixture). As described above, the value obtained by converting the peak wavelength of the emission spectrum of the exciplex into energy is generally expected to be a value close to the difference between the HOMO level of Liq and the LUMO level of mPn-mDMePyPTzn; however, the light-emitting device 4 exhibits a large ΔE_{HL}-E_{Ex} value, 0.3 eV, as shown in Table 9. It was thus found that the light-emitting device of this embodiment had a ΔE_{HL}-E_{Ex} of 0.3 eV or more, and the value obtained by converting into energy the peak wavelength of the emission spectrum of the exciplex formed in the electron-transport layer of the light-emitting device was smaller than the difference between the HOMO level of Liq and the LUMO level of mPn-mDMePyPTzn by greater than or equal to 0.3 eV.

### EXAMPLE 4

Described in this example are fabrication methods of a light-emitting device 5 to a light-emitting device 7 of one embodiment of the present invention. Structural formulae of materials used in this example are shown below.

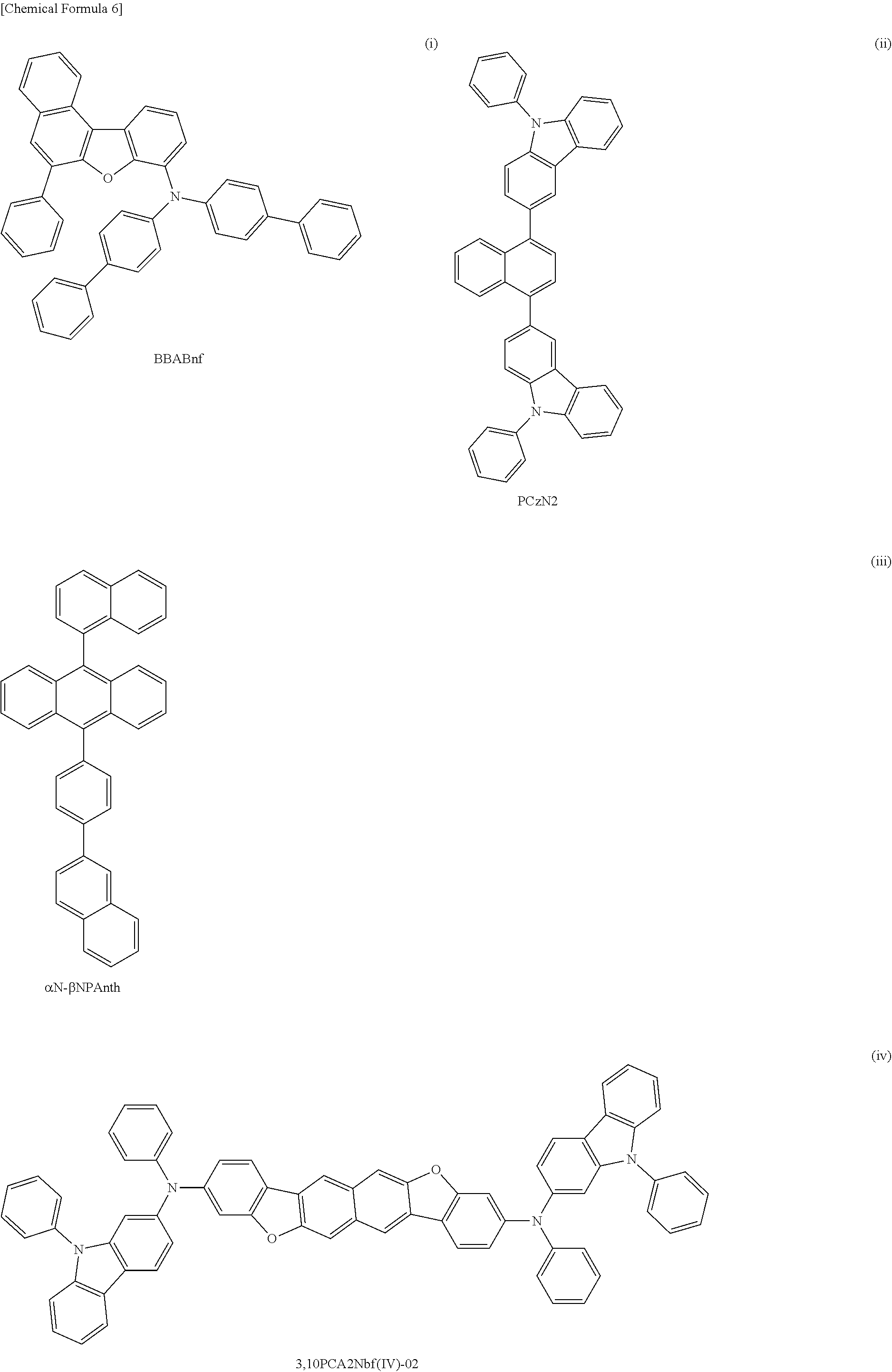

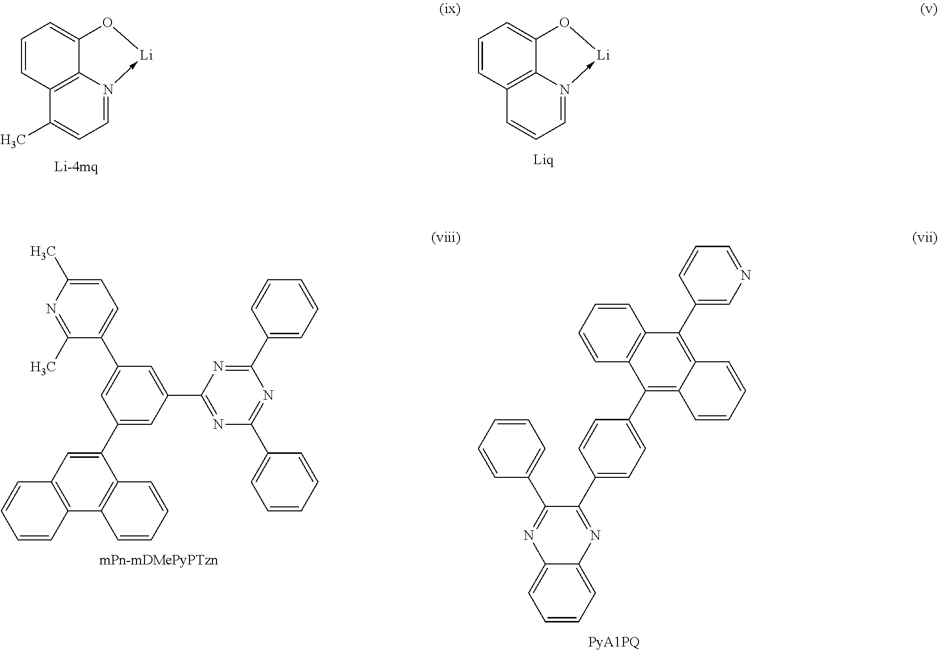

### <<Fabrication Method of Light-Emitting Device 5>>

First, indium tin oxide containing silicon oxide (ITSO) was deposited on a glass substrate by a sputtering method to form the anode 101. Note that the film thickness was 70 nm and the area of the electrode was 4 mm² (2 mm×2 mm).

Next, in pretreatment for forming the light-emitting device over the substrate, the surface of the substrate was washed with water and baked at 200° C. for one hour, and then UV ozone treatment was performed for 370 seconds.

After that, the substrate was transferred into a vacuum evaporation apparatus in which the pressure was reduced to approximately 10⁻⁴ Pa, vacuum baking at 170° C. for 30 minutes was performed in a heating chamber in the vacuum evaporation apparatus, and then the substrate was cooled down for approximately 30 minutes.

Then, the substrate on which the anode 101 was formed was fixed to a substrate holder provided in the vacuum evaporation apparatus such that the surface on which the anode 101 was formed faced downward. On the anode 101, N,N-bis(4-biphenyl)-6-phenylbenzo[b]naphtho[1,2-d]furan-8-amine (abbreviation: BBABnf) represented by Structural Formula (i) above and an electron acceptor material (OCHD-001) were deposited by co-evaporation to a thickness of 10 nm at a mass ratio of 1:0.1 (=BBABnf: OCHD-001) by an evaporation method using resistance heating, whereby the hole-injection layer 111 was formed.

Next, as the first hole-transport layer 112-1, BBABnf was deposited by evaporation to a thickness of 20 nm over the hole-injection layer 111, and then, as the second hole-transport layer 112-2, 3,3′-(naphthalene-1,4-diyl)bis(9-phenyl-9H-carbazole) (abbreviation: PCzN2) represented by Structural Formula (ii) above was deposited by evaporation to a thickness of 10 nm, whereby the hole-transport layer 112 was formed. Note that the second hole-transport layer 112-2 also functions as an electron-blocking layer.

Subsequently, 9-(1-naphthyl)-10-[4-(2-naphthyl)phenyl]anthracene (abbreviation: α,N-βNPAnth) represented by Structural Formula (iii) above, and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) represented by Structural Formula (iv) were deposited by co-evaporation to a thickness of 25 nm at a mass ratio of 1:0.015 (=α,N-βNPAnth: 3,10PCA2Nbf(IV)-02), so that the light-emitting layer 113 was formed.

After that, over the light-emitting layer 113, αN-βNPAnth and 4-methyl-8-quinolinolato-lithium (abbreviation: Li-4mq) represented by Structural Formula (ix) above were deposited by co-evaporation to a thickness of 25 nm at a mass ratio of 1:1 (=αN-βNPAnth: Li-4mq), so that the electron-transport layer 114 was formed.

After the formation of the electron-transport layer 114, 8-hydroxyquinolinato-lithium (abbreviation: Liq) represented by Structural Formula (vi) above was deposited by evaporation to a thickness of 1 nm to form the electron-injection layer 115, and then aluminum was deposited by evaporation to a thickness of 200 nm to form the cathode 102, whereby the light-emitting device 5 of this example was fabricated.

### <<Fabrication Method of Light-Emitting Device 6>>

The light-emitting device 6 was fabricated in the same manner as the light-emitting device 5 except that αN-βNPAnth in the light-emitting device 5 was replaced with 2-[3-(2,6-dimethyl-3-pyridinyl)-5-(9-phenanthrenyl)phenyl]-4,6-diphenyl-1,3,5-triazine (abbreviation: mPn-mDMePyPTzn) represented by Structural Formula (viii) above.

### <<Fabrication Method of Light-Emitting Device 7>>

The light-emitting device 7 was fabricated in the same manner as the light-emitting device 5 except that αN-βNPAnth in the light-emitting device 5 was replaced with 2-phenyl-3-[10-(3-pyridyl)-9-anthryl]phenylquinoxaline (abbreviation: PyA1PQ) represented by Structural Formula (viii) above.

The element structures of the light-emitting device 5 to the light-emitting device 7 are listed in the table.

TABLE 10

| | Hole- | | | | | Electron- |
|---|---|---|---|---|---|---|
| | injection | Hole-transport layer | | Light-emitting | Electron- | injection |
| | layer | 1 | 2 | layer | transport layer | layer |
| | 10 nm | 20 nm | 10 nm | 25 nm | 25 nm | 1 nm |
| Light- | BBABnf: | BBABnf | PCzN2 | αN-βNPAnth: | αN-βNPAnth: | Liq |
| emitting | OCHD- | | | 3,10PCANbf(IV)-02 | Li-4mq | |
| device 5 | 001 | | | (1:0.015) | mPn-mDMePyPTzn: | |
| Light- | (1:0.1) | | | | Li-4mq | |
| emitting | | | | | PyA1PQ:Li-4mq | |
| device 6 | | | | | | |
| Light- | | | | | | |
| emitting | | | | | | |
| device 7 | | | | | | |

These light-emitting devices were subjected to sealing with a glass substrate (a sealant was applied to surround the elements, followed by UV treatment and one-hour heat treatment at 80° C. at the time of sealing) in a glove box containing a nitrogen atmosphere so that the light-emitting device 5 to the light-emitting device 7 are not exposed to the air. Then, the initial characteristics and reliability of the light-emitting device 5 to the light-emitting device 7 were measured. Note that the measurement was performed at room temperature.

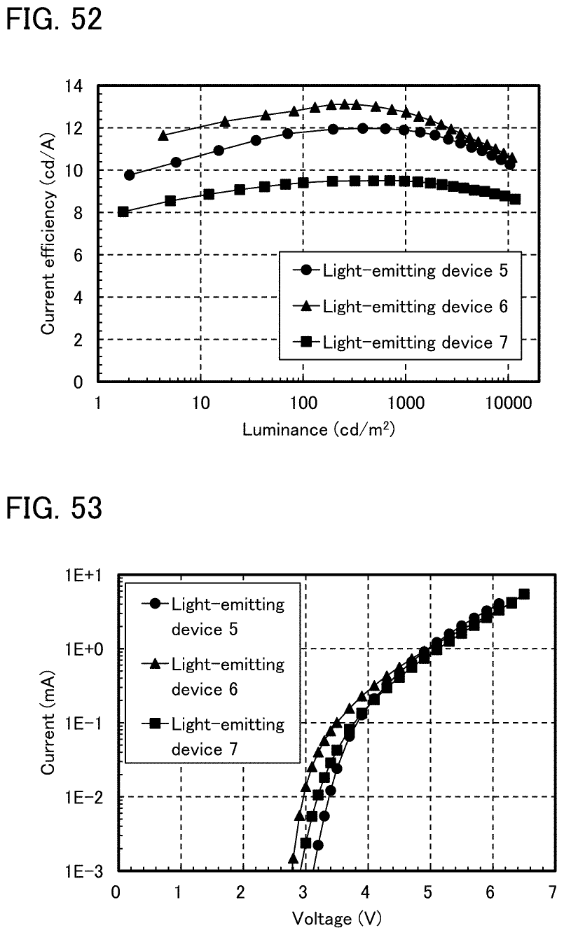

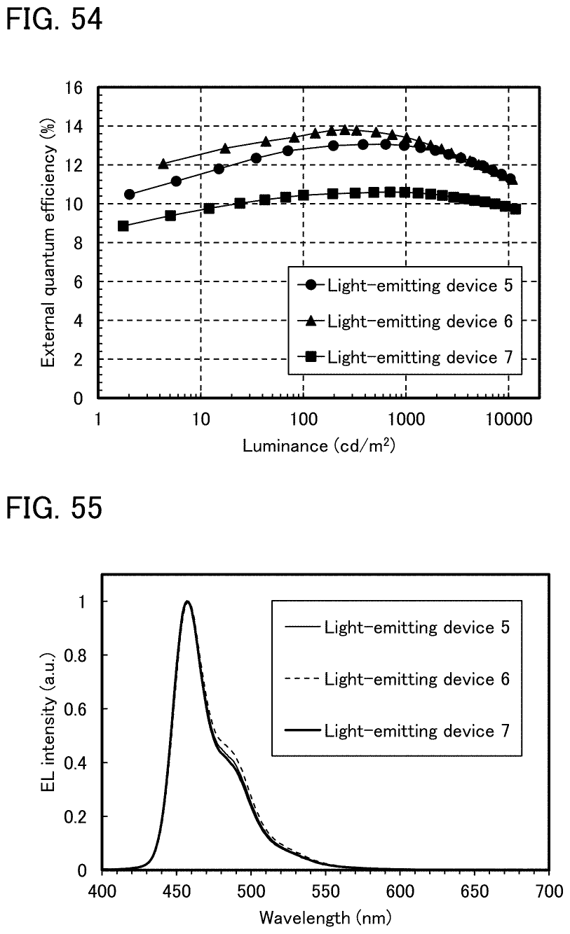

FIG. 50 shows the luminance-current density characteristics of the light-emitting device 5 to the light-emitting device 7; FIG. 51, the luminance-voltage characteristics thereof; FIG. 52, the current efficiency-luminance characteristics thereof; FIG. 53, the current-voltage characteristics thereof, FIG. 54, the external quantum efficiency-luminance characteristics thereof; and FIG. 55, the emission spectra thereof. Table 11 shows the main characteristics of the light-emitting device 5 to the light-emitting device 7 at around 1000 cd/m².

TABLE 11

| | | | | | | Current | External |
|---|---|---|---|---|---|---|---|
| | Voltage | Current | Current density | Chromaticity | Chromaticity | efficiency | quantum |
| | (V) | (mA) | (mA/cm²) | x | y | (cd/A) | efficiency (%) |
| Light-emitting device 5 | 4.3 | 0.32 | 8.1 | 0.14 | 0.10 | 11.9 | 13.0 |
| Light-emitting device 6 | 4.1 | 0.32 | 8.0 | 0.14 | 0.11 | 12.7 | 13.4 |
| Light-emitting device 7 | 4.5 | 0.41 | 10.3 | 0.14 | 0.10 | 9.5 | 10.6 |

FIG. 50 to FIG. 55 and Table 11 show that the three devices are blue-light-emitting devices with favorable initial characteristics.

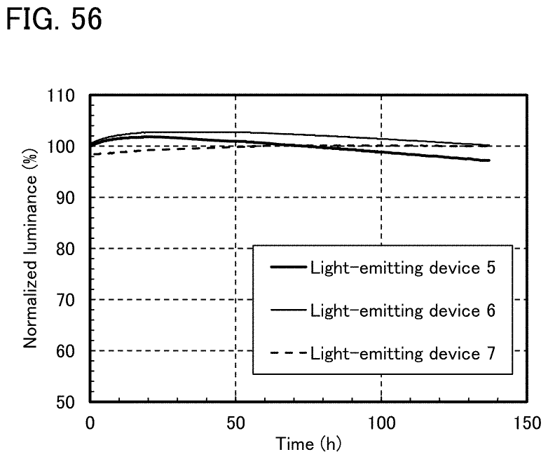

A graph showing a change in luminance over driving time at a current density of 50 mA/cm² is shown in FIG. 56. FIG. 56 indicates that the light-emitting device 5 to the light-emitting device 7, which are the light-emitting devices of embodiments of the present invention, have a long lifetime.

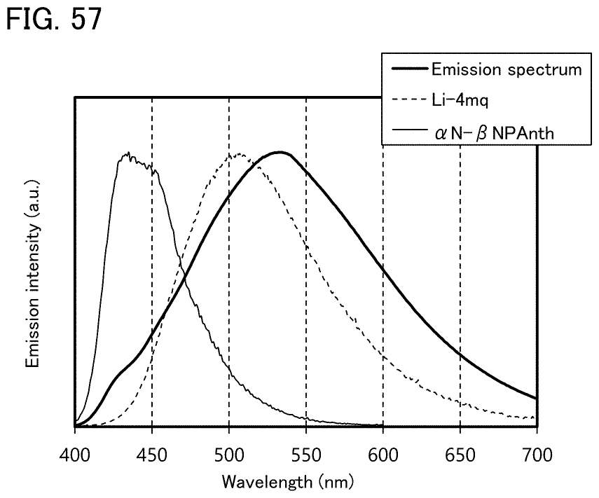

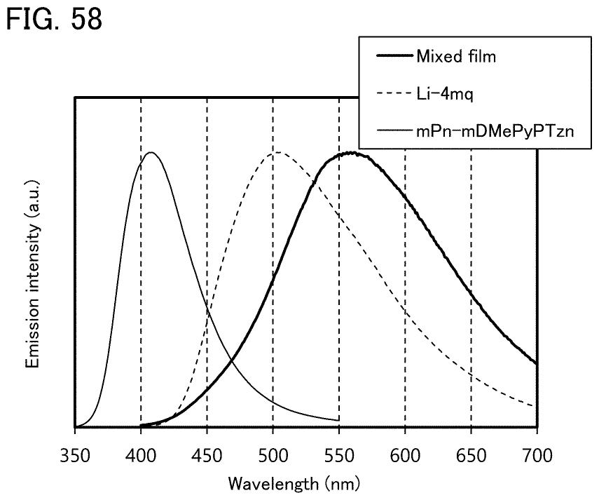

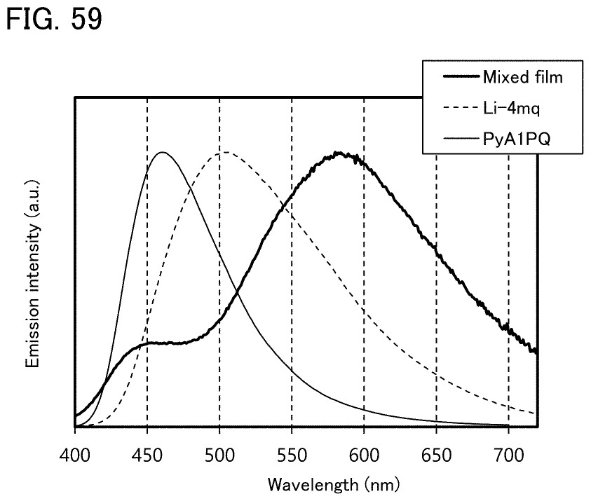

Shown here are the results of measuring the photoluminescence properties of the materials used in the electron-transport layer of each device. The measurement was performed in a manner similar to that in Example 1. FIG. 57 shows the emission spectra of an αN-βNPAnth film, a Li-4mq film, and a mixed film of αN-βNPAnth and Li-4mq mixed at a mass ratio of 1:1, which are used in the light-emitting device 5; FIG. 58 shows the emission spectra of a mPn-mDMePyPTzn film, a Li-4mq film, and a mixed film of mPn-mDMePyPTzn and Li-4mq mixed at a mass ratio of 1:1, which are used in the light-emitting device 6; and FIG. 59 shows the emission spectra of a PyA1PQ film, a Li-4mq film, and a mixed film of PyA1PQ and Li-4mq mixed at a mass ratio of 1:1, which are used in the light-emitting device 7.

In FIG. 57, the emission spectrum of the mixed film of αN-βNPAnth and Li-4mq mixed at a mass ratio of 1:1 shifts to a much longer wavelength side than the emission spectra of the αN-βNPAnth film and the Li-4mq film, suggesting that αN-βNPAnth and Li-4mq form an exciplex. Similarly, FIG. 58 suggests that mPn-mDMePyPTzn and Li-4mq form an exciplex and FIG. 59 suggests that PyA1PQ and Li-4mq form an exciplex.

Note that an exciplex is formed by interaction of molecular orbitals of two substances; the exciplex probably emits light having a peak at a wavelength corresponding to the difference between a shallower HOMO level and a deeper LUMO level of the levels of the two substances. The measurement method and calculation method of the HOMO level and the LUMO level are omitted because described in Example 1. Refer to the description in Example 1. As in Example 1, since the significant figures of the HOMO level of Liq are to the first decimal place, the significant figures of each of ΔE_{LUMO-HOMO} and ΔE_{HL}-E_{Ex} are to the first decimal place.

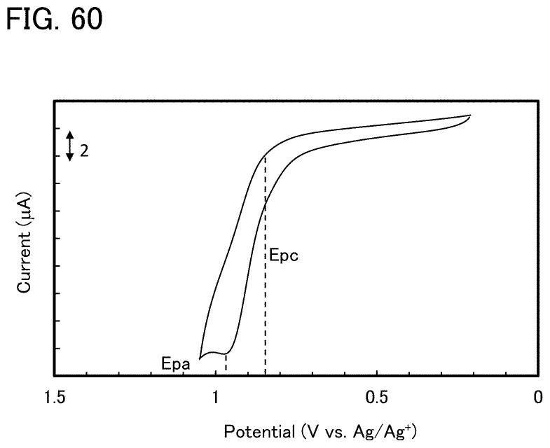

FIG. 60 shows the oxidation-reduction wave of αN-βNPAnth. In the oxidation-reduction wave of αN-βNPAnth, the oxidation peak potential (Epa) was observed at 0.978 V and the reduction peak potential (Epc) was observed at 0.840 V. Accordingly, Ea was found to be 0.91 V and the HOMO level of αN-βNPAnth was calculated to be −5.85 eV.

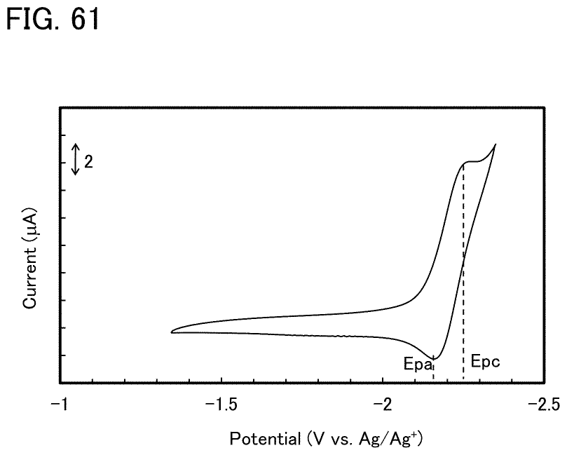

FIG. 61 shows the reduction-oxidation wave of αN-βNPAnth. In the reduction-oxidation wave of αN-βNPAnth, the reduction peak potential (Epc) was observed at −2.248 V and the oxidation peak potential (Epa) was observed at −2.161 V. Accordingly, Ec was found to be −2.20 V and the LUMO level of αN-βNPAnth was calculated to be −2.74 eV.

FIG. 49 shows the reduction-oxidation wave of mPn-mDMePyPTzn. In the reduction-oxidation wave of mPn-mDMePyPTzn, the reduction peak potential (Epc) was observed at −2.001 V and the oxidation peak potential (Epa) was observed at −1.917 V. Accordingly, Ec was found to be −1.96 V and the LUMO level of mPn-mDMePyPTzn was calculated to be −2.98 eV.

FIG. 39 shows the oxidation-reduction wave of PyA1PQ. In the oxidation-reduction wave of PyA1PQ, the oxidation peak potential (Epa) was observed at 1.045 V and the reduction peak potential (Epc) was observed at 0.885 V. Accordingly, Ea was found to be 0.97 V and the HOMO level of PyA1PQ was calculated to be −5.91 eV.

FIG. 40 shows the reduction-oxidation wave of PyA1PQ. In the reduction-oxidation wave of PyA1PQ, the reduction peak potential (Epc) was observed at −1.984 V and the oxidation peak potential (Epa) was observed at −1.904 V. Accordingly, Ec was found to be −1.94 V and the LUMO level of PyA1PQ was calculated to be −3.00 eV.

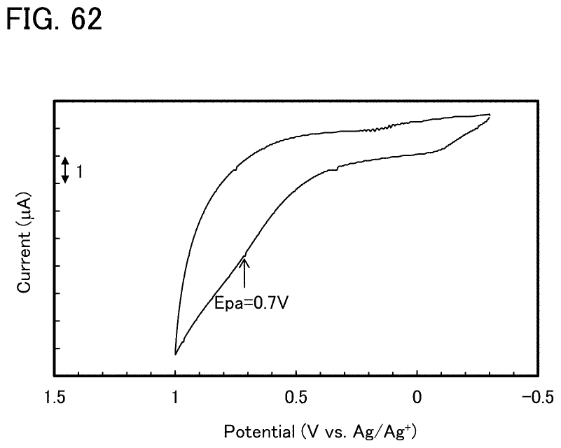

FIG. 62 shows the oxidation-reduction wave of Li-4mq. In the oxidation-reduction wave of Li-4mq, the oxidation peak potential (Epa) was observed at approximately 0.70 eV as a shoulder peak. In contrast, the reduction peak potential (Epc) was not observed; thus, it was assumed that the difference between Epa and Epc was approximately 0.1 V (because the difference between Epa and Epc is known to be a little less than 60 mV in an ideal diffusion system with a sufficient high electron mobility). That is, Epc in the oxidation-reduction wave of Li-4mq was set to 0.60 V here. Accordingly, Ea of Li-4mq was found to be 0.65 eV; the HOMO level of Li-4mq was calculated to be approximately −5.6 eV because calculation should be performed to the first decimal place as significant figures according to the above assumption.

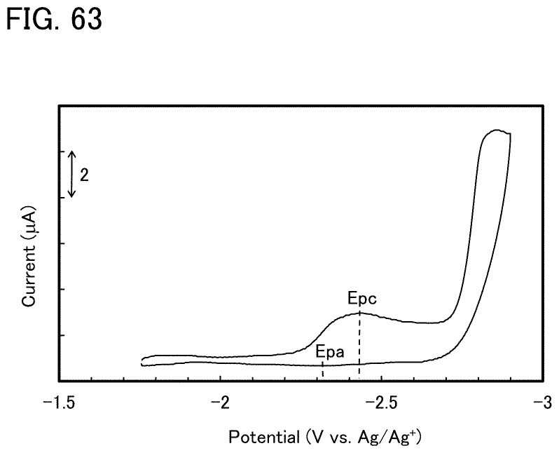

FIG. 63 shows the reduction-oxidation wave of Li-4mq. In the reduction-oxidation wave of Li-4mq, the reduction peak potential (Epc) was observed at −2.437 V and the oxidation peak potential (Epa) was observed at −2.325 V. Accordingly, Ec was found to be −2.38 V and the LUMO level of Li-4mq was calculated to be −2.56 eV.

Table 12 shows the HOMO level and the LUMO level calculated above for each of αN-βNPAnth, mPn-mDMePyPTzn, and PyA1PQ, which are organic compounds having electron-transport properties used for the electron-transport layers of the light-emitting device 5 to the light-emitting device 7; the difference between the LUMO level of each of the three materials and the HOMO level of Li-4mq, which is an organometallic complex of an alkali metal (ΔE_{LUMO-HOMO}); the peak wavelength of the emission spectrum of an exciplex of each of the materials and Liq (λp_{Ex}); the value obtained by converting the peak wavelength into energy (E_{Ex}); and the value obtained by subtracting E_{Ex} from ΔE_{LUMO-HOMO} (ΔE_{HL}-E_{Ex}). Since the significant figures of the HOMO level of Liq are to the first decimal place as described above, the significant figures of each of ΔE_{LUMO-HOMO} and ΔE_{HL}-E_{Ex} are to the first decimal place.

TABLE 12

| | | | ΔE_{LUMO-} | | | ΔE_{HL}- |
|---|---|---|---|---|---|---|
| | HOMO | LUMO | _{HOMO} | λp_{Ex} | E_{Ex} | E_{Ex} |
| | (eV) | (eV) | (eV) | (nm) | (eV) | (eV) |
| αN-βNPAnth | −5.85 | −2.74 | 2.9 | 533 | 2.33 | 0.5 |
| mPn-mDMePyPTzn | — | −2.98 | 2.6 | 559 | 2.22 | 0.4 |
| PyA1PQ | −5.91 | −3.00 | 2.6 | 559 | 2.22 | 0.4 |

**HOMO of Li-4mq = −5.6 eV, LUMO = −2.56 eV

FIG. 57 to FIG. 59 show that each of αN-βNPAnth, mPn-mDMePyPTzn, and PyA1PQ, probably forms an exciplex with Li-4mq, which is an organometallic complex of an alkali metal, in the electron-transport layer of the light-emitting device 5 to the light-emitting device 7 (note that the exciplex can be specified by the observation of no new absorption peak in the absorption spectrum of the mixed film after the mixture). As described above, the value obtained by converting the peak wavelength of the emission spectrum of the exciplex into energy is generally expected to be a value close to the difference between the HOMO level of Li-4mq and the LUMO level of each of αN-βNPAnth, mPn-mDMePyPTzn, and PyA1PQ; however, the light-emitting device of this invention exhibits large ΔE_{HL}-E_{Ex} values, 0.4 eV to 0.5 eV, as shown in Table 12. It was thus found that the light-emitting device of one embodiment of the present invention had a ΔE_{HL}-E_{Ex} of 0.3 eV or more or 0.5 eV or more, and the value obtained by converting into energy the peak wavelength of the emission spectrum of the exciplex formed in the electron-transport layer of the light-emitting device was smaller than the difference between the HOMO level of Li-4mq and the LUMO level of mPn-mDMePyPTzn or PyA1PQ by greater than or equal to 0.3 eV or 0.5 eV.

### REFERENCE EXAMPLE 1

### Synthesis Example 1

Described in this synthesis example a synthesis methods of 2-phenyl-3-[10-(3-pyridyl)-9-anthryl]phenylquinoxaline (abbreviation: PyA1PQ) used in Example 2. The structure of PyA1PQ is shown below.

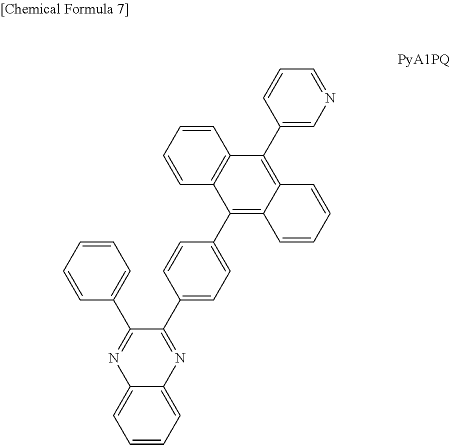 [SMILES: c1ccc(-c2nc3ccccc3nc2-c2ccc(-c3c4ccccc4c(-c4cccnc4)c4ccccc34)cc2)cc1]

Into a 50 mL three-neck flask were put 0.74 g (2.2 mmol) of 3-(10-bromo-9-anthryl)pyridine, 0.26 g (0.85 mmol) of tri(ortho-tolyl)phosphine, 0.73 g (2.3 mmol) of 4-(3-phenylquinoxalin-2-yl)phenylboronic acid, 1.3 g (9.0 mmol) of an aqueous solution of potassium carbonate, 40 mL of ethylene glycol dimethyl ether (DME), and 4.4 mL of water. The mixture was degassed by being stirred under reduced pressure, and the air in the flask was replaced with nitrogen.

To this mixture in the flask was added 65 mg (0.29 mmol) of palladium(II) acetate, and the mixture was stirred at 80° C. under a nitrogen stream for 11 hours. After the stirring, water was added to the mixture in the flask, followed by extraction with toluene. The obtained solution of the extract was washed with saturated saline, and drying with magnesium sulfate was performed. The mixture was gravity filtered, and the filtrate was concentrated to give an oily substance. The obtained oily substance was purified twice by silica gel column chromatography twice (chloroform and then toluene:ethyl acetate=5:1) and recrystallized with toluene/hexane to give 0.43 g of a target yellow solid in a yield of 36%. The synthesis scheme is shown in the following formula.

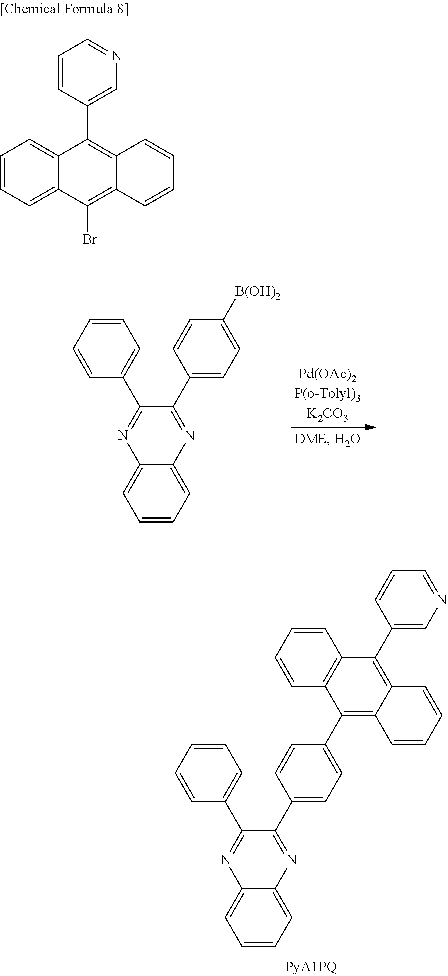 [SMILES: Brc1c2ccccc2c(-c2cccnc2)c2ccccc12 ; OB(O)c1ccc(-c2nc3ccccc3nc2-c2ccccc2)cc1 ; c1ccc(-c2nc3ccccc3nc2-c2ccc(-c3c4ccccc4c(-c4cccnc4)c4ccccc34)cc2)cc1]

By a train sublimation method, 0.44 g of the obtained yellow solid was purified by sublimation. The purification by sublimation was performed for 18 hours under the heating condition of a pressure of 10 Pa, an argon flow rate of 5.0 mL/min, and a temperature of 260° C. After the purification by sublimation, 0.35 g of a target yellow solid was obtained at a collection rate of 79%.

The following shows analysis results by nuclear magnetic resonance (¹H-NMR) spectroscopy of the yellow solid obtained in the above reaction. The results revealed that PyA1PQ represented by the above structural formula was obtained in this example.

¹H NMR (CDCl3, 300 MHz): δ=7.37-7.50 (m, 9H), 7.56-7.78 (m, 9H), 7.82-7.86 (m, 3H), 8.24-8.30 (m, 2H), 8.75 (dd, J=1.8 Hz, 0.9 Hz, 1H), 8.84 (dd, J=4.8 Hz, 1.8 Hz, 1H).

### REFERENCE NUMERALS

1: anode, 102: cathode, 103: EL layer, 111: hole-injection layer, 112: hole-transport layer, 112-1: first hole-transport layer, 112-2: second hole-transport layer, 113: light-emitting layer, 114: electron-transport layer, 114-1: first electron-transport layer, 114-2: second electron-transport layer, 115: electron-injection layer, 400: substrate, 401: anode, 403: EL layer, 404: cathode, 405: sealant, 406: sealant, 407: sealing substrate, 412: pad, 420: IC chip, 501: anode, 502: cathode, 511: first light-emitting unit, 512: second light-emitting unit, 513: charge-generation layer, 601: driver circuit portion (source line driver circuit), 602: pixel portion, 603: driver circuit portion (gate line driver circuit), 604: sealing substrate, 605: sealant, 607: space, 608: wiring, 609: FPC (flexible printed circuit), 610: element substrate, 611: wiring FET, 612: current controlling FET, 613: anode, 614: insulator, 616: EL layer, 617: cathode, 618: light-emitting device, 1001: substrate, 1002: base insulating film, 1003: gate insulating film, 1006: gate electrode, 1007: gate electrode, 1008: gate electrode, 1020: first interlayer insulating film, 1021: second interlayer insulating film, 1022: electrode, 1024W: anode, 1024R: anode, 1024G: anode, 1024B: anode, 1025: partition, 1028: EL layer, 1029: cathode, 1031: sealing substrate, 1032: sealant, 1033: transparent base material, 1034R: red coloring layer, 1034G: green coloring layer, 1034B: blue coloring layer, 1035: black matrix, 1036: overcoat layer, 1037: third interlayer insulating film, 1040: pixel portion, 1041: driver circuit portion, 1042: peripheral portion, 2001: housing, 2002: light source, 2100: robot, 2110: arithmetic device, 2101: illuminance sensor, 2102: microphone, 2103: upper camera, 2104: speaker, 2105: display, 2106: lower camera, 2107: obstacle sensor, 2108: moving mechanism, 3001: lighting device, 5000: housing, 5001: display portion, 5002: display portion, 5003: speaker, 5004: LED lamp, 5006: connection terminal, 5007: sensor, 5008: microphone, 5012: support, 5013: earphone, 5100: cleaning robot, 5101: display, 5102: camera, 5103: brush, 5104: operation button, 5150: portable information terminal, 5151: housing, 5152: display region, 5153: bend portion, 5120: dust, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: second display portion, 7401: housing, 7402: display portion, 7403: operation button, 7404: external connection port, 7405: speaker, 7406: microphone, 7400: cellular phone, 9310: portable information terminal, 9311: display panel, 9313: hinge, 9315: housing,

1. A light-emitting device comprising a first electrode, a second electrode, and an EL layer,
wherein the EL layer is positioned between the first electrode and the second electrode,
wherein the EL layer includes a light-emitting layer and an electron-transport layer,
wherein the electron-transport layer is positioned between the light-emitting layer and the second electrode,
wherein the electron-transport layer includes an organometallic complex of an alkali metal and an organic compound having an electron-transport property,
wherein the organometallic complex and the organic compound form an exciplex in combination, and
wherein a value (eV) obtained by converting into energy a peak wavelength of an emission spectrum of the exciplex formed with the organometallic complex and the organic compound having a mass ratio of 1:1 is smaller than a difference (eV) between a HOMO level of the organometallic complex and a LUMO level of the organic compound by greater than or equal to 0.5 eV.

2-3. (canceled)

4. A light-emitting device comprising a first electrode, a second electrode, and an EL layer,
wherein the EL layer is positioned between the first electrode and the second electrode,
wherein the EL layer includes a light-emitting layer and an electron-transport layer,
wherein the electron-transport layer is positioned between the light-emitting layer and the second electrode,
wherein the electron-transport layer includes an organometallic complex of an alkali metal and an organic compound having an electron-transport property,
wherein the organometallic complex and the organic compound form an exciplex in combination, and
wherein a peak wavelength of an emission spectrum of the exciplex formed with the organometallic complex and the organic compound having a mass ratio of 1:1 is greater than or equal to 570 nm.

5. The light-emitting device according to claim 4,
wherein the peak wavelength of the emission spectrum of the exciplex formed with the organometallic complex and the organic compound having a mass ratio of 1:1 is greater than or equal to 570 nm and less than 610 nm.

6. The light-emitting device according to claim 4,
wherein the peak wavelength of the emission spectrum of the exciplex formed with the organometallic complex and the organic compound having a mass ratio of 1:1 is greater than or equal to 610 nm.

7. The light-emitting device according to claim 1,
wherein the organometallic complex of an alkali metal is an organometallic complex of lithium.

8. (canceled)

9. The light-emitting device according to claim 1,
wherein the organometallic complex of an alkali metal is 8-hydroxyquinolinato-lithium or a derivative thereof.

10. A light-emitting device comprising a first electrode, a second electrode, and an EL layer,
wherein the EL layer is positioned between the first electrode and the second electrode,
wherein the EL layer includes a light-emitting layer and an electron-transport layer,
wherein the electron-transport layer is positioned between the light-emitting layer and the second electrode,
wherein the electron-transport layer includes an organometallic complex of an alkali metal and an organic compound having an electron-transport property,
wherein a difference between a HOMO level of the organometallic complex and a LUMO level of the organic compound is less than or equal to 2.9 eV, and
wherein when a mixed film of the organometallic complex and the organic compound is analyzed by mass spectrometry, a value obtained by subtracting 2 from the sum of a molecular weight of the organometallic complex, a molecular weight of the organic compound, and an atomic weight of an alkaline earth metal contained in the organometallic complex is observed as m/z.

11. The light-emitting device according to claim 10,
wherein the organometallic complex of an alkali metal is an organometallic complex of lithium.

12. (canceled)

13. The light-emitting device according to claim 10,
wherein the organometallic complex of an alkali metal is 8-hydroxyquinolinato-lithium or a derivative thereof.

14. The light-emitting device according to claim 10,
wherein the organometallic complex and the organic compound form an exciplex.

15. The light-emitting device according to claim 14,
wherein a value (eV) obtained by converting into energy a peak wavelength of an emission spectrum of the exciplex formed with the organometallic complex and the organic compound having a mass ratio of 1:1 is smaller than the difference (eV) between the HOMO level of the organometallic complex and the LUMO level of the organic compound by greater than or equal to 0.1 eV.

16-17. (canceled)

18. The light-emitting device according to claim 14,
wherein a peak wavelength of an emission spectrum of the exciplex formed with the organometallic complex and the organic compound having a mass ratio of 1:1 is greater than or equal to 570 nm.

19-20. (canceled)

21. The light-emitting device according to claim 1,
wherein the organic compound has a heteroaromatic ring.

22. (canceled)

23. The light-emitting device according to claim 1,
wherein the light-emitting layer contains a host material and a light-emitting material, and
wherein the light-emitting material emits blue fluorescent light.

24. An electronic device comprising the light-emitting device according to claim 1, and a sensor, an operation button, a speaker, or a microphone.

25. A light-emitting apparatus comprising the light-emitting device according to claim 1, and a transistor or a substrate.

26. A lighting device comprising the light-emitting device according to claim 1, and a housing.

27. The light-emitting device according to claim 4,
wherein the organometallic complex of an alkali metal is an organometallic complex of lithium.

28. The light-emitting device according to claim 4,
wherein the organometallic complex of an alkali metal is 8-hydroxyquinolinato-lithium or a derivative thereof.

29. The light-emitting device according to claim 4,
wherein the organic compound has a heteroaromatic ring.

30. The light-emitting device according to claim 4,
wherein the light-emitting layer contains a host material and a light-emitting material, and
wherein the light-emitting material emits blue fluorescent light.

31. The light-emitting device according to claim 10,
wherein the organic compound has a heteroaromatic ring.

32. The light-emitting device according to claim 10,
wherein the light-emitting layer contains a host material and a light-emitting material, and
wherein the light-emitting material emits blue fluorescent light.
